(19) United States
(12) Patent Application Publication
(10) Pub. No.: US 2023/0422535 A1
(43) Pub. Date: Dec. 28, 2023

(54) IMAGING DEVICE AND METHOD FOR MANUFACTURING THE SAME

(71) Applicant: Panasonic Intellectual Property Management Co., Ltd., Osaka (JP)

(72) Inventor: TAIJI NODA, Osaka (JP)

(21) Appl. No.: 18/463,332

(22) Filed: Sep. 8, 2023

Related U.S. Application Data
(63) Continuation of application No. PCT/JP2022/011257, filed on Mar. 14, 2022.

(30) Foreign Application Priority Data
Apr. 5, 2021 (JP) 2021-064237

(51) Int. Cl. H10K 39/32

(52) U.S. Cl. CPC H10K 39/32

(57) ABSTRACT

An imaging device includes a pixel region and a first peripheral region. The pixel region includes a pixel substrate portion and an amplifying transistor that outputs a signal voltage corresponding to an amount of signal charge. The amplifying transistor is located in the pixel substrate portion. The first peripheral region includes a first peripheral substrate portion and a first peripheral transistor. The first peripheral transistor is located in the first peripheral substrate portion. The pixel substrate portion and the first peripheral substrate portion are stacked on each other. At least one type of impurity that contributes to inhibition of transient enhanced diffusion of a conductive impurity is defined as a specific species. The first peripheral transistor includes a first specific layer that is located in the first peripheral substrate portion and that contains the conductive impurity and the specific species.

### BACKGROUND

### 1. Technical Field

The present disclosure relates to an imaging device and a method for manufacturing the same.

### 2. Description of the Related Art

Image sensors are used in digital cameras or other devices. Examples of image sensors include CCD (charge-coupled device) image sensors and CMOS (complementary metal-oxide semiconductor) image sensors.

An image sensor according to one example has a photodiode provided in a semiconductor substrate. An image sensor according to another example has a photoelectric conversion layer provided above a semiconductor substrate.

An imaging device according to one specific example produces signal charge through photoelectric conversion. The signal charge thus produced is accumulated in a charge accumulation node. A signal corresponding to the amount of charge accumulated in the charge accumulation node is read out via a CCD or CMOS circuit formed in a semiconductor substrate.

Japanese Unexamined Patent Application Publication No. 2019-24075 discloses an imaging device. The imaging device of Japanese Unexamined Patent Application Publication No. 2019-24075 includes a pixel region and a peripheral region.

### SUMMARY

In one general aspect, the techniques disclosed here feature an imaging device including: a pixel region including a pixel substrate portion and an amplifying transistor that is located in the pixel substrate portion and that outputs a signal voltage corresponding to an amount of signal charge; and a first peripheral region including a first peripheral substrate portion and a first peripheral transistor located in the first peripheral substrate portion. The pixel substrate portion and the first peripheral substrate portion are stacked on each other. When at least one type of impurity that contributes to inhibition of transient enhanced diffusion of a conductive impurity is defined as a specific species, the first peripheral transistor includes a first specific layer that is located in the first peripheral substrate portion and that contains the conductive impurity and the specific species.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a diagram schematically showing an exemplary configuration of an imaging device;

FIG. 2 is a diagram schematically showing an exemplary circuit configuration of the imaging device;

FIG. 3 is a schematic cross-sectional view showing a pixel region, a peripheral region, and a blocking region;

FIG. 4 is a schematic plan view showing another example of the shape of a blocking region;

FIG. 5 is a cross-sectional view showing a transistor according to a first configuration example;

FIG. 6 is a cross-sectional view showing a transistor according to a first modification of the first configuration example;

FIG. 7 is a cross-sectional view showing a transistor according to a second modification of the first configuration example;

FIG. 8 is a diagram showing in-depth impurity profiles in source-drain formation regions according to a third modification of the first configuration example;

FIGS. 9A to 9E are cross-sectional views showing a method for manufacturing a transistor according to the first configuration example;

FIGS. 10A to 10D are cross-sectional views showing the method for manufacturing a transistor according to the first configuration example;

FIGS. 11A to 11C are cross-sectional views showing the method for manufacturing a transistor according to the first configuration example;

FIGS. 12A and 12B are graphs showing in-depth impurity profiles in extension formation regions according to the first configuration example;

FIG. 13 is a schematic perspective view illustrating a transistor of a pixel region and a transistor of a peripheral region;

FIG. 14 is a schematic perspective view illustrating a transistor of a pixel region and a transistor of a peripheral region;

FIG. 15 illustrates schematic cross-sectional views showing a transistor of a pixel region and a transistor of a peripheral region;

FIG. 16 is a schematic perspective view illustrating a transistor of a pixel region and transistors of a peripheral region;

FIG. 17 is a schematic perspective view illustrating a transistor of a pixel region and transistors of a peripheral region;

FIG. 18 is a schematic perspective view illustrating a transistor of a pixel region and transistors of peripheral regions;

FIG. 19 is a schematic perspective view illustrating a transistor of a pixel region and transistors of peripheral regions;

FIG. 20 illustrates schematic cross-sectional views showing a transistor of a pixel region and transistors of peripheral regions;

FIG. 21 is a schematic perspective view illustrating a transistor of a pixel region and transistors of peripheral regions;

FIG. 22 is a schematic perspective view illustrating a transistor of a pixel region and transistors of peripheral regions;

FIG. 23 illustrates schematic cross-sectional views showing a transistor of a pixel region and transistors of peripheral regions;

FIG. 24 is a schematic cross-sectional view showing a transistor of a pixel region and transistors of peripheral regions;

FIG. 25 is a schematic view of a back-side illumination imaging device;

FIG. 26 is a schematic view of a back-side illumination imaging device;

FIG. 27 is a schematic view of a back-side illumination imaging device;

FIG. 28 is a schematic view showing shapes that a pixel region and peripheral regions of an imaging device may take;

FIG. 29 is a schematic view showing shapes that a pixel region and peripheral regions of an imaging device may take;

FIG. 30 is a schematic view showing shapes that a pixel region and peripheral regions of an imaging device may take;

FIG. 31 is a schematic view showing shapes that a pixel region and peripheral regions of an imaging device may take

FIG. 32 is a schematic view showing shapes that a pixel region and peripheral regions of an imaging device may take;

FIG. 33A is a schematic cross-sectional view of an imaging device according to a specific example;

FIG. 33B is a schematic perspective view of an imaging device according to a specific example;

FIG. 34A is a schematic cross-sectional view of an imaging device according to a specific example;

FIG. 34B is a schematic perspective view of an imaging device according to a specific example;

FIG. 35A is a schematic cross-sectional view of an imaging device according to a specific example;

FIG. 35B is a schematic perspective view of an imaging device according to a specific example;

FIG. 36A is a schematic cross-sectional view of an imaging device according to a specific example;

FIG. 36B is a schematic perspective view of an imaging device according to a specific example;

FIG. 37A is a schematic cross-sectional view of an imaging device according to a specific example;

FIG. 37B is a schematic perspective view of an imaging device according to a specific example; and

FIG. 38 is a schematic cross-sectional view of an imaging device according to a specific example.

### DETAILED DESCRIPTIONS

Japanese Unexamined Patent Application Publication No. 2019-24075 fails to go into improving the performance of an imaging device in consideration of the presence of a transistor in a peripheral region.

The techniques disclosed here are suitable to improving the performance of an imaging device in consideration of the presence of a first peripheral transistor in a first peripheral region.

### Underlying Knowledge Forming Basis of the Present Disclosure

In the process of manufacturing a stacked semiconductor device including a first layer and a second layer, the first layer may be heated for the following reasons. First, the first layer may be heated by heat that is supplied in forming the first layer. Second, in a case where the first layer and the second layer are separately formed and then those layers are joined to each other, the first layer may be heated by heating for the joining. Third, in a case where the second layer is subjected to heat treatment after a stacked structure including the first layer and the second layer has been formed, the first layer may be heated too by the heat treatment.

There has been known an imaging device having a pixel region including a pixel transistor and a peripheral region including a peripheral transistor. The inventor studied an imaging device in which a pixel substrate portion provided with a pixel transistor and a peripheral substrate portion provided with a peripheral transistor are stacked. In the process of manufacturing such an imaging device too, the peripheral region may be heated for reasons that are similar to those noted above. However, heating the peripheral transistor may cause diffusion of a conductive impurity in the peripheral transistor. The diffusion of the conductive impurity may cause deterioration in performance of the peripheral transistor. The deterioration in performance of the peripheral transistor may cause deterioration in performance of the imaging device as a whole. To address this problem, the inventor studied to improve the performance of an imaging device in consideration of the presence of a peripheral transistor.

### Brief Overview of Aspects of the Present Disclosure

An imaging device according to a first aspect of the present disclosure includes a pixel region including a pixel substrate portion and an amplifying transistor that is located in the pixel substrate portion and that outputs a signal voltage corresponding to an amount of signal charge and a first peripheral region including a first peripheral substrate portion and at least one first peripheral transistor located in the first peripheral substrate portion. The pixel substrate portion and the first peripheral substrate portion are stacked on each other. When at least one type of impurity that contributes to inhibition of transient enhanced diffusion of a conductive impurity is defined as a specific species, the at least one first peripheral transistor includes a first specific layer that is located in the first peripheral substrate portion and that contains the conductive impurity and the specific species.

The technique according to the first aspect is suitable to improving the performance of the imaging device in consideration of the presence of the first peripheral transistor in the first peripheral region.

In a second aspect of the present disclosure, for example, in the imaging device according to the first aspect, the specific species may contain at least one selected from the group consisting of carbon, nitrogen, and fluorine.

The specific species of the second aspect may inhibit the transient enhanced diffusion of the conductive impurity.

In a third aspect of the present disclosure, for example, in the imaging device according to the first or second aspect, the specific species may contain at least one selected from the group consisting of germanium, silicon, and argon.

The specific species of the third aspect may inhibit the transient enhanced diffusion of the conductive impurity through pre-amorphization.

In a fourth aspect of the present disclosure, for example, in the imaging device according to any one of the first to third aspects, a gate length of the at least one first peripheral transistor may be shorter than a gate length of the amplifying transistor.

The configuration of the fourth aspect is an example of a configuration of the imaging device.

In a fifth aspect of the present disclosure, for example, in the imaging device according to any one of the first to fourth aspects,
the amplifying transistor may include an amplifying gate insulator film,
the at least one first peripheral transistor may include a first peripheral gate insulator film, and
the first peripheral gate insulator film may be thinner than the amplifying gate insulator film.

The configuration of the fifth aspect is an example of a configuration of the imaging device.

In a sixth aspect of the present disclosure, for example, in the imaging device according to any one of the first to fifth aspects,
the at least one first peripheral transistor may include a first source, a first drain, and a first extension diffusion layer,
the first extension diffusion layer may be adjacent to the first source or the first drain and shallower than the first source and the first drain, and
the first extension diffusion layer may include the first specific layer.

The configuration of the sixth aspect is an example of a configuration of the imaging device.

In a seventh aspect of the present disclosure, for example, in the imaging device according to any one of the first to sixth aspects,
the at least one first peripheral transistor may include a first source, a first drain, and a first pocket diffusion layer,
the first pocket diffusion layer may be adjacent to the first source or the first drain, and
the first pocket diffusion layer may include the first specific layer.

The configuration of the seventh aspect is an example of a configuration of the imaging device.

In an eighth aspect of the present disclosure, for example, in the imaging device according to any one of the first to seventh aspects,
the at least one first peripheral transistor may include a first source and a first drain, and
at least one selected from the group consisting of the first source and the first drain may include the first specific layer.

The configuration of the eighth aspect is an example of a configuration of the imaging device.

In a ninth aspect of the present disclosure, for example, in the imaging device according to any one of the first to eighth aspects,
the pixel substrate portion may include a charge accumulation region serving as an impurity region in which charge generated by photoelectric conversion is accumulated, and
a concentration of carbon in the first specific layer may be higher than a concentration of carbon in the charge accumulation region.

Only a high-performance imaging device can have the feature of the ninth aspect.

In a tenth aspect of the present disclosure, for example, in the imaging device according to any one of the first to ninth aspects,
the amplifying transistor may include a gate, and
a concentration of carbon in the first specific layer may be higher than a concentration of carbon in a portion of a surface of the pixel substrate portion, the portion of the surface overlapping the gate in a plan view.

Only a high-performance imaging device can have the feature of the tenth aspect.

In an eleventh aspect of the present disclosure, for example, in the imaging device according to any one of the first to tenth aspects,
the pixel region may further include a photoelectric conversion layer, and
the photoelectric conversion layer, the pixel substrate portion, and the first peripheral substrate portion may be stacked on each other.

The configuration of the eleventh aspect is an example of a configuration of the imaging device.

In a twelfth aspect of the present disclosure, for example, in the imaging device according to any one of the first to eleventh aspects, the pixel substrate portion may include a photodiode.

The configuration of the twelfth aspect is an example of a configuration of the imaging device.

In a thirteenth aspect of the present disclosure, for example, in the imaging device according to any one of the first to twelfth aspects,
the at least one first peripheral transistor may include an end-of-range defect,
at least part of the first specific layer may be located above the end-of-range defect and may overlap the end-of-range defect in a plan view.

The end-of-range defect of the thirteenth aspect may include a trace of pre-amorphization that may enhance the diffusion-inhibiting action on the conductive impurity by an impurity exemplified by carbon.

In a fourteenth aspect of the present disclosure, for example, in the imaging device according to any one of the first to thirteenth aspects,
the at least one first peripheral transistor may include a segregated portion in which the specific species is segregated in a direction parallel with a depth of the first peripheral substrate portion, and
at least part of the first specific layer may be located above the segregated portion and may overlap the segregated portion in a plan view.

The segregated portion of the fourteenth aspect may be a trace of pre-amorphization that may enhance the diffusion-inhibiting action on the conductive impurity by an impurity exemplified by carbon.

In a fifteenth aspect of the present disclosure, for example, in the imaging device according to the fourteenth aspect, wherein
the pixel substrate portion may include a charge accumulation region serving as an impurity region in which charge generated by photoelectric conversion is accumulated, and
the segregated portion may be shallower than the charge accumulation region.

The configuration of the fifteenth aspect is an example of a configuration of the imaging device.

In a sixteenth aspect of the present disclosure, for example, in the imaging device according to any one of the first to fifteenth aspects,
the at least one first peripheral transistor may comprise two first peripheral transistors,
the first peripheral substrate portion may include a shallow trench isolation structure,
the shallow trench isolation structure may provide device isolation of the two first peripheral transistors from each other,
the shallow trench isolation structure may have a trench, and
a range of distribution of the specific species in the first specific layer of at least one of the two first peripheral transistors may be shallower than a bottom of the trench.

The configuration of the sixteenth aspect is an example of a configuration of the imaging device.

In a seventeenth aspect of the present disclosure, for example, the imaging device according to any one of the first to sixteenth aspects may further include an insulating part, and
the pixel substrate portion and the first peripheral substrate portion may be stacked with the insulating part disposed between the pixel substrate portion and the first peripheral substrate portion.

The configuration of the seventeenth aspect is an example of a configuration of the imaging device.

In an eighteenth aspect of the present disclosure, for example, the imaging device according to any one of the first to seventeenth aspects may further include a second peripheral region including a second peripheral substrate portion and at least one second peripheral transistor located in the second peripheral substrate portion, and
the first peripheral substrate portion and the second peripheral substrate portion may be included in one semiconductor substrate.

The configuration of the eighteenth aspect is an example of a configuration of the imaging device.

In a nineteenth aspect of the present disclosure, for example, the imaging device according to any one of the first to seventeenth aspects may further include a second peripheral region including a second peripheral substrate portion and at least one second peripheral transistor located in the second peripheral substrate portion, and
the pixel substrate portion, the first peripheral substrate portion, and the second peripheral substrate portion may be stacked on top of each other.

The configuration of the nineteenth aspect is an example of a configuration of the imaging device.

In a twentieth aspect of the present disclosure, for example, the imaging device according to any one of the first to seventeenth aspects may further include a second peripheral region including a second peripheral substrate portion and at least one second peripheral transistor located in the second peripheral substrate portion, a first semiconductor substrate, a second semiconductor substrate, and a third semiconductor substrate,
the pixel substrate portion may be included in the first semiconductor substrate,
the first peripheral substrate portion may include a portion included in the second semiconductor substrate and a portion included in the third semiconductor substrate,
the second peripheral substrate portion may include a portion included in the second semiconductor substrate and a portion included in the third semiconductor substrate,
the at least one first peripheral transistor may include a P-channel transistor located in the second semiconductor substrate and an N-channel transistor located in the third semiconductor substrate,
the at least one second peripheral transistor may include a P-channel transistor located in the second semiconductor substrate and an N-channel transistor located in the third semiconductor substrate, and
the first semiconductor substrate, the second semiconductor substrate, and the third semiconductor substrate may be stacked on each other.

The configuration of the twentieth aspect is an example of a configuration of the imaging device.

In a twenty-first aspect of the present disclosure, for example, the imaging device according to any one of the first to seventeenth aspects may further include a second peripheral region including a second peripheral substrate portion and at least one second peripheral transistor located in the second peripheral substrate portion, and
the pixel substrate portion and the second peripheral substrate portion may be included in one semiconductor substrate.

The configuration of the twenty-first aspect is an example of a configuration of the imaging device.

In a twenty-second aspect of the present disclosure, for example, the imaging device according to the twenty-first aspect may further include a vertical signal line,
the at least one second peripheral transistor may include a load transistor, and
the amplifying transistor may be connected to the load transistor via the vertical signal line.

The configuration of the twenty-second aspect is an example of a configuration of the imaging device.

In a twenty-third aspect of the present disclosure, for example, in the imaging device according to any one of the eighteenth to twenty-second aspects,
the at least one first peripheral transistor may include a first source, a first drain, and a first extension diffusion layer,
the first extension diffusion layer may be adjacent to the first source or the first drain and shallower than the first source and the first drain,
the at least one second peripheral transistor may include a second source, a second drain, and a second extension diffusion layer,
the second extension diffusion layer may be adjacent to the second source or the second drain and shallower than the second source and the second drain,
a concentration of the conductive impurity in the second extension diffusion layer may be lower than a concentration of the conductive impurity in the first extension diffusion layer, and
the second extension diffusion layer may be deeper than the first extension diffusion layer.

The configuration of the twenty-third aspect is an example of a configuration of the imaging device.

In a twenty-fourth aspect of the present disclosure, for example, in the imaging device according to any one of the eighteenth to twenty-third aspects, a gate length of the at least one first peripheral transistor may be shorter than a gate length of the at least one second peripheral transistor.

The configuration of the twenty-fourth aspect is an example of a configuration of the imaging device.

In a twenty-fifth aspect of the present disclosure, for example, in the imaging device according to any one of the eighteenth to twenty-fourth aspects, a gate length of the amplifying transistor may be longer than a gate length of the at least one second peripheral transistor.

The configuration of the twenty-fifth aspect is an example of a configuration of the imaging device.

In a twenty-sixth aspect of the present disclosure, for example, in the imaging device according to any one of the eighteenth to twenty-fifth aspects,
the at least one second peripheral transistor may include a second specific layer that is located in the second peripheral substrate portion and that contains the conductive impurity, and
a concentration of the specific species in the first specific layer may be higher than a concentration of the specific species in the second specific layer.

The configuration of the twenty-sixth aspect is an example of a configuration of the imaging device.

In a twenty-seventh aspect of the present disclosure, for example, in the imaging device according to any one of the eighteenth to twenty-sixth aspects,
the amplifying transistor may include a gate,
the at least one second peripheral transistor may include a second specific layer that is located in the second peripheral substrate portion and that contains the conductive impurity, and
a concentration of carbon in the second specific layer may be higher than a concentration of carbon in a portion of a surface of the pixel substrate portion, the portion of the surface overlapping the gate in a plan view.

The configuration of the twenty-seventh aspect is an example of a configuration of the imaging device.

In a twenty-eighth aspect of the present disclosure, for example, in the imaging device according to the twenty-sixth or twenty-seventh aspect,
the at least one second peripheral transistor may include a second source, a second drain, and a second extension diffusion layer,
the second extension diffusion layer may be adjacent to the second source or the second drain and shallower than the second source and the second drain, and
the second extension diffusion layer may include the second specific layer.

The configuration of the twenty-eighth aspect is an example of a configuration of the imaging device.

In a twenty-ninth aspect of the present disclosure, for example, in the imaging device according to any one of the twenty-sixth to twenty-eighth aspects,
the at least one second peripheral transistor may include a second source, a second drain, and a second pocket diffusion layer that is adjacent to the second source or the second drain, and
the second pocket diffusion layer may include the second specific layer.

The configuration of the twenty-ninth aspect is an example of a configuration of the imaging device.

In a thirtieth aspect of the present disclosure, for example, in the imaging device according to any one of the twenty-sixth to twenty-ninth aspects,
the at least one second peripheral transistor may include a second source and a second drain, and
at least one selected from the group consisting of the second source and the second drain may include the second specific layer.

The configuration of the thirtieth aspect is an example of a configuration of the imaging device.

In a thirty-first aspect of the present disclosure, for example, in the imaging device according to any one of the eighteenth to thirtieth aspects,
the at least one second peripheral transistor may include a second source, a second drain, and a second extension diffusion layer,
the second extension diffusion layer may be adjacent to the second source or the second drain and shallower than the second source and the second drain, and
the second extension diffusion layer may contain nitrogen.

The configuration of the thirty-first aspect is an example of a configuration of the second peripheral transistor.

In a thirty-second aspect of the present disclosure, for example, in the imaging device according to the thirty-first aspect, the at least one second peripheral transistor may include an N-channel transistor.

The thirty-second aspect may bring about improvement in reliability of the imaging device.

In a thirty-third aspect of the present disclosure, for example, in the imaging device according to any one of the eighteenth to thirty-second aspects,
the at least one first peripheral transistor may include a first peripheral gate insulator film,
the at least one second peripheral transistor may include a second peripheral gate insulator film, and
the first peripheral gate insulator film may be thinner than the second peripheral gate insulator film.

The configuration of the thirty-third aspect is an example of a configuration of the imaging device.

In a thirty-fourth aspect of the present disclosure, for example, in the imaging device according to any one of the eighteenth to thirty-third aspects,
the amplifying transistor may include an amplifying gate insulator film,
the at least one second peripheral transistor may include a second peripheral gate insulator film, and
the amplifying gate insulator film may be thicker than the second peripheral gate insulator film.

The configuration of the thirty-fourth aspect is an example of a configuration of the imaging device.

In a thirty-fifth aspect of the present disclosure, for example, in the imaging device according to any one of the first to thirty-fourth aspects,
the imaging device nay be a front-side illumination imaging device,
the pixel substrate portion may be disposed above the first peripheral substrate portion,
the at least one first peripheral transistor may include a first gate electrode, and the first gate electrode may be located above the first peripheral substrate portion.

The configuration of the thirty-fifth aspect is an example of a configuration of the imaging device.

In a thirty-sixth aspect of the present disclosure, for example, in the imaging device according to any one of the first to thirty-fourth aspects,
the imaging device may be a back-side illumination imaging device,
the pixel substrate portion may be disposed above the first peripheral substrate portion,
the at least one first peripheral transistor may include a first gate electrode, and
the first gate electrode may be located below the first peripheral substrate portion.

The configuration of the thirty-sixth aspect is an example of a configuration of the imaging device.

In a thirty-seventh aspect of the present disclosure, for example, in the imaging device according to any one of the first to thirty-fourth aspects,
the imaging device may be a front-side illumination imaging device,
the pixel substrate portion may be disposed below the first peripheral substrate portion,
the at least one first peripheral transistor may include a first gate electrode, and
the first gate electrode may be located above the first peripheral substrate portion.

The configuration of the thirty-seventh aspect is an example of a configuration of the imaging device.

In a thirty-eighth aspect of the present disclosure, for example, in the imaging device according to any one of the first to thirty-fourth aspects,
the imaging device may be a back-side illumination imaging device,
the pixel substrate portion may be disposed below the first peripheral substrate portion,
the at least one first peripheral transistor may include a first gate electrode, and
the first gate electrode may be located below the first peripheral substrate portion.

The configuration of the thirty-eighth aspect is an example of a configuration of the imaging device.

A manufacturing method according to a thirty-ninth aspect of the present disclosure is a method for manufacturing the imaging device according to any one of the first to thirty-eighth aspects, the method including: fabricating a stacked structure including the pixel substrate portion and the first peripheral substrate portion; and heating the pixel substrate portion in the stacked structure.

The manufacturing method of the thirty-ninth aspect is an example of the method for manufacturing an imaging device.

An imaging device according to a fortieth aspect of the present disclosure includes a pixel region including a pixel substrate portion and an amplifying transistor that is located in the pixel substrate portion and that outputs a signal voltage corresponding to an amount of signal charge and a first peripheral region including a first peripheral substrate portion and at least one first peripheral transistor located in the first peripheral substrate portion. The pixel substrate portion and the first peripheral substrate portion are stacked on each other. When at least one type of impurity including at least one selected from the group consisting of carbon, nitrogen, and fluorine is defined as a specific species, the at least one first peripheral transistor includes a first specific layer that is located in the first peripheral substrate and that contains a conductive impurity and the specific species.

An imaging device according to a forty-first aspect of the present disclosure includes a pixel region including a pixel substrate portion and an amplifying transistor that is located in the pixel substrate portion and that outputs a signal voltage corresponding to an amount of signal charge and a first peripheral region including a first peripheral substrate portion and at least one first peripheral transistor located in the first peripheral substrate portion. The pixel substrate portion and the first peripheral substrate portion are stacked on each other. When at least one type of impurity including at least one selected from the group consisting of germanium, silicon, and argon is defined as a specific species, the at least one first peripheral transistor includes a first specific layer that is located within the first peripheral substrate and that contains a conductive impurity and the specific species.

An imaging device according to a forty-second aspect of the present disclosure includes a pixel region including a pixel substrate portion and an amplifying transistor that is located in the pixel substrate portion and that outputs a signal voltage corresponding to an amount of signal charge and a first peripheral region including a first peripheral substrate portion and at least one first peripheral transistor located in the first peripheral substrate portion. The pixel substrate portion and the first peripheral substrate portion are stacked on each other. The at least one first peripheral transistor includes a first source, a first drain, and a first extension diffusion layer. The first extension diffusion layer is adjacent to the first source or the first drain and shallower than the first source and the first drain. The first extension diffusion layer contains a first impurity and carbon.

An imaging device according to a forty-third aspect of the present disclosure includes a pixel region including a pixel substrate portion and an amplifying transistor, located in the pixel substrate portion, that outputs a signal voltage corresponding to an amount of signal charge and a first peripheral region including a first peripheral substrate portion and at least one first peripheral transistor located in the first peripheral substrate portion. The pixel substrate portion and the first peripheral substrate portion are stacked on each other. The at least one first peripheral transistor includes a first source and a first drain. At least one selected from the group consisting of the first source and the first drain contains a first impurity and carbon.

In the forty-second aspect, the first extension diffusion layer may contain, instead of or in addition to carbon, at least one selected from the group consisting of nitrogen, fluorine, germanium, silicon, and argon. In the forty-third aspect, the first source or the first drain may contain, instead of or in addition to carbon, at least one selected from the group consisting of nitrogen, fluorine, germanium, silicon, and argon. In the forty-second and forty-third aspects, the first impurity is an impurity possessing electrical conductivity.

A description of the after-mentioned conductive impurity may be applied to the first impurity. In the forty-second and forty-third aspects, the term “first impurity” may be read as “conductive impurity”. In the forty-second and forty-third aspects, the term “carbon” may be read as “at least one type of impurity that contributes to inhibition of transient enhanced diffusion of the first impurity”.

An imaging device according to a forty-fourth aspect of the present disclosure includes a pixel region including a pixel substrate portion and an amplifying transistor that is located in the pixel substrate portion and that outputs a signal voltage corresponding to an amount of signal charge and a first peripheral region including a first peripheral substrate portion and at least one first peripheral transistor located in the first peripheral substrate portion. The pixel substrate portion and the first peripheral substrate portion are stacked on each other. The at least one first peripheral transistor includes a high-k metal gate.

In the imaging device, an operating voltage of the first peripheral transistor may be lower than an operating voltage of the second peripheral transistor. In the imaging device, a threshold voltage of the first peripheral transistor may be lower than a threshold voltage of the second peripheral transistor.

In the imaging device, the amplifying transistor may include a gate, a source, and a drain. The first peripheral transistor includes a gate, a source, and a drain. The imaging device may be configured such that the gate of the amplifying transistor is located closer to a position of incidence of incident light on the imaging device than the source of the amplifying transistor and the drain of the amplifying transistor in a direction parallel with a thickness of the imaging device. The imaging device may be configured such that the gate of the first peripheral transistor is located closer to the position of incidence of the incident light on the imaging device than the source of the first peripheral transistor and the drain of the first peripheral transistor in the direction parallel with the thickness of the imaging device.

In the imaging device, the amplifying transistor may include a gate, a source, and a drain. The first peripheral transistor includes a gate, a source, and a drain. The imaging device may be configured such that the source of the amplifying transistor and the drain of the amplifying transistor are located closer to a position of incidence of incident light on the imaging device than the gate of the amplifying transistor in a direction parallel with a thickness of the imaging device. The imaging device may be configured such that the source of the first peripheral transistor and the drain of the first peripheral transistor are located closer to the position of incidence of the incident light on the imaging device than the gate of the first peripheral transistor in the direction parallel with the thickness of the imaging device.

The imaging device may be configured such that the pixel substrate portion is located closer to a position of incidence of incident light on the imaging device than the first peripheral substrate portion in a direction parallel with a thickness of the imaging device.

An imaging device according to another aspect of the present disclosure is an imaging device including:
a pixel region including a first pixel substrate, an impurity region that is located in the first pixel substrate and that accumulates signal charge, a second pixel substrate, and an amplifying transistor that is located in the second pixel substrate and that outputs a signal voltage corresponding to an amount of the signal charge; and
a peripheral region including a first peripheral substrate and a first peripheral transistor located in the first peripheral substrate, wherein
the first pixel substrate, the second pixel substrate, and the first peripheral substrate are stacked in this order from a position of incidence of incident light on the imaging device, and
when at least one type of impurity that contributes to inhibition of transient enhanced diffusion of a conductive impurity is defined as a specific species, the first peripheral transistor includes a first specific layer that is located in the first peripheral substrate and that contains the conductive impurity and the specific species.

In the imaging device, a gate length of the first peripheral transistor may be shorter than a gate length of the amplifying transistor.

A method for manufacturing an imaging device according to an aspect of the present disclosure is a method for manufacturing the imaging device, the method including:
fabricating a stacked structure including the pixel substrate portion and the first peripheral substrate portion; and
heating the stacked structure.

The techniques of the first to forty-fourth aspects may be combined as appropriate, provided no contradictory arises.

The following describes embodiments of the present disclosure in detail with reference to the drawings. It should be noted that the embodiments to be described below each illustrate a comprehensive and specific example. The numerical values, shapes, materials, constituent elements, placement and topology of constituent elements, steps, orders of steps, or other features that are shown in the following embodiments are just a few examples and are not intended to limit the present disclosure. The various aspects described herein may be combined with each other, provided no contradiction arises. Further, those of the constituent elements in the following embodiments which are not recited in an independent claim reciting the most superordinate concept are described as optional constituent elements.

In the following description, constituent elements having substantially the same functions are denoted by common reference signs, and a description of such constituent elements may be omitted. Further, for the avoidance of an overly complex drawing, an illustration of some elements may be omitted. Regarding various elements of an imaging device, dimensions, outward appearances, or other features depicted in the drawings may be different from the dimensions and outward appearances of an actual imaging device. That is, the accompanying drawings are only schematic views for understanding of the present disclosure and do not necessarily rigorously reflect the scale or other features of an actual imaging device.

The term “planar view” or “a plan view” herein means a view as seen from a direction perpendicular to a first semiconductor substrate, a second semiconductor substrate, a third semiconductor substrate, a pixel substrate portion, a first peripheral substrate portion, or a second peripheral substrate portion. Terms such as “above”, “below”, “top”, and “bottom” herein are used to designate the mutual arrangement of members, and are not used to limit the attitude of the imaging device during use.

The expression “substrate”, as in “supporting substrate”, “semiconductor substrate”, or the like, is sometimes used herein. The substrate is not limited to a particular structure or manufacturing method. The substrate may have a single-layer structure or may have a stacked structure. The stacked structure may include, for example, a semiconductor layer, an insulating layer, or other layers. The substrate may be a wafer obtained by slicing an ingot or may be a film deposited by sputtering or other processes. The substrate may be a plate-like body that is used in a chip stacked structure. Further, the substrate may be a plate-like body that is used in a stacked structure that is manufactured by a three-dimensional stacking technology 3DSI (3D Sequential Integration).

The concept “extension diffusion layer” herein encompasses a so-called LDD (lightly-doped drain) diffusion layer.

There is herein an expression “the gate length of a peripheral transistor is shorter than the gate length of a pixel transistor”. This expression may be supplemented with “at least one”, as in “the gate length of at least one peripheral transistor is shorter than the gate length of at least one pixel transistor”. In the expression thus supplemented, all peripheral transistors and pixel transistors that are present in an imaging device satisfy this magnitude relationship. The same applies to an expression regarding a magnitude relationship between the sizes of other elements. The same also applies to a magnitude relationship between the concentrations of impurities such as carbon. The same also applies to a magnitude relationship between an element of a first peripheral transistor and a second peripheral transistor.

### Embodiment of Imaging Device

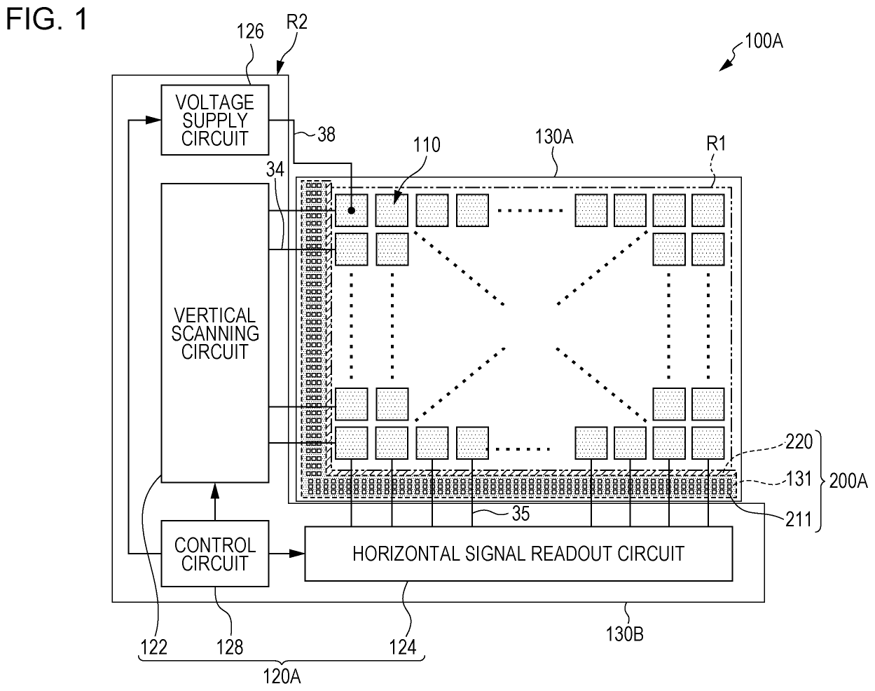

FIG. 1 schematically shows an exemplary configuration of an imaging device according to an embodiment of the present disclosure. An imaging device 100A shown in FIG. 1 has a plurality of pixels 110 arrayed, for example, in a plurality of rows and columns. In the configuration illustrated in FIG. 1, the pixels 110 are arrayed in m rows and n columns and form a pixel region R1 having a substantially rectangular shape. Note here that m and n each independently represent an integer greater than or equal to 1.

As will be mentioned later, in the embodiment of the present disclosure, each of these pixels 110 has a photoelectric converter supported by a semiconductor substrate 130A and a readout circuit formed in the semiconductor substrate 130A and electrically connected to the photoelectric converter. As will be described in detail later with reference to the drawings, each of the plurality of pixels 110 includes an impurity region, provided in the semiconductor substrate 130A, that functions as part of a charge accumulation region that temporarily retains signal charge generated by the photoelectric converter. Note, however, that it is possible to, instead of providing such a photoelectric converter supported by the semiconductor substrate 130A, provide a photodiode as a photoelectric converter in the semiconductor substrate.

The imaging device 100A further has a peripheral circuit 120A that drives the plurality of pixels 110. In the example shown in FIG. 1, the peripheral circuit 120A includes a vertical scanning circuit 122, a horizontal signal readout circuit 124, a voltage supply circuit 126, and a control circuit 128. In the embodiment of the present disclosure, some or all of these circuits are formed in a semiconductor substrate 130B. As schematically shown in FIG. 1, the peripheral circuit 120A is located in a first peripheral region R2 provided in the semiconductor substrate 130B. FIG. 1 shows both the semiconductor substrates 130A and 130B for convenience of explanation. In actuality, the semiconductor substrates 130A and the semiconductor substrate 130B are stacked on top of each other. Specifically, the semiconductor substrates 130A and the semiconductor substrate 130B are stacked with an interlayer insulating layer 90B sandwiched therebetween.

The imaging device 100A further has a blocking region 200A provided outside the pixel region R1 in planar view. As schematically shown in FIG. 1, the blocking region 200A includes an impurity region 131 formed in the semiconductor substrate 130A and a plurality of contact plugs 211 provided over the impurity region 131. The impurity region 131 is typically a P-type diffusion region.

By being provided over the impurity region 131, the plurality of contact plugs 211 are electrically connected to the impurity region 131 of the semiconductor substrate 130A. As will be mentioned later, by being connected to a power source (not illustrated in FIG. 1), the plurality of contact plugs 211 are configured such that a predetermined voltage can be supplied to the impurity region 131. That is, during operation of the imaging device 100A, the impurity region 131 is in a state in which a predetermined voltage is applied to the impurity region 131 via the contact plugs 211.

Further, the blocking region 200A has a device isolation 220. The device isolation 220 is a structure formed in the semiconductor substrate 130A, for example, by a STI (shallow trench isolation) process. The device isolation 220 may be provided in the semiconductor substrate 130A in such a way as to surround the pixel region R1 in top view. The device isolation 220 is equivalent to the shallow trench isolation structure in the present disclosure. It should be noted that the blocking region 200A is not essential.

Details of the circuits constituting the peripheral circuit 120A are given here. The vertical scanning circuit 122 has connections with a plurality of address signal lines 34. These address signal lines 34 are provided separately in correspondence with each of the rows of pixels 110. Each address signal line 34 is connected to one or more pixels 110 belonging to the corresponding row. The vertical scanning circuit 122 controls the timing of readout of signals from the pixels 110 to the after-mentioned vertical signal lines 35 by applying row selecting signals to the address signal lines 34. The vertical scanning circuit 122 is also called “row scanning circuit”. The address signal lines 34 are not the only signal lines that are connected to the vertical scanning circuit 122. Plural types of signal line may be connected to the vertical scanning circuit 122 for each row of pixels 110.

As schematically shown in FIG. 1, the imaging device 100A also has a plurality of vertical signal lines 35. The vertical signal lines 35 are provided separately for each of the columns of pixels 110. Each vertical signal line 35 is connected to one or more pixels 110 belonging to the corresponding column. These vertical signal lines 35 are connected to the horizontal signal readout circuit 124. The horizontal signal readout circuit 124 sequentially outputs signals read out from the pixels 110 to output lines (not illustrated in FIG. 1). The horizontal signal readout circuit 124 is also called “column scanning circuit”.

The control circuit 128 exercises overall control of the imaging device 100A by receiving command data, clocks, or other signals that are supplied, for example, from outside the imaging device 100A. The control circuit 128 typically has a timing generator and supplies driving signals to the vertical scanning circuit 122, the horizontal signal readout circuit 124, the after-mentioned voltage supply circuit 126, or other circuits. In FIG. 1, arrows extending from the control circuit 128 schematically express the flow of outputs signals from the control circuit 128. The control circuit 128 may be implemented, for example, by a microcontroller including one or more processors. The functions of the control circuit 128 may be implemented by a combination of a general-purpose circuit and software, or may be implemented by hardware specialized in such processing.

In the embodiment of the present disclosure, the peripheral circuit 120A includes the voltage supply circuit 126, which is electrically connected to each pixel 110 in the pixel region R1. The voltage supply circuit 126 supplies a predetermined voltage to a pixel 110 via a voltage line 38. The voltage supply circuit 126 is not limited to a particular power-supply circuit. The voltage supply circuit 126 may be a circuit that converts a voltage supplied from a power source such as a battery into a predetermined voltage, or may be a circuit that generates a predetermined voltage. The voltage supply circuit 126 may be part of the aforementioned vertical scanning circuit 122. As schematically shown in FIG. 1, these circuits constituting the peripheral circuit 120A are disposed in the first peripheral region R2.

It should be noted that the number and placement of the pixels 110 are not limited to the illustrated example. For example, the number of pixels 110 that are included in the imaging device 100A may be 1. Although, in this example, the center of each pixel 110 is located at a lattice point of a tetragonal lattice, the plurality of pixels 110 may be placed so that the center of each pixel 110 is located at a lattice point of a triangular lattice, a hexagonal lattice, or other lattices. For example, the pixels 110 may be arrayed one-dimensionally, and in this case, the imaging device 100A may be utilized as a line sensor.

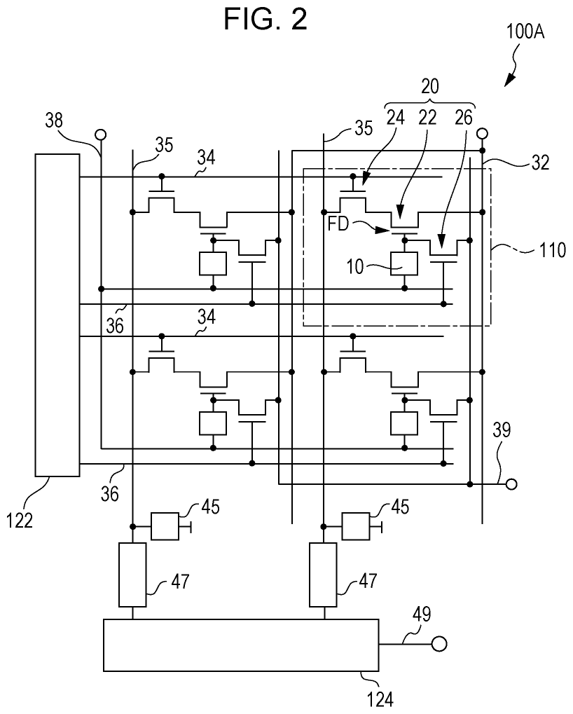

FIG. 2 is a diagram schematically showing an exemplary circuit configuration of the imaging device 100A shown in FIG. 1. For the avoidance of an overly complex drawing, FIG. 2 illustrates only four of the plurality of pixels 110 arrayed in two rows and two columns. Each of these pixels 110 includes a photoelectric converter 10 and a readout circuit 20 electrically connected to the photoelectric converter 10. As will be described in detail with reference to the drawings, the photoelectric converter 10 includes a photoelectric conversion layer disposed above the semiconductor substrate 130A.

By having a connection with the voltage line 38, which is connected to the voltage supply circuit 126, the photoelectric converter 10 of each pixel 110 is configured such that a predetermined voltage can be applied via the voltage line 38 during operation of the imaging device 100A. For example, in a case where of positive and negative charge generated by photoelectric conversion, the positive charge is utilized as signal charge, a positive voltage of, for example, approximately 10 V may be applied to the voltage line 38 during operation of the imaging device 100A. The following illustrates a case where a positive hole is utilized as signal charge.

In the configuration illustrated in FIG. 2, the readout circuit 20 includes an amplifying transistor 22, an address transistor 24, and a reset transistor 26. The amplifying transistor 22, the address transistor 24, and the reset transistor 26 are typically field-effect transistors formed in the semiconductor substrate 130A. Unless otherwise noted, the following describes an example involving the use of N-channel MOSFETs (metal-oxide semiconductor field-effect transistors) as the transistors.

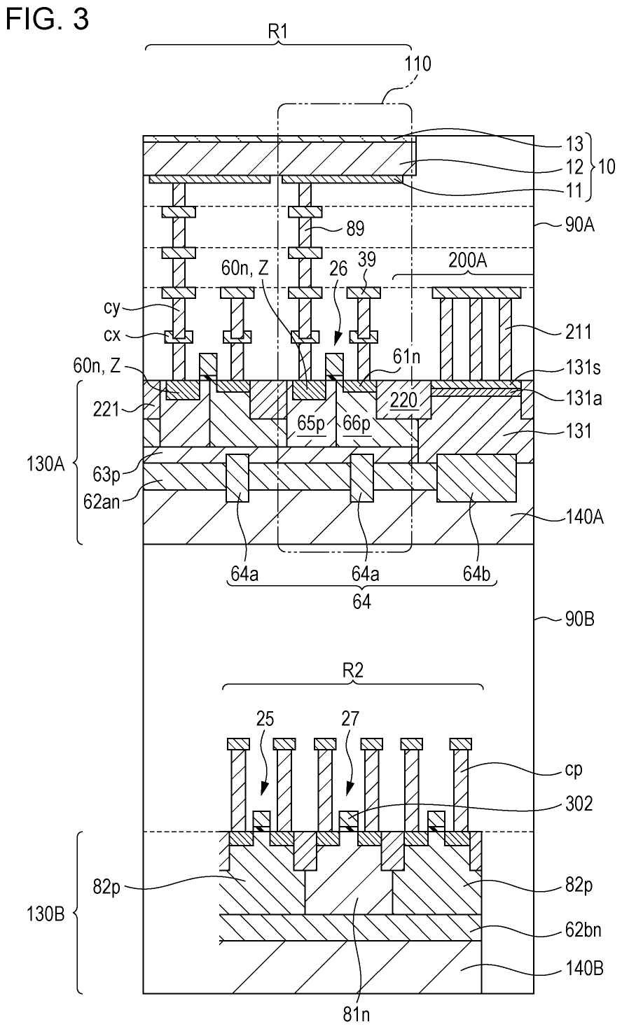

As schematically shown in FIG. 2, the amplifying transistor 22 has its gate electrically connected to the photoelectric converter 10. A positive hole can for example be accumulated as signal charge in a charge accumulation node FD by applying a predetermined voltage to the photoelectric converter 10 of each pixel 110 from the voltage supply circuit 126 via the voltage line 38 during operation. Note here that the charge accumulation node FD is a node at which the gate of the amplifying transistor 22 is connected to the photoelectric converter 10. The charge accumulation node FD has a function of temporarily retaining charge generated by the photoelectric converter 10. The charge accumulation node FD includes as part thereof an impurity region formed in the semiconductor substrate 130A. A charge accumulation region Z shown in FIG. 3, which will be described later, corresponds to the impurity region included in the charge accumulation node FD.

As shown in FIG. 2, the amplifying transistor 22 of each pixel 110 has its drain connected to a power-supply wire 32. The power-supply wire 32 supplies a power-supply voltage VDD of, for example, approximately 3.3 V to the amplifying transistor 22 during operation of the imaging device 100A. On the other hand, the amplifying transistor 22 has its source connected to a vertical signal line 35 via the address transistor 24. By having its drain supplied with the power-supply voltage VDD, the amplifying transistor 22 outputs a signal voltage corresponding to the amount of signal charge accumulated in the charge accumulation node FD.

The address transistor 24, which is connected between the amplifying transistor 22 and the vertical signal line 35, has its gate connected to an address signal line 34. The vertical scanning circuit 122 controls the turning on and turning off of the address transistor 24 by applying a row-selecting signal to the address signal line 34. That is, by controlling a row-selecting signal, the vertical scanning circuit 122 allows an output from the amplifying transistor 22 of a selected pixel 110 to be read out to the corresponding vertical signal line 35. The placement of the address transistor 24 is not limited to the example shown in FIG. 2, and the address transistor 24 may be disposed between the drain of the amplifying transistor 22 and the power-supply wire 32.

Each of the vertical signal lines 35 is connected to a load circuit 45 and a column signal processing circuit 47. The load circuit 45 forms a source-follower circuit with the amplifying transistor 22. The column signal processing circuit 47 executes noise suppression signal processing typified by correlated double sampling, analog-digital conversion, or other processing. The column signal processing circuit 47 is also called “row signal accumulation circuit”. The horizontal signal readout circuit 124 sequentially reads out signals from a plurality of the column signal processing circuit 47 to a horizontal common signal line 49. The column signal processing circuit 47 may be part of the horizontal signal readout circuit 124. The load circuit 45 and the column signal processing circuit 47 may be part of the aforementioned peripheral circuit 120A.

In this example, the readout circuit 20 includes the reset transistor 26 in addition to the amplifying transistor 22 and the address transistor 24. A first one of a drain and a source of the reset transistor 26 is part of the charge accumulation node FD, and a second one of the drain and the source is connected to a reset voltage line 39. The first one of the drain and the source of the reset transistor 26 corresponds to the charge accumulation region Z of FIG. 3 and, specifically, to an impurity region 60n. By having a connection with a reset voltage supply circuit (not illustrated in FIG. 2), the reset voltage line 39 is made able to supply a predetermined reset voltage Vref to the reset transistor 26 of each pixel 110 during operation of the imaging device 100A. As the reset voltage Vref, a voltage of 0 V or nearly 0 V is selected, for example. As is the case with the aforementioned voltage supply circuit 126, the reset voltage supply circuit needs only be able to apply the reset voltage Vref to the reset voltage line 39, and is not limited in specific configuration to a particular power-supply circuit. The reset voltage supply circuit may be part of the vertical scanning circuit 122. The voltage supply circuit 126 and the reset voltage supply circuit may be independent separate circuits, or may be in the form of a single voltage supply circuit disposed in the imaging device 100A. The reset voltage supply circuit too may be part of the aforementioned peripheral circuit 120A.

The reset transistor 26 has its gate connected to a reset signal line 36. As is the case with the address signal lines 34, these reset signal lines 36 are provided separately for each of the rows of pixels 110 and, in this example, are connected to the vertical scanning circuit 122. As mentioned above, by applying row-selecting signals to the address signal lines 34, the vertical scanning circuit 122 can select, on a row-by-row basis, pixels 110 to which signals are to be read out. Similarly, by applying reset signals to the gates of the reset transistors 26 via the reset signal lines 36, the vertical scanning circuit 122 can turn on a selected row of reset transistors 26. The turning on of the reset transistors 26 causes the potentials of the charge accumulation nodes FD to be reset.

FIG. 3 is a schematic a cross-sectional view showing the pixel region R1, the first peripheral region R2, and the blocking region. This is a cross-section of two representative ones of the plurality of pixels 110. The semiconductor substrate 130A and the semiconductor substrate 130B are stacked on top of each other. Specifically, the semiconductor substrates 130A and the semiconductor substrate 130B are stacked with the interlayer insulating layer 90B sandwiched therebetween.

### Pixels and Blocking Region

First, attention is focused on the pixel region R1. The pixel region R1 is provided with a photoelectric conversion layer 12. The photoelectric conversion layer 12 is supported by the semiconductor substrate 130A. Over the photoelectric conversion layer 12, a counter electrode 13 having translucency is disposed. As shown in FIG. 3, the photoelectric conversion layer 12 and the counter electrode 13 are each typically successively provided above the semiconductor substrate 130A across the plurality of pixels 110.

The pixels 110 each include a photoelectric converter 10 serving as a unit structure that constitutes the pixel region R1 and having part of the photoelectric conversion layer 12, part of the counter electrode 13, and a pixel electrode 11. The pixel electrode 11 of the photoelectric converter 10 is located between the photoelectric conversion layer 12 and the semiconductor substrate 130A, and is formed from metal such as aluminum or copper, a metal nitride, polysilicon given electrical conductivity by being doped with an impurity, or other substances. As schematically shown in FIG. 3, the pixel electrode 11 of each pixel 110 is electrically separated from the pixel electrode 11 of another adjacent pixel by spatial separation of one pixel from another.

The photoelectric conversion layer 12 of the photoelectric converter 10 is formed from an organic material or an inorganic material such as amorphous silicon. The photoelectric conversion layer 12 generates positive and negative charge through photoelectric conversion upon receiving incident light via the counter electrode 13. That is, the photoelectric converter 10 has a function of converting light into charge. The photoelectric conversion layer 12 may include a layer composed of an organic material and a layer composed of an inorganic material.

The counter electrode 13 of the photoelectric converter 10 is an electrode formed from a transparent conducting material such as ITO. The term “translucency” herein means allowing passage of at least a portion of light of a wavelength that the photoelectric conversion layer 12 can absorb, and it is not essential to allow passage of light across a range of wavelengths of visible light. Although not illustrated in FIG. 3, the counter electrode 13 has a connection with the aforementioned voltage line 38. Of positive and negative charge generated by photoelectric conversion, the positive charge can be selectively collected by the pixel electrode 11 by, during operation of the imaging device 100A, controlling the potential of the voltage line 38 so that the potential of the counter electrode 13 is for example higher than the potential of the pixel electrode 11. Forming the counter electrode 13 in the shape of a single layer extending across the plurality of pixels 110 makes it possible to apply a predetermined potential to the counter electrode 13 of the plurality of pixels 110 en bloc via the voltage line 38.

Each of the plurality of pixels 110 further includes part of the semiconductor substrate 130A. As schematically shown in FIG. 3, the semiconductor substrate 130A has a plurality of the impurity regions 60n as first impurity regions near a surface thereof. The impurity region 60n functions as a first one of the drain and the source of the reset transistor 26, which is included in the aforementioned readout circuit 20. Further, the semiconductor substrate 130A also has an impurity region 61n serving as a second one of the drain and the source of the reset transistor 26. As schematically shown in FIG. 3, the impurity region 61n is connected to the aforementioned reset voltage line 39 via a polysilicon plug. In this example, the impurity region 60n and the impurity region 61n have an N-type conductivity type. These impurity regions 60n and 61n are typically N-type diffusion regions.

As can be understood from the foregoing, in the semiconductor substrate 130A, a plurality of the readout circuits 20 are formed in correspondence with the plurality of pixels 110. The readout circuit 20 of each pixel is electrically separated from the readout circuit 20 of another pixel by a device isolation 221 provided in the semiconductor substrate 130A.

As shown in FIG. 3, an interlayer insulating layer 90A covering the semiconductor substrate 130A is located between the photoelectric converter 10 and the semiconductor substrate 130A. The interlayer insulating layer 90A generally includes a plurality of insulating layers and a plurality of wiring layers. The plurality of wiring layers disposed in the interlayer insulating layer 90A may include a wiring layer having the address signal lines 34, the reset signal lines 36, or other wires as part thereof, a wiring layer having the vertical signal line 35, the power-supply wire 32, the reset voltage line 39, or other wires as part thereof, or other wiring layers. The numbers of insulating layers and wiring layers in the interlayer insulating layer 90A are not limited to this example but may be arbitrarily set.

The interlayer insulating layer 90A has provided therein a conducting structure 89 electrically connecting the pixel electrode 11 of the photoelectric converter 10 to the readout circuit 20, which is formed in the semiconductor substrate 130A. As schematically shown in FIG. 3, the conductive structure 89 includes a wire and a via that are disposed in the interlayer insulating layer 90A. The wire and the via are typically formed from metal such as copper or tungsten or a metal compound such as a metal nitride or a metal oxide. The conductive structure 89 also includes a contact plug cx connected to the aforementioned impurity region 60n. The contact plug cx, which is connected to the impurity region 60n, is typically a polysilicon plug, and is doped with an impurity such as phosphorus for superior electrical conductivity. Although not illustrated in FIG. 3, the conductive structure 89 also has an electrical connection with the gate electrode of the amplifying transistor 22. A plug cy is connected to the contact plug cx. Examples of metal that the plug cy may contain include tungsten and copper.

Attention is focused on the semiconductor substrate 130A. The semiconductor substrate 130A includes a supporting substrate 140A and one or more semiconductor layer formed over the supporting substrate 140A. In the example shown in FIG. 3, the semiconductor substrate 130A has an N-type semiconductor layer 62an provided over the supporting substrate 140A. The following takes a P-type silicon substrate as an example of the supporting substrate 140A. The supporting substrate 140A may have a lower electric resistivity than the semiconductor layer 62an. The semiconductor substrate 130A may be an SOI (silicon-on-insulator) substrate, a substrate having a semiconductor layer provided on a surface thereof by epitaxial growth or other processes, or other substrates. It should be noted that the after-mentioned semiconductor substrates 130B and 130C too may have features that are similar to those of the semiconductor substrate 130A.

Attention is focused on the pixel region R1 first in the configuration illustrated in FIG. 3. The semiconductor substrate 130A has the N-type semiconductor layer 62an over the supporting substrate 140A and a P-type semiconductor layer 63p over the N-type semiconductor layer 62an. During operation of the imaging device 100A, the potential of the N-type semiconductor layer 62an is controlled via a well contact (not illustrated in FIG. 3). Since the N-type semiconductor layer 62an, which is located in the pixel region R1, is provided inside the semiconductor substrate 130A, the flow of a small number of carriers from the supporting substrate 140A or the peripheral circuit into a charge accumulation region that accumulates signal charge can be reduced.

In the configuration illustrated in FIG. 3, the semiconductor substrate 130A further has a P-type semiconductor layer 66p located over the P-type semiconductor layer 63p and a P-type impurity region 65p formed in the P-type semiconductor layer 66p. In this example, the aforementioned impurity region 60n, which has a connection with the conductive structure 89, is provided in the P-type impurity region 65p. A junction capacitor that is formed by a p-n junction between the impurity region 60n and the P-type impurity region 65p, which serves as a P well, functions as a capacitor that stores at least a portion of signal charge that is collected by the pixel electrode 11. That is, the impurity region 60n constitutes a charge accumulation region that temporarily retains signal charge. On the other hand, the impurity region 61n is provided in the P-type semiconductor layer 66p. In this example, the P-type impurity region 65p is lower in impurity concentration than the P-type semiconductor layer 66p.

Further, the semiconductor substrate 130A has a plurality of P-type regions 64 provided in the semiconductor substrate 130A in such a way as to pass completely through the N-type semiconductor layer 62an. The P-type regions 64 has a comparatively high impurity concentration. Providing the P-type regions 64 inside the semiconductor substrate 130A makes it possible to electrically connect two regions of the same conductivity type separated from each other by the N-type semiconductor layer 62an.

In this example, the plurality of P-type regions 64 include a plurality of P-type regions 64a located in the pixel region R1 when seen from a direction normal to the semiconductor substrate 130A and one or more p-type regions 64b located below the plurality of contact plugs 211 of the blocking region 200A. The P-type regions 64a are formed between the P-type semiconductor layer 63p and the supporting substrate 140A in such a way as to pass completely through the N-type semiconductor layer 62an, and have a function of electrically connecting the P-type semiconductor layer 63p to the supporting substrate 140A. On the other hand, the P-type region 64b is electrically connected to the impurity region 131 of the blocking region 200A by having one end reaching the impurity region 131, and electrically connects the impurity region 131 to the supporting substrate 140A.

Accordingly, in this example, an electrical path leading from the impurity region 131 of the blocking region 200A to the P-type semiconductor layer 63p via the P-type region 64b, the supporting substrate 140A, and the P-type regions 64a is formed in the semiconductor substrate 130A. As mentioned above, the plurality of contact plugs 211 are connected to the impurity region 131 of the blocking region 200A, and these contact plugs 211 are configured to be connectable to a power source (not illustrated) such as a ground. For example, the potential of the impurity region 131 of the blocking region 200A can be grounded via the plurality of contact plugs 211. Connecting an appropriate power source to the plurality of contact plugs 211 of the blocking region 200A makes it possible to control the potentials of the P-type impurity region 65p and the P-type semiconductor layer 66p via the P-type semiconductor layer 63p by utilizing an electrical path including the impurity region 131, the P-type region 64b, the supporting substrate 140A, and the P-type regions 64a.

In the example shown in FIG. 3, an impurity region 131a that is relatively high in impurity concentration is formed in a portion of the impurity region 131 located near the surface of the semiconductor substrate 130A. Providing the impurity region 131a, which is relatively high in impurity concentration in the impurity region 131, and connecting the plurality of contact plugs 211 to the impurity region 131a brings about an effect of reducing contact resistance between the plurality of contact plugs 211 and the impurity region 131.

Furthermore, in this example, a silicide layer 131s is formed between the plurality of contact plugs 211 and the impurity region 131. Providing the silicide layer 131s in a portion of the impurity region 131a near the surface of the semiconductor substrate 130A and connecting the plurality of contact plugs 211 to the silicide layer 131s makes it possible to further reduce the contact resistance.

Next, attention is focused on the first peripheral region R2 of the semiconductor substrate 130B. As mentioned above, a circuit for driving the plurality of pixels 110 and a circuit for processing signals read out from the plurality of pixels 110 are formed in the first peripheral region R2. The first peripheral region R2 includes, for example, a plurality of transistors 25 and a first peripheral transistor 27 that constitute a logic circuit such as a multiplexer. As schematically shown in FIG. 3, in this example, an N-type semiconductor layer 62bn is formed over the supporting substrate 140B, and an N-type impurity region 81n and a P-type impurity region 82p are formed as wells over the N-type semiconductor layer 62bn. Each of the transistors 25 has its drain and source located in the P-type impurity region 82p, and the first peripheral transistor 27 has its drain and source located in the N-type impurity region 81n. The N-type semiconductor layer 62bn is supplied with a predetermined voltage by being connected to a power source (not illustrated). The following takes a P-type silicon substrate as an example of the supporting substrate 140B. In the following, the N-type impurity region 81n is sometimes referred to as “N-type well”.

The depth of the N-type semiconductor layer 62an of the pixel region R1 and the depth of the N-type semiconductor layer 62bn of the first peripheral region R2 may be equal to or different from each other.

In the configuration illustrated in FIG. 3, contact plugs cp are connected to the drain, source, and gate electrodes of peripheral transistors such as the transistors 25 and the first peripheral transistor 27.

Each of the impurity layers and impurity regions located above the supporting substrate 140A is formed by ion implantation of an impurity into a semiconductor layer obtained by epitaxial growth over the supporting substrate 140A. The p-type regions 64a, which is located in the pixel region R1, of the p-type region 64 may be formed in places that do not overlap the device isolation in the pixels in planar view.

Similarly, each of the impurity layers and impurity regions located above the supporting substrate 140B is formed by ion implantation of an impurity into a semiconductor layer obtained by epitaxial growth over the supporting substrate 140B.

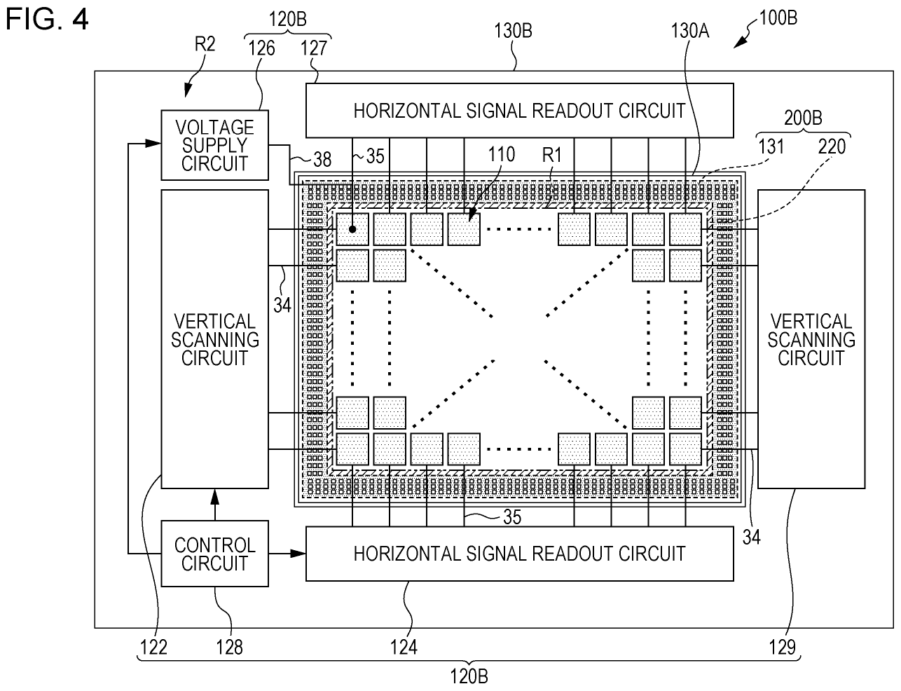

FIG. 4 shows another example of the shape of a blocking region. An imaging device 100B shown in FIG. 4 differs from the imaging device 100A shown in FIG. 1 in that instead of the blocking region 200A, the imaging device 100B has a blocking region 200B surrounding the pixel region R1 in the shape of a rectangle. As compared with the aforementioned blocking region 200A, the impurity region 131 of the blocking region 200B surrounds the pixel region R1 in seamless manners in a circular pattern in planar view. As schematically shown in FIG. 4, in this example too, the plurality of contact plugs 211 are connected to the impurity region 131. In this example, the device isolation 220 of the blocking region 200B too surrounds the pixel region R1 in seamless manners in a circular pattern inside the impurity region 131. As is the case with FIG. 1, FIG. 4 shows both the semiconductor substrates 130A and 130B for convenience of explanation. In actuality, the semiconductor substrates 130A and the semiconductor substrate 130B are stacked on top of each other. Specifically, the semiconductor substrates 130A and the semiconductor substrate 130B are stacked with an interlayer insulating layer 90B sandwiched therebetween.

In this example, a peripheral circuit 120B provided in the first peripheral region R2 includes a second vertical scanning circuit 129 and a second horizontal signal readout circuit 127 in addition to the vertical scanning circuit 122, the horizontal signal readout circuit 124, the voltage supply circuit 126, and the control circuit 128. As illustrated, to the vertical scanning circuit 129 too, address signal lines 34 provided separately in correspondence with each of the rows of pixels 110 are connected.

For example, the vertical scanning circuit 122 is responsible for a row-selecting operation on pixels in the left half of the pixel; region R1, and the vertical scanning circuit 129 is responsible for a row-selecting operation on pixels in the right half of the pixel region R1. Further, the horizontal signal readout circuit 124 is responsible for processing of signals read out from pixels in the lower half of the pixel region R1, and the horizontal signal readout circuit 127 is responsible for processing of signals read out from pixels in the upper half of the pixel region R1. By thus partitioning the pixel region R1 and executing a readout of signals through a plurality of vertical scanning circuits and horizontal signal readout circuits, the speeding up of operations, such as the shortening of frame rates, can be achieved.

Forming the blocking region 200B in the semiconductor substrate 130A in a shape that surrounds the pixel region R1, which includes an array of pixels 110, in planar view makes it possible to more effectively inhibit migration of charge between charge accumulation regions of the pixels and the outside of the pixel region R1. It is not essential in the embodiment of the present disclosure that a blocking region surround the pixel region R1 in seamless manners in a circular pattern in planar view. For example, a blocking region may include a plurality of portions each including a device isolation 220 and an impurity region 131, and the plurality of portions may be disposed as a whole to surround the pixel region R1. Such a configuration too is expected to bring about effects which are similar to those which are brought about in a case where a blocking region is provided in such a way as to surround the pixel region R1 in seamless manners in a circular pattern in planar view. Further, the blocking region 200B is not indispensable.

### Transistor of First Peripheral Region R2

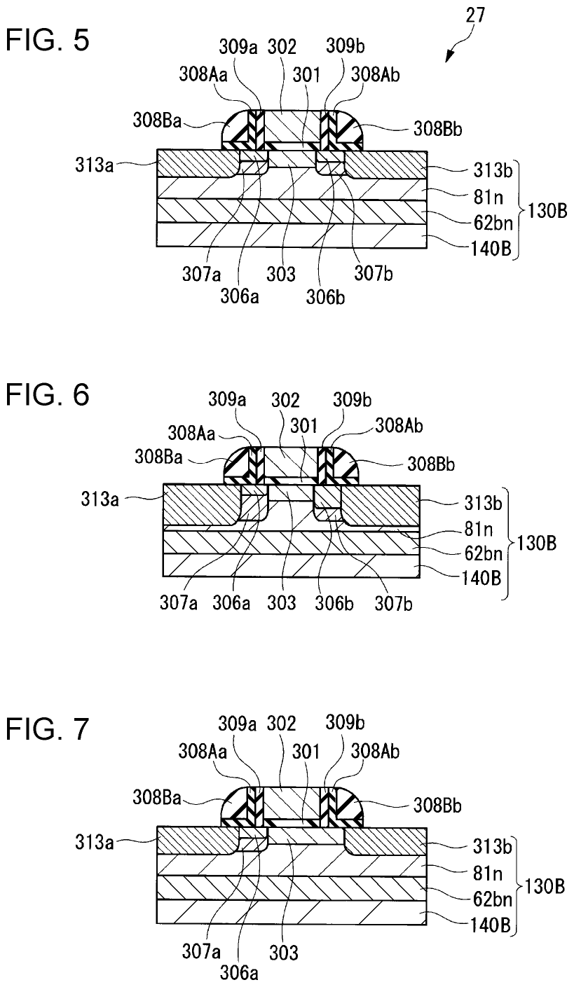

As noted above, the first peripheral region R2 includes the first peripheral transistor 27. The following describes a configuration example of the first peripheral transistor 27 according to the embodiment with reference to FIGS. 5 to 12B.

FIG. 5 shows a cross-sectional configuration of a first peripheral transistor 27 according to a first configuration example. This first peripheral transistor 27 is specifically a MIS transistor, more specifically a MOSFET.

As shown in FIG. 5, for example, a gate insulator film 301 composed of silicon oxide (SiO₂) is interposed between a principal surface of a semiconductor substrate 130B composed of P-type silicon (Si) and a gate electrode 302 composed of polysilicon or gate metal and formed over the principal surface. The semiconductor substrate 130B has formed in an upper part thereof an N-channel diffusion layer 303 in which, for example, arsenic (As) is diffused and the N-type impurity region 81n, which is an N-type well in which, for example, arsenic (As) and phosphorus (P) are diffused and that is greater in junction depth than the N-type channel diffusion layer 303. In the semiconductor substrate 130B, the supporting substrate 140B, the N-type semiconductor layer 62bn, and the N-type impurity region 81n, which is an N-type well, are stacked in this order.

In gate lengthwise regions in the N-type channel diffusion layer 303, i.e. regions in which a source and a drain are formed, first extension diffusion layers 306a and 306b and first pocket diffusion layers 307a and 307b under the first extension diffusion layers 306a and 306b are formed, respectively. The first extension diffusion layers 306a and 306b are P-type extension high-concentration diffusion layers, formed by diffusion of, for example, boron (B), which is a P-type impurity, that have comparatively shallow junctions. The first pocket diffusion layers 307a and 307b are N-type pocket diffusion layers formed by diffusion of, for example, arsenic (As), which is an N-type impurity.

The first extension diffusion layers 306a and 306b, which are P-type extension high-concentration diffusion layers, contain carbon (C).

In the present configuration example, carbon is used to inhibit the diffusion of boron, and for this reason, the first extension diffusion layers 306a and 306b are shallow in impurity profile and keep steep and high activation concentrations. This causes a low-resistance extension diffusion layer with a shallow junction depth to be formed, making it possible to achieve a fine device having high driving force.

Incidentally, the first peripheral region R2 may be heated by heat in the process of manufacturing an imaging device. However, the aforementioned diffusion-inhibiting action derived from carbon inhibits the redistribution of the conductive impurity in the first peripheral transistor 27 of the first peripheral region R2 even in a case where the first peripheral region R2 is heated by such heat, making it possible to maintain the shallow junction.

A description is given with a specific example. In the process of manufacturing a stacked semiconductor device, a stacked structure may be obtained by forming a lower transistor layer and forming an upper transistor layer contiguous to the lower transistor layer. In this case, the lower transistor layer is affected by thermal processing of the upper transistor layer. The performance of the lower transistor layer may be secured by improving the heat resistance of the lower transistor layer in consideration of “additional” heat that is applied to the lower transistor layer by the thermal processing of the upper transistor layer. Let thought be given here to a situation in which the stacked semiconductor device corresponds to the imaging device 100A, the lower transistor layer corresponds to the first peripheral region R2, and a transistor of the lower transistor layer corresponds to the first peripheral transistor 27. In this situation, the diffusion-inhibiting action on the conductive impurity by carbon inhibits the redistribution of the conductive impurity in the first peripheral transistor 27 of the first peripheral region R2 even in a case where the first peripheral region R2 is heated by the aforementioned “additional” heat, making it possible to maintain the shallow junction.

Further, the inclusion of carbon in the first extension diffusion layers 306a and 306b also brings about an effect of reducing the occurrence of residual defects in the first extension diffusion layers 306a and 306b. Examples of residual defects include EOR (end-of-range; hereinafter abbreviated as “EOR”) defects. The term “EOR defect” here refers to a defect layer that is formed in a region just below an original amorphous/crystal (a/c) interface before thermal processing in a case where the semiconductor substrate 130B, which is composed of silicon, is subjected to thermal processing in an amorphized state.

Further, carbon implantation is executed in order to inhibit boron-induced transient enhanced diffusion (hereinafter abbreviated as “TED”). Carbon forms, for example, carbon-interstitial silicon complexes or clusters with excess point defects, which induce TED, and thereby reduces excess point defects. Further, in consideration of the fact that excess point defects may grow to generate secondary defects such as dislocation loops, it can be said that carbon reduces crystal defects. By thus using, in the extension formation regions of the semiconductor substrate 130B, crystal layers with reduced generation of residual defect layers such as secondary defects, even the occurrence of junction leaks due to residual defect layers can be reduced.

Further, in regions in the semiconductor substrate 130B outside the first extension diffusion layers 306a and 306b, a P-type source diffusion layer 313a and a P-type drain diffusion layer 313b are formed. The P-type source diffusion layer 313a and the P-type drain diffusion layer 313b are connected to the first extension diffusion layers 306a and 306b, and are greater in junction depth than the first extension diffusion layers 306a and 306b. In the present configuration example, the P-type source diffusion layer 313a and the P-type drain diffusion layer 313b contain carbon (C). Note, however, that either or both the P- P-type source diffusion layer 313a or/and the P-type drain diffusion layer 313b may not contain carbon (C).

On both side surfaces of the gate electrode 302, offset spacers 309a and 309b having insulation properties are formed. The offset spacers 309a and 309b contain carbon. Furthermore, first side walls 308Aa and 308Ab with L-shaped cross-sections are formed over the semiconductor substrate 130B. The first side walls 308Aa and 308Ab extend from over outer side surfaces of the offset spacers 309a and 309b to upper portions of inner ends of the P-type source diffusion layer 313a and the P-type drain diffusion layer 313b, respectively. Further, second side walls 308Ba and 308Bb having insulation properties are formed on outer sides of the first side walls 308Aa and 308Ab, respectively.

In the first configuration example, arsenic ions are used as the impurity of the N-type channel diffusion layer 303. Alternatively, ions of an element that are larger in mass than arsenic ions and that exhibit an N type or both arsenic ions and ions of an element that are larger in mass than the arsenic ions and that exhibit an N type may be used.

Further, carbon is not the only impurity that contributes to inhibition of TED. Instead of or in combination with carbon, at least one selected from the group consisting of nitrogen, fluorine, germanium, silicon, and argon may be used. Nitrogen, fluorine, germanium, silicon, argon, or other impurities may contribute to inhibition of TED. Specifically, as is the case with carbon, impurities such as nitrogen and fluorine form, for example, impurity-interstitial silicon or impurity-vacancy complexes or clusters with excess point defects, which induce TED, and thereby reduce excess point defects. Specifically, excess point defects are reduced by the formation of, for example, carbon-interstitial silicon, nitrogen-interstitial silicon, fluorine-interstitial silicon, and fluorine-vacancy complexes. Germanium, silicon, argon, or other impurities contribute to inhibition of TED through the pre-amorphization of substrate. Besides, at least one selected from among non-conducting elements in the group consisting of elements in groups 14, 17, and 18 may be used as an impurity that contributes to inhibition of TED.

Further, although, in the first configuration example, the transistor is a P-channel MIS transistor, the transistor may alternatively be an N-channel MIS transistor. In the case of an N-channel MIS transistor, phosphorus (P) ions, arsenic (As) ions, or ions of a Group 5B element that are larger in mass than arsenic ions, such as antimony (Sb) ions or bismuth (Bi) ions, can be used as N-type impurity ions that constitute extension diffusion layers. Further, in the case of an N-channel MIS transistor, for example, boron (B) ions, ions of a Group III element that are larger in mass than boron ions, such as indium (In) ions, or a combination thereof can be used as P-type pocket diffusion layers. This makes it possible to reduce variations in threshold voltage attributed to pocket profiles, as carbon inhibits TED of the P-type pocket diffusion layers. As the N-type impurity ions that constitute extension diffusion layers, one type of the aforementioned impurities or a combination of two or more types of the aforementioned impurities may be used. The same applies to the elements that are used in the P-type pocket diffusion layers.

### First Modification of First Configuration Example

FIG. 6 shows a cross-sectional configuration of a transistor according to a first modification of the first configuration example. In the transistor according to the first modification, as shown in FIG. 6, the impurity profiles of the first extension diffusion layers 306a and 306b, which are P-type extension high-concentration diffusion layers, are bilaterally asymmetric with respect to the gate electrode 302. Making a source region shallower and steeper in extension profile than a drain region as shown in FIG. 6 effect an increase in carrier concentration gradient between the source region and a channel region, bringing about improvement in driving force in the MIS transistor. Further, since the drain region is deeper in extension profile than the source region, less hot carriers are generated than in a symmetrical, shallow, and steep profile structure. It should be noted that a transistor having the configuration of FIG. 6 may be fabricated, for example, with reference to Japanese Patent No. 5235486.

In the example shown in FIG. 6, the first extension diffusion layer 306a is shallower than the first extension diffusion layer 306b. Note, however, that a configuration in which the first extension diffusion layer 306b is shallower than the first extension diffusion layer 306a may be adopted.

### Second Modification of First Configuration Example

FIG. 7 shows a cross-sectional configuration of a transistor according to a second modification of the first configuration example. As shown in FIG. 7, the transistor according to the second modification has a P-type extension high-concentration diffusion layer beside only either the P-type source diffusion layer 313a or the P-type drain diffusion layer 313b.

In the example shown in FIG. 7, the transistor according to the second modification has the first extension diffusion layer 306a as a P-type extension high-concentration diffusion layer that is adjacent to the P-type source diffusion layer 313a and, meanwhile, does not have a first extension diffusion layer that is adjacent to the P-type drain diffusion layer 313b. Note, however, that a configuration in which the transistor does not have a first extension diffusion layer that is adjacent to the P-type source diffusion layer 313a and, meanwhile, has the first extension diffusion layer 306b adjacent to the P-type drain diffusion layer 313b may be adopted.

Further, as shown in FIG. 7, the transistor according to the second modification has an N-type pocket diffusion layer beside only either the P-type source diffusion layer 313a or the P-type drain diffusion layer 313b. Specifically, the transistor according to the second modification has the first N-pocket diffusion layer 307a adjacent to the P-type source diffusion layer 313a and, meanwhile, does not have a first pocket diffusion layer that is adjacent to the P-type drain diffusion layer 313b. Note, however, that a configuration in which the transistor does not have a first pocket diffusion layer that is adjacent to the P-type source diffusion layer 313a and, meanwhile, has the first pocket diffusion layer 307b adjacent to the P-type drain diffusion layer 313b may be adopted.

### Third Modification of First Configuration Example

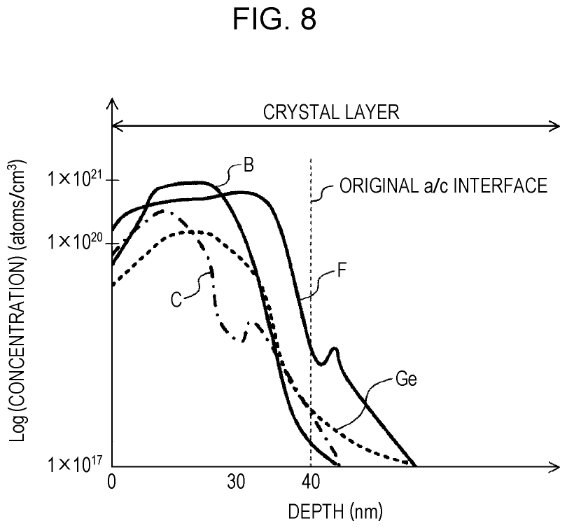

In a third modification of the first configuration example, the P-type source diffusion layer 313a and the P-type drain diffusion layer 313b contain fluorine (F) and carbon (C). Fluorine may bring about partial amorphization of the semiconductor substrate 130B. Further, fluorine may inhibit transient enhanced diffusion (TED) of impurities. FIG. 8 shows examples of concentration distributions of impurities in the P-type source diffusion layer 313a and the P-type drain diffusion layer 313b in a direction parallel with the depth of the semiconductor substrate 130B. The vertical axis represents the concentrations of fluorine (F), carbon (C), boron (B), and germanium (Ge) on a log scale. The concentration distributions of FIG. 8 relate to a case where fluorine is implanted for amorphization and inhibition of the diffusion of the impurities and diffused during annealing. In the examples shown in FIG. 8, the concentration distribution of fluorine has segregation near the original position of the a/c interface.

According to the third modification, the diffusion of the impurities is inhibited after the aforementioned annealing. Further, even if the first peripheral region R2 is heated during thermal processing for the pixel region R1, redistributions of the conductive impurities may fall within narrow ranges.

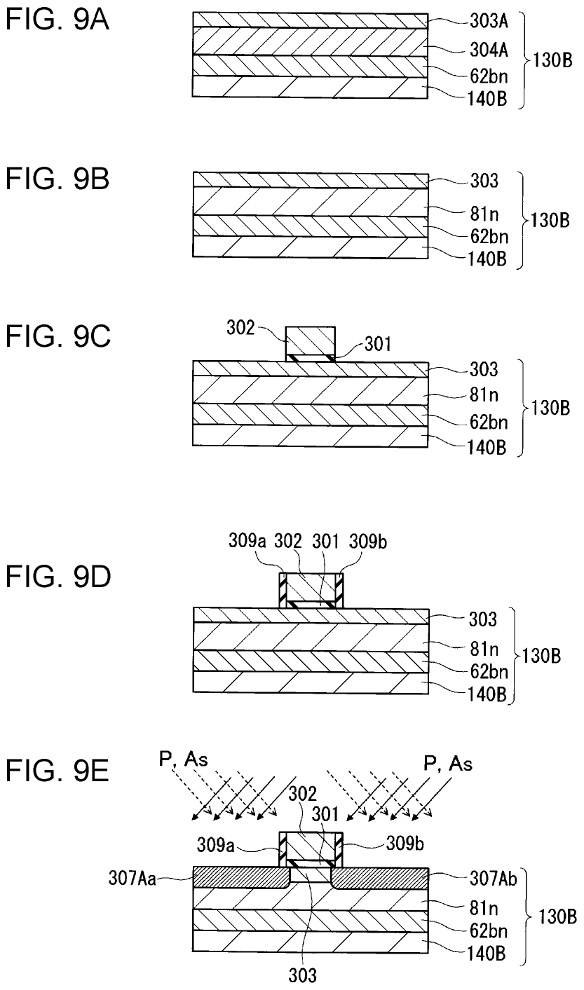

The following describes a method for manufacturing a transistor shown in FIG. 5 with reference to FIGS. 9A to 11C. FIGS. 9A to 11C are cross-sectional views showing a method for manufacturing a transistor shown in FIG. 5. It should be noted that the following omits to describe a method for fabricating the N-type semiconductor layer 62bn. The N-type semiconductor layer 62bn can be fabricated by a publicly-known method.

FIGS. 9A to 9E, FIGS. 10A to 10D, and FIGS. 11A to 11C show cross-sectional configurations in the order of steps of a method for manufacturing a MIS transistor according to the first configuration example.

First, as shown in FIG. 9A, an N-type well impurity-implanted layer 304A is formed by implanting N-type impurity ions, e.g. phosphorus (P) ions, twice into a channel formation region of a semiconductor substrate 130B composed of P-type silicon. The first round of ion implantation involves an implantation energy of 260 keV and an implantation dose amount of 4×10¹²/cm², and the second round of ion implantation involves an implantation energy of 540 keV and an implantation dose amount of 1×10¹³/cm². After that, an N-type channel impurity-implanted layer 303A is formed on top of the N-type well impurity-implanted layer 304A by implanting arsenic (As) ions into the semiconductor substrate 130B with an implantation energy of approximately 90 keV and in an implantation dose amount of approximately 5×10¹²/cm². At this point in time, the ion implantation may be preceded by deposition of a silicon oxide film on a surface of the semiconductor substrate 130B. It should be noted that the N-type well impurity-implanted layer 304A and the N-type channel impurity-implanted layer 303A may be formed in any order.

Next, as shown in FIG. 9B, the semiconductor substrate 130B thus ion-implanted is subjected to first rapid thermal processing (RTA) that raises the temperature to approximately to 850° C. to 1050° C. at a temperature rise rate higher than or equal to approximately 100° C./sec. e.g. approximately 200° C./sec, and keeps the peak temperature for a maximum of approximately ten seconds or does not keep the peak temperature. This first rapid thermal processing causes the N-type channel diffusion layer 303 and the N-type impurity region 81n, which is an N-type well, to be formed in the upper part of the semiconductor substrate 130B. It should be noted that the rapid thermal processing that does not keep the peak temperature refers to thermal processing in which the thermal processing temperature drops at the same time as it reaches the peak temperature.

Next, as shown in FIG. 9C, a gate insulator film 301 composed of silicon oxide with a film thickness of approximately 1.5 nm is selectively formed on top of the semiconductor substrate 130B, and a gate electrode 302 composed of polysilicon with a film thickness of approximately 100 nm is selectively formed on top of the gate insulator film 301. Although the gate insulator film 301 is composed of silico oxide here, the gate insulator film 301 may be a high-k insulator film composed of silicon oxynitride (SiON), hafnium oxide (HfOₓ), hafnium-silicon-oxynitride (HfSiON), or other substances. Further, instead of being composed of polysilicon, the gate electrode 302 may be composed of a metal gate, a film stack of polysilicon and a metal gate, silicide-topped polysilicon, or fully silicided polysilicon.

Next, as shown in FIG. 9D, an insulator film composed of silicon oxide with a film thickness of approximately 8 nm is deposited, and then the offset spacers 309a and 309b are formed by anisotropic etching on both side surfaces of the gate electrode 302 and the gate insulator film 301 with a finish thickness of approximately 4 nm. Although the offset spacers 309a and 309b are composed of silicon oxide here, the offset spacers 309a and 309b may be high-k insulator films composed of silicon nitride (SiN), HfO₂, or other substances.

Next, as shown in FIG. 9E, an N-type impurity, e.g. phosphorus (P) ions, is implanted into the semiconductor substrate 130B with an implantation energy of approximately 40 keV and in an implantation dose amount of approximately 2×10¹³/cm² with the offset spacer 309a and 309b and the gate electrode 302 as masks. Then, N-type pocket impurity-implanted layers 307Aa and 307Ab are formed by angularly implanting an N-type impurity, e.g. arsenic (As) ions, with an implantation energy of approximately 80 keV and in an implantation dose amount of approximately 1×10¹³/cm². Note here that the P ions and the As ions may be implanted in any order.

In this example, both the P ions and the As ions are implanted into the N-type pocket impurity-implanted layers 307Aa and 307Ab. Note, however, that only either the P ions or the As ions may be implanted into the N-type pocket impurity-implanted layers 307Aa and 307Ab.

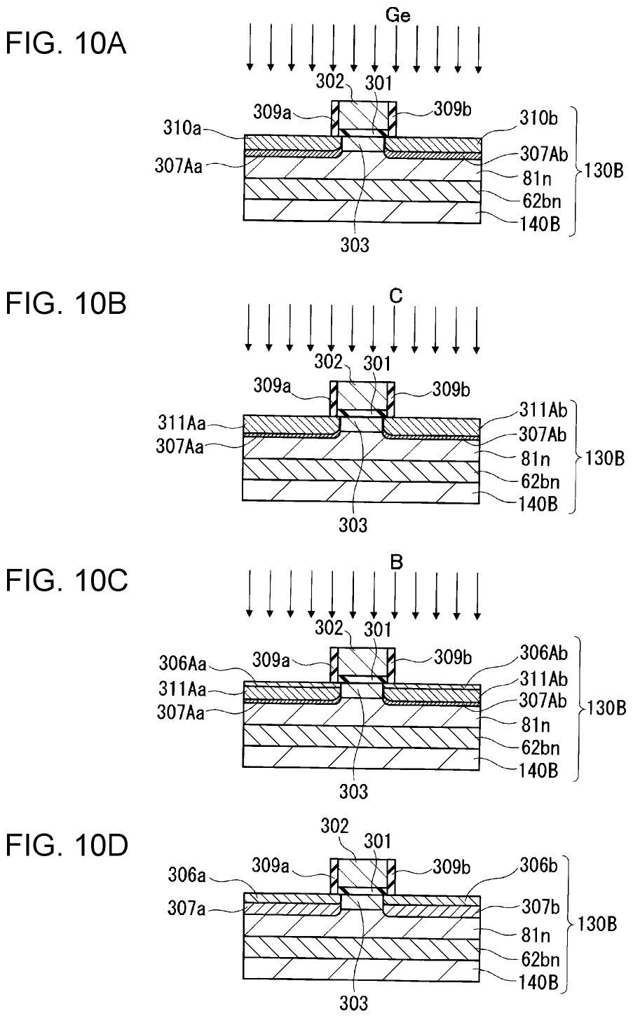

Next, as shown in FIG. 10A, amorphous layers 310a and 310b are selectively formed in the semiconductor substrate 130B by implanting germanium (Ge) ions into the semiconductor substrate 130B with an implantation energy of approximately 10 keV and in an implantation dose amount of approximately 5×10¹⁴/cm² with the offset spacer 309a and 309b and the gate electrode 302 as masks. Although the amorphous layers 310a and 310b are formed of germanium here, they may be formed of silicon (Si), argon (Ar), krypton (Kr), xenon (Xe), carbon (C), or other substances.

Next, as shown in FIG. 10B, with the amorphous layers 310a and 310b formed, carbon-implanted layers 311Aa and 311Ab are formed by implanting carbon (C) ions into the semiconductor substrate 130B with an implantation energy of approximately 5 keV and in an implantation dose amount of approximately 1×10¹⁵/cm² with the offset spacer 309a and 309b and the gate electrode 302 as masks. The carbon ions need only be implanted, for example, with the implantation energy falling within a range of 1 keV to 10 keV and with the implantation dose amount falling within a range of 1×10¹⁴/cm² to 3×10¹⁵/cm². At this point in time, molecular ions of carbon-containing molecules such as C₅H₅ or C₇H₇ may be used instead of the carbon ions. Further, nitrogen ions, fluorine ions, or other ions may be used instead of the carbon ions, which are impurity ions for use in the prevention of diffusion. Further, in a case where carbon or carbon-containing molecular ions are used instead of germanium in the formation of the amorphous layers 310a and 310b, the step of forming the amorphous layers 310a and 310b and the step of forming the carbon-implanted layers 311Aa and 311Ab may be executed simultaneously. Further, the semiconductor substrate 130B may be amorphized during pocket implantation by using ions with a comparatively large mass number, such as antimony (Sb), in N-type pocket impurity implantation.

Next, as shown in FIG. 10C, first P-type impurity-implanted layers 306Aa and 306Ab are formed on top of the carbon-implanted layers 311Aa and 311Ab by implanting a P-type impurity, e.g. boron (B) ions, into the semiconductor substrate 130B with an implantation energy of approximately 0.5 keV and in an implantation dose amount of approximately 5×10¹⁴/cm² with the offset spacer 309a and 309b and the gate electrode 302 as masks. Instead of boron, boron difluoride (BF₂), boron clusters such as B₁₈Hₓ or B₁₀Hₓ, or indium (In) may be used.

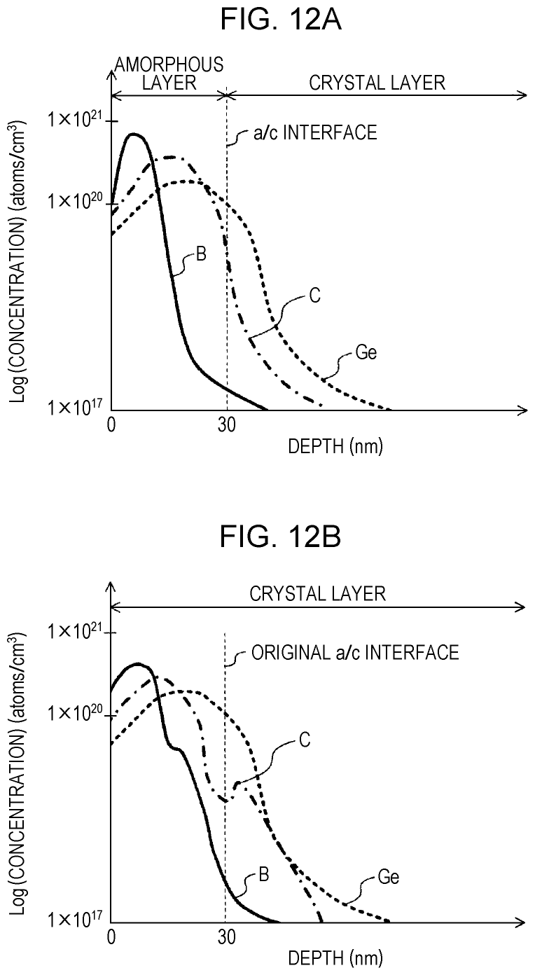

FIGS. 12A and 12B are graphs showing in-depth impurity profiles in extension formation regions according to FIG. 5. FIG. 12A shows, on a log scale, concentration distributions (impurity profiles) of impurities (boron (B), carbon (C), and germanium (Ge)) immediately after boron ion implantation in a direction parallel with the depth of the semiconductor substrate 130B. As shown in FIG. 12A, the amorphous layers 310a and 310b are approximately 30 nm deep under the condition of implantation of germanium according to the present manufacturing method example.

Next, the semiconductor substrate 130B is subjected to second rapid thermal processing that heats the substrate to a temperature of 1200° C. to 1350° C., for example, by laser annealing and keeps the substrate near the peak temperature for approximately 1 ms. As shown in FIG. 10D, this second rapid thermal processing causes the first extension diffusion layers 306a and 306b and the first pocket diffusion layers 307a and 307b to be formed in regions in the semiconductor substrate 130B lateral to the gate electrode 302, respectively. The first extension diffusion layers 306a and 306b have boron ions diffused therein and have comparatively shallow junction planes, and the first pocket diffusion layers 307a and 307b are N-type pocket diffusion layers formed by diffusion of phosphorus ions and arsenic ions contained in the N-type pocket impurity-implanted layers 307Aa and 307Ab. Although laser annealing is used in the second rapid thermal processing, which is on the millisecond time scale, here, a so-called millisecond annealing (MSA) method such as flash lamp annealing may be used. Furthermore, the second rapid thermal processing may involve the use of annealing that heats the semiconductor substrate 130B to a temperature of approximately 850° C. to 1050° C. at a temperature rise rate of approximately 200° C./sec and keeps the peak temperature for a maximum of approximately ten seconds or does not keep the peak temperature, e.g. low-temperature spike-RTA.

FIG. 12B shows, on a log scale, concentrations distributions of impurities (B, C, and Ge) in the first extension diffusion layers 306a and 306b, which are P-type extension high-concentration diffusion layers formed by the second rapid thermal processing, in a direction parallel with the depth of the semiconductor substrate 130B. After the second rapid thermal processing has been executed, the amorphous layers 310a and 310b, formed during germanium ion implantation, recover to crystal layers. Boron is diffused to have a peak at a slightly greater depth than it does immediately after ion implantation. Carbon has a first peak composed of a carbon cluster near a concentration peak position during ion implantation, and also has a segregated second peak near the original amorphous/crystal (a/c) interface. Germanium has almost the same concentration distribution as it does immediately after ion implantation.

The concept “pre-amorphization” is explained here. Let it be assumed that amorphization of a certain region in a semiconductor substrate and implantation into that region of an impurity having a polarity, i.e. a conductivity type, (e.g. implantation of B ions or other ions) are executed. In this case, it is conceivable that the amorphization and the impurity implantation may be executed in this order. In this case, the amorphization may be referred to as “pre-amorphization”. Doing ion implantation after amorphizing a substrate causes channeling during the ion implantation to be inhibited, so that a shallow implantation distribution may be formed. Specifically, an implantation distribution whose so-called tailing is small may be formed. Then, executing annealing later effects solid-phase epitaxial regrowth by which an amorphous layer recovers to a crystal layer, bringing about a high activation rate of an impurity and a shallow junction depth. In the present manufacturing method example, it can be said that pre-amorphization preceding B ion implantation for forming the first extension diffusion layers 306a and 306b is done.

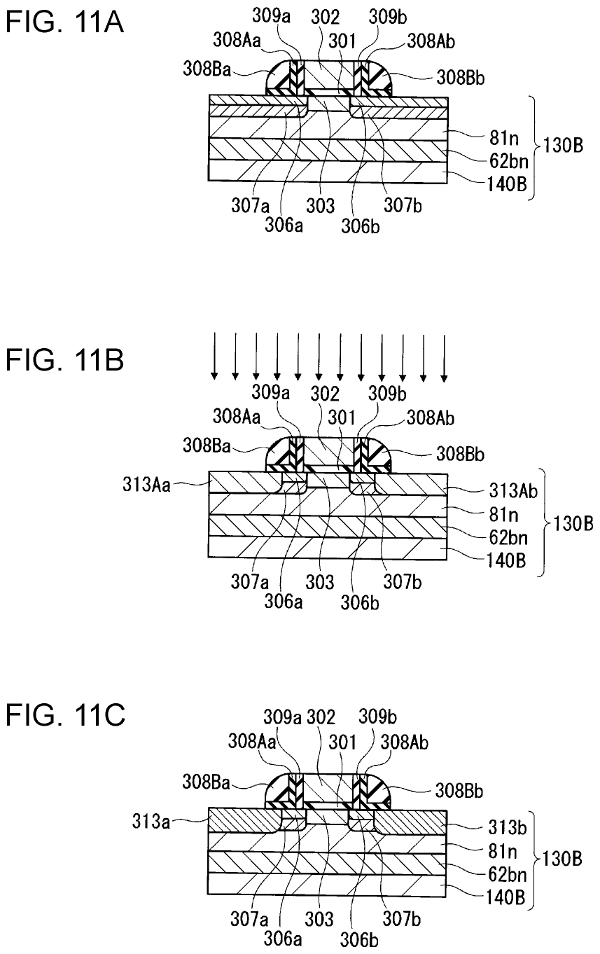

Next, a first insulator film composed of silicon oxide with a film thickness of approximately 10 nm and a second insulator film composed of silicon nitride with a film thickness of approximately 40 nm are sequentially deposited all over the surface of the semiconductor substrate 130B including the offset spacers 309a and 309b and the gate electrode 302, for example, by a chemical vapor deposition (CVD) method. After that, the first and second insulator films thus deposited are subjected to anisotropic etching, whereby as shown in FIG. 11A, the first side walls 308Aa and 308Ab are formed from the first insulator film and the second side walls 308Ba and 308Bb are formed from the second insulator film over side surfaces of the gate electrode 302 in a direction parallel with a gate length. Note here that the second side walls 308Ba and 308Bb may be composed of silicon oxide instead of silicon nitride or, furthermore, may be formed by a film stack composed of silicon oxide and silicon nitride.

Next, as shown in FIG. 11B, second P-type impurity-implanted layers 313Aa and 313Ab are formed by implanting a P-type impurity, i.e. boron ions, into the semiconductor substrate 130B with an implantation energy of approximately 3 keV and in an implantation dose amount of approximately 3×10¹⁵/cm² with the gate electrode 302, the offset spacers 309a and 309b, the first side walls 308Aa and 308Ab, and the second side walls 308Ba and 308Bb as masks.

Next, as shown in FIG. 11C, the semiconductor substrate 130B is subjected to third rapid thermal processing that heats the substrate to a temperature of 1200° C. to 1350° C., for example, by laser annealing and keeps the substrate near the peak temperature for approximately 1 ms. This third rapid thermal processing causes the P-type source diffusion layer 313a and the P-type drain diffusion layer 313b to be formed in regions in the semiconductor substrate 130B lateral to the first side walls 308Aa and 308Ab and the second side walls 308Ba and 308Bb. The P-type source diffusion layer 313a and the P-type drain diffusion layer 313b are P-type high-concentration impurity diffused layers, formed by diffusion of boron ions and connected to the first extension diffusion layers 306a and 306b, that have deeper junction planes than the first extension diffusion layers 306a and 306b. Although laser annealing is used in the millisecond rapid thermal processing here, a so-called millisecond annealing (MSA) method such as flash lamp annealing may be used. Further, the third rapid thermal processing may involve the use of annealing that raises the temperature to approximately 850° C. to 1050° C. at a temperature rise rate of approximately 200° C./sec to 250° C./sec and keeps the peak temperature for a maximum of approximately ten seconds or does not keep the peak temperature, e.g. spike-RTA.

The second rapid thermal processing, which is shown in FIG. 10D, may be omitted. In that case, the third rapid thermal processing also serves as the second rapid thermal processing.

Thus, according to the present manufacturing method example, before ion implantation for use in the formation of extension diffusion layers is executed with low energy in the step of forming the first P-type impurity-implanted layers 306Aa and 306Ab as shown in FIG. 10C, the semiconductor substrate 130B is amorphized by germanium in the step shown in FIG. 10A and then carbon is implanted as an impurity for use in the prevention of diffusion in the step shown in FIG. 10B. Carbon has an effect of inhibiting transient enhanced diffusion (TED) of impurity atoms. Carbon is effective in the formation of the respective shallow diffusion layers of a p-type field-effect transistor (pFET) and an n-type field-effect transistor (nFET), as carbon greatly inhibits the diffusion of boron and phosphorus.

Since carbon is co-implanted into the regions of formation of the first extension diffusion layers 306a and 306b, carbon plays a role of eliminating excess point defects in the semiconductor substrate 130B. This reduces excess point defects introduced by ion implantation and inhibits TED of atoms of impurities such as boron and phosphorus, making it possible to keep the junction depth of each diffusion layer shallow.

For the reason noted above, implanting carbon in such a way as to satisfy the aforementioned condition makes it possible to surely form low-resistance first extension diffusion layers 306a and 306b with shallow junctions, reduced junction leaks, and suppressed increases in value of resistance due to dose loss.

As noted above, the first peripheral region R2 may be heated by heat in the process of manufacturing an imaging device. However, even in such a case, a diffusion-inhibiting effect based on carbon implantation and an associated effect are brought about.

In one example, the fabrication of the structure of the first peripheral region R2 is followed by the fabrication of the structure of the pixel region R1 over the first peripheral region R2. Specifically, an opening is formed in the interlayer film in the pixel region R1. After the formation of the opening, implantation of, for example, a impurity region that constitutes the charge accumulation region Z may be executed in the pixel region R1. Next, open plug portions are embedded in the pixel region R1 by depositing polysilicon so that the opening is filled. The polysilicon may be doped with phosphorus. Next, the pixel region R1, including the plug portions, is subjected to heat treatment. This heat treatment is executed, for example, for approximately ten minutes at 850° C. This heat treatment causes the first peripheral region R2 to be heated too. However, in the first peripheral region R2, the diffusion-inhibiting effect based on carbon implantation inhibits the redistribution of the conductive impurity, making it possible to maintain the shallow junction.

Even with attention focused only on the manufacture of the first peripheral transistor 27 of the first peripheral region R2, the diffusion-inhibiting effect based on carbon implantation is effective. Furthermore, as noted above, even in a case where the first peripheral region R2 is heated by heat treatment for heating the pixel region R1, the diffusion-inhibiting effect based on carbon implantation may be exerted.

It should be noted that only phosphorus (P) may be used as an impurity in the first pocket diffusion layers 307a and 307b, which are N-type pocket diffusion layers. Using phosphorus is more effective in preventing the diffusion of carbon ions than using arsenic (As).

A transistor according to the present disclosure and a method for manufacturing the same can achieve reductions in junction depth and resistance of an extension diffusion layer along with miniaturization, and are effective in a MIS transistor having high driving force and a method for manufacturing the same.

### Transistors of Pixel Regions and Peripheral Regions

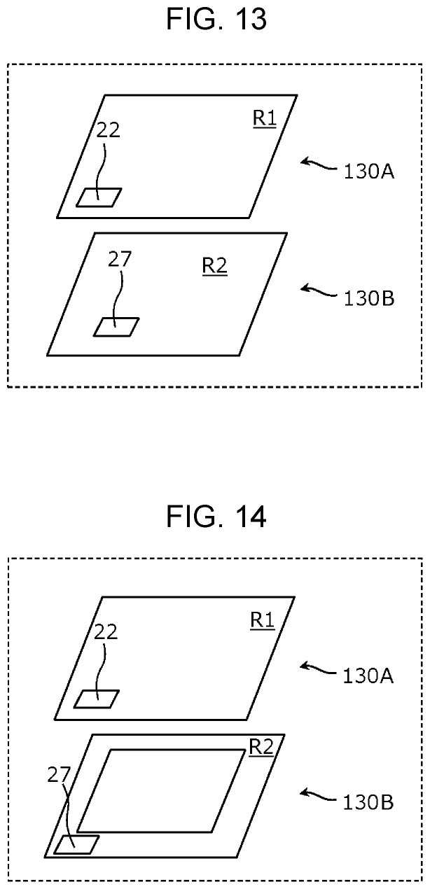

The following further describes transistors of pixel regions and transistors of peripheral regions with reference to FIGS. 13 to 24. FIGS. 13, 14, 16, 17, 18, 19, 21, and 22 are schematic perspective views illustrating transistors of pixel regions and transistors of peripheral regions. FIGS. 15, 20, 23, and 24 illustrates schematic cross-sectional views showing transistors of pixel regions and transistors of peripheral regions. It should be noted that FIGS. 13 to 24 omit to illustrate the blocking regions 200A and 200B.

In the following, the previously-used terms are sometimes replaced by different terms. For example, one of the P-type source diffusion layer 313a and the P-type drain diffusion layer 313b is sometimes referred to as “source”, and the other as “drain”.

In the following, the P-type source diffusion layer 313a, which serves as the source of the first peripheral transistor 27, is sometimes referred to as “first source”. The P-type drain diffusion layer 313b, which serves as the drain of the first peripheral transistor 27, is sometimes referred to as “first drain”.

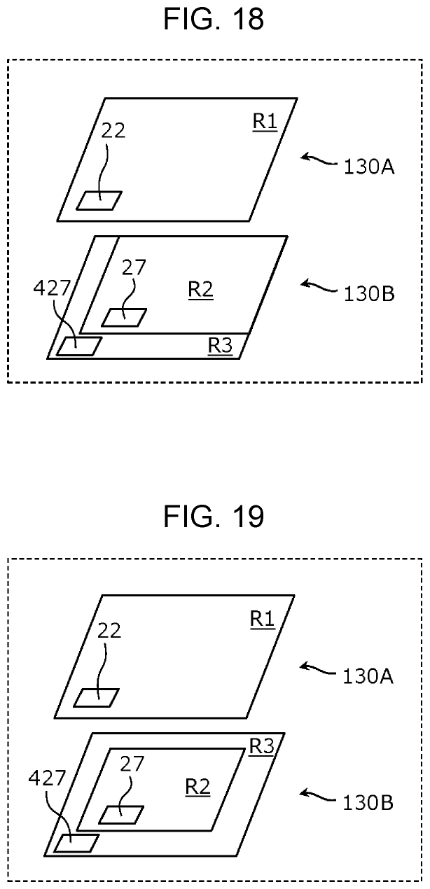

As shown in FIGS. 18 and 19, the imaging device may include a second peripheral region R3.

The pixel region R1 may be constituted using one semiconductor substrate, and the first peripheral region R2 may be constituted using another semiconductor substrate. The pixel region R1 may be constituted using one semiconductor substrate, the first peripheral region R2 may be constituted using another semiconductor substrate, and the second peripheral region R3 may be constituted using still another semiconductor substrate. The pixel region R1 may be constituted using one semiconductor substrate, and the first peripheral region R2 and the second peripheral region R3 may be constituted using another semiconductor substrate. The pixel region R1 and the second peripheral region R3 may be constituted using one semiconductor substrate, and the first peripheral region R2 may be constituted using another semiconductor substrate. Thus, in the present embodiment, the imaging device may have a plurality of semiconductor substrates.

In the following, the terms “pixel substrate portion”, “first peripheral substrate portion”, and “second peripheral substrate portion” are sometimes used. The pixel substrate portion may be a portion of a plurality of semiconductor substrates included in the pixel region R1. The first peripheral substrate portion may be a portion of a plurality of semiconductor substrates included in the first peripheral region R2. The second peripheral substrate portion may be a portion of a plurality of semiconductor substrates included in the second peripheral region R3.

The pixel substrate portion may be included in one semiconductor substrate, the first peripheral substrate portion may be included in another semiconductor substrate, and the second peripheral substrate portion may be included in still another semiconductor substrate. The pixel substrate portion may be included in one semiconductor substrate, and the first peripheral substrate portion and the second peripheral substrate portion may be included in another semiconductor substrate. The pixel substrate portion and the second peripheral substrate portion may be included in one semiconductor substrate, and the first peripheral substrate portion may be included in another semiconductor substrate.

The pixel substrate portion may be referred to specifically as “pixel semiconductor substrate portion”. The first peripheral substrate portion may be referred to specifically as “first peripheral semiconductor substrate portion”. The second peripheral substrate portion may be referred to specifically as “second peripheral semiconductor substrate portion”.

The term “pixel transistor” is described. A pixel transistor is a transistor that the pixel region R1 has. For example, an amplifying transistor 22, an address transistor 24, and a reset transistor 26 may fall under the category of pixel transistors. FIGS. 13 to 37B illustrate an amplifying transistor 22 as a pixel transistor. Further, the following describes a case where a pixel transistor is an amplifying transistor 22. Note, however, that the term “amplifying transistor 22” can be read as “pixel transistor, “address transistor 24”, or “reset transistor 26” in the following description, provided no contradiction arises. Elements, such as a source and a drain, that a transistor has and elements, such as wires, associated with a transistor may be read as appropriate.

The gate insulator film of a pixel transistor may be referred to as “pixel gate insulator film”. The gate insulator film of a pixel transistor may be referred to as “amplifying gate insulator film”. The gate insulator film of a first peripheral transistor may be referred to as “first peripheral gate insulator film”. The gate insulator film of a second peripheral transistor may be referred to as “second peripheral gate insulator film”.

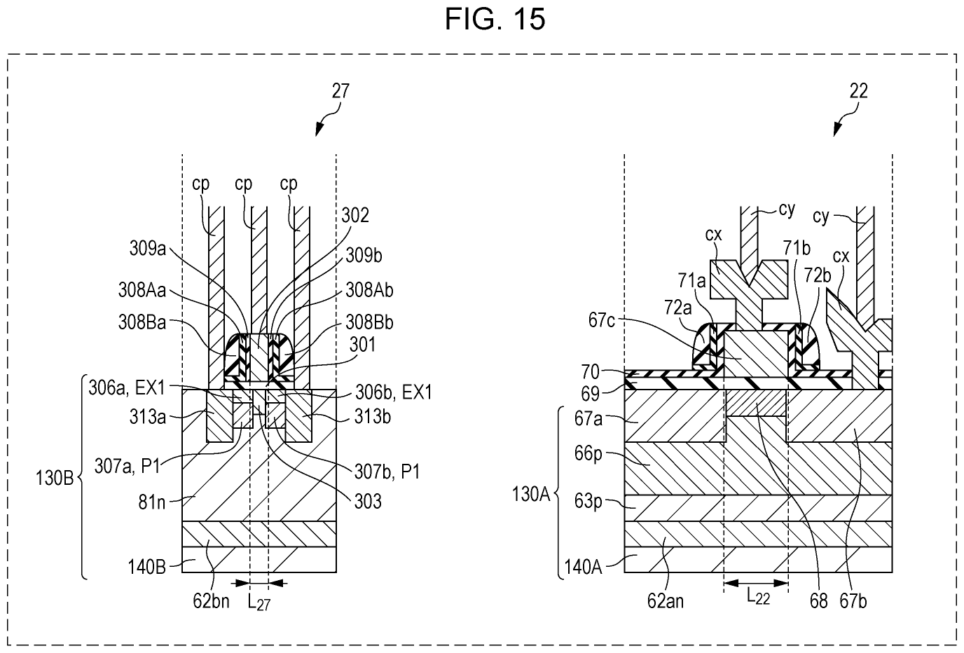

In each of the examples shown in FIGS. 13 and 14, the first peripheral region R2 and the pixel region R1 are stacked on top of each other. The pixel region R1 is constituted using the semiconductor substrate 130A. The first peripheral region R2 is constituted using the semiconductor substrate 130B.

FIG. 13 schematically shows an amplifying transistor 22 in the pixel region R1 and a first peripheral transistor 27 in the first peripheral region R2 in a case where the first peripheral region R2 is in the shape of a rectangle in planar view. FIG. 14 schematically shows an amplifying transistor 22 in the pixel region R1 and a first peripheral transistor 27 in the first peripheral region R2 in a case where the first peripheral region R2 is in the shape of a frame in planar view. Specifically, in FIG. 14, the first peripheral region R2 is in the shape of a square in planar view. The first peripheral region R2 may be in the shape of letter L or in the shape of letter U in planar view.

In the first peripheral region R2, elements such as image signal processors (ISP) and memories may be provided. In the first peripheral region R2, elements such as ISPs and memories may be stacked in multiple layers.

FIG. 15 shows configurations that the amplifying transistor 22 in the pixel region R1 and the first peripheral transistor 27 in the first peripheral region R2 may have in each of the examples shown in FIGS. 13 and 14. In the example shown in FIG. 15, the amplifying transistor 22 is an N-channel MOSFET, and the first peripheral transistor 27 is a P-channel MOSFET. Note, however, that as mentioned above, these transistors are not limited to particular conductivity types. In this respect, the same applies to the after-mentioned transistors 427, 727, and 827.

In the example shown in FIG. 15, the first peripheral transistor 27 is similar to that described with reference to FIG. 5. Note, however, that in the example shown in FIG. 15, another transistor may be employed instead of the first peripheral transistor 27. For example, a transistor described with reference to FIG. 6, 7, or 8 may be employed.

In the example shown in FIG. 15, a contact plug cp is connected to the P-type source diffusion layer 313a, which serves as the source of the first peripheral transistor 27. A contact plug cp is connected to the P-type drain diffusion layer 313b, which serves as the drain of the first peripheral transistor 27. A contact plug cp is connected to the gate electrode 302 of the first peripheral transistor 27.

In one example, the contact plugs cp are metal plugs. Examples of metal that the contact plugs cp may contain include tungsten and copper.

In the example shown in FIG. 15, the amplifying transistor 22 has a source 67a, a drain 67b, and a gate electrode 67c. The source 67a is an N-type impurity region. The drain 67b is an N-type impurity region. The gate electrode 67c is made, for example, of a polysilicon material.

A channel diffusion layer 68 is formed between the source 67a and the drain 67b. The channel diffusion layer 68 is an N-type impurity region.

A gate insulator film 69 is formed between the gate electrode 67c and the pixel substrate portion. Specifically, the gate insulator film 69 is an oxide film. In one specific example, the gate insulator film 69 contains silicon oxide, and in one specific example, the gate insulator film 69 contains silicon dioxide.

An offset spacer 70 is formed over the gate electrode 67c and the gate insulator film 69. In one example, the offset spacer 70 contains silicon oxide, and in one specific example, the offset spacer 70 contains silicon dioxide.

A first side wall 71a is formed on a portion of the offset spacer 70 beside the source 67a. In the example shown in FIG. 15, the first side wall 71a has an L-shaped cross-section. A second side wall 72a is formed on an outer side of the first side wall 71a.

A first side wall 71b is formed on a portion of the offset spacer 70 beside the drain 67b. In the example shown in FIG. 15, the first side wall 71b has an L-shaped cross-section. A second side wall 72b is formed on an outer side of the first side wall 71b.

In one specific example, the first side wall 71a contains silicon oxide, and in one specific example, the first side wall 71a contains silicon dioxide. In this respect, the same applies to the first side wall 71b. In one specific example, the second side wall 72a has a stacked structure including a plurality of insulating layers, and in one specific example, the second side wall 72a includes a silicon dioxide layer and a silicon nitride layer. In this respect, the same applies to the second side wall 72b.

The offset spacer 70 has a through-hole formed over the gate electrode 67c. A contact plug cx is connected to the gate electrode 67c via the through-hole. The gate insulator film 69 and the offset spacer 70 have through-holes formed over the drain 67b. A contact plug cx is connected to the drain 67b via the through-holes.

The contact plugs cx are for example polysilicon plugs. The contact plugs cx may be doped with an impurity such as phosphorus for higher electric conductivity.

It should be noted that an embodiment in which a contact plug cx is connected to the source 67a may be adopted. Specifically, the gate insulator film 69 and the offset spacer 70 have through-holes formed over the source 67a, and a contact plug cx is connected to the source 67a via the through-holes.

The contact plug cx connected to the gate electrode 67c is connected to a plug cy. The contact plug cx connected to the drain 67b is connected to a plug cy. In a case where a contact plug cx connected to the source 67a is present, the contact plug cx may be connected to a plug cy.

In one example, the plugs cy are metal plugs. Examples of metal that the contact plugs cy may contain include tungsten and copper.

As can be understood from the description with reference to FIGS. 1 to 15, an imaging device according to the present embodiment includes a pixel region R1 and a first peripheral region R2. The pixel region R1 has a pixel substrate portion. The first peripheral region R2 has a first peripheral substrate portion. The pixel substrate portion and the first peripheral substrate portion are stacked on top of each other. The expression “the pixel substrate portion and the first peripheral substrate portion are stacked on top of each other” is intended to encompass both an embodiment in which an inclusion is interposed between the pixel substrate portion and the first peripheral substrate portion and an embodiment in which no inclusion is interposed between the pixel substrate portion and the first peripheral substrate portion. Typically, the pixel substrate portion and the first peripheral substrate portion are stacked with an insulating part sandwiched therebetween. The insulating part may correspond to the interlayer insulating layer 90B of FIG. 3.

The pixel region R1 has an amplifying transistor 22. The amplifying transistor 22 is provided in the pixel substrate portion. The first peripheral region R2 has a first peripheral transistor 27. The first peripheral transistor 27 is provided in the first peripheral substrate portion. In one example, the first peripheral transistor 27 is a logic transistor. The first peripheral transistor 27 may be a planar transistor, or may be a three-dimensional structural transistor. A first example of a three-dimensional structural transistor is a FinFET (fin field-effect transistor). A second example of a three-dimensional structural transistor is a GAA (gate all around) such as a nanowire FET. A third example of a three-dimensional structural transistor is a nanosheet FET.

In the present embodiment, the amplifying transistor 22 outputs a signal voltage corresponding to signal charge obtained by photoelectric conversion. The photoelectric conversion is carried out in a photoelectric conversion layer 12. Specifically, there are provided a path that leads the signal charge from the photoelectric conversion layer 12 to a charge accumulation region Z and a path that leads the signal charge from the charge accumulation region Z to a gate electrode 67c of the amplifying transistor 22. In the example shown in FIG. 3, the charge accumulation region Z corresponds to an impurity region 60n. As mentioned above, the charge accumulation region Z is included in a charge accumulation node FD.

As shown in FIG. 15, in the present embodiment, the gate length L₂₇ of the first peripheral transistor 27 is shorter than the gate length L₂₂ of the amplifying transistor 22.

The ratio L₂₇/L₂₂ of the gate length L₂₇ of the first peripheral transistor 27 to the gate length L₂₂ of the amplifying transistor 22 is for example lower than or equal to 0.8, or may be lower than or equal to 0.34. This ratio is for example higher than or equal to 0.01, or may be higher than or equal to 0.05.

The term “gate length” here refers to a dimension of a gate electrode in a direction from a source to a drain or from the drain to the source. The term “gate width” refers to a dimension of a gate electrode in a direction orthogonal to a direction parallel with a gate length in planar view. The direction orthogonal to a direction parallel with a gate length in planar view may also be referred to as “depth direction”.

In the present embodiment, the gate insulator film 301 of the first peripheral transistor 27 is thinner than the gate insulator film 69 of the amplifying transistor 22.

The ratio T₃₀₁/T₆₉ of the thickness T₃₀₁ of the gate insulator film 301 of the first peripheral transistor 27 to the thickness T₆₉ of the gate insulator film 69 of the amplifying transistor 22 is for example lower than or equal to 0.7, or may be lower than or equal to 0.36. This ratio is for example higher than or equal to 0.1, or may be higher than or equal to 0.2.

In one example, the first peripheral transistor 27 has a first specific layer. The first specific layer is located within the first peripheral substrate portion. The first specific layer contains a conductive impurity and a specific species.

The conductive impurity is an impurity having a conductivity type. That is, the conductive impurity is a P-type or N-type impurity.

In the present embodiment, the specific species is at least one type of impurity that contributes to the inhibition of the transient enhanced diffusion of the conductive impurity. The specific species may contain at least one selected from the group consisting of carbon, nitrogen, and fluorine. Carbon, nitrogen, and fluorine may inhibit the transient enhanced diffusion of the conductive impurity. That is, the specific species may contain at least one type of impurity that inhibits the transient enhanced diffusion of the conductive impurity. Further, the specific species may contain at least one selected from the group consisting of germanium, silicon, and argon. Germanium, silicon, and argon may be a trace of pre-amorphization that may enhance the diffusion-inhibiting action on the conductive impurity by an impurity exemplified by carbon. That is, the specific species may contain at least one type of impurity that is a trace of pre-amorphization that may enhance the diffusion-inhibiting action on the conductive impurity by an impurity exemplified by carbon. In the aforementioned example, the specific species may also be referred to as “co-implanted species”. The concentration of the specific species in the first specific layer is for example higher than or equal to 5×10¹⁶ atoms/cm³. The concentration of the specific species in the first specific layer may be higher than or equal to 5×10¹⁷ atoms/cm³.

As noted above, the first specific layer contains the conductive impurity and the specific species. A technique involving the use of such a first specific layer is suitable to improving the performance of the imaging device in consideration of the presence of the first peripheral transistor 27 in the first peripheral region R2.

In one example, the first peripheral transistor 27 has the P-type source diffusion layer 313a, which serves as the first source, and the P-type drain diffusion layer 313b, which serves as the first drain. At least one selected from the group consisting of the P-type source diffusion layer 313a, which serves as the first source, and the P-type drain diffusion layer 313b, which serves as the first drain, includes the first specific layer.

In one example, the first peripheral transistor 27 has a first extension diffusion layer EX1. The first extension diffusion layer EX1 is adjacent to the P-type source diffusion layer 313a, which serves as the first source, or the P-type drain diffusion layer 313b, which serves as the first drain. The first extension diffusion layer EX1 is shallower than the P-type source diffusion layer 313a, which serves as the first source, and the P-type drain diffusion layer 313b, which serves as the first drain. The first extension diffusion layer EX1 includes the first specific layer. The first extension diffusion layer EX1 is the first extension diffusion layer 306a or the first extension diffusion layer 306b.

The expression “an extension layer and a source are adjacent to each other” specifically means that the extension diffusion layer and the source are connected to each other. The same applies to similar expressions such as the expression “an extension diffusion layer and a drain are adjacent to each other”, the expression “a pocket diffusion layer and a source are adjacent to each other”, and the expression “a pocket diffusion layer and a drain are adjacent to each other”, each of which specifically means that those elements are connected to each other.

The sentence “the first extension diffusion layer EX1 is shallower than the P-type source diffusion layer 313a, which serves as the first source, and the P-type drain diffusion layer 313b, which serves as the first drain” means that the deepest portion of the first extension diffusion layer EX1 is at a shallower depth than the deepest portions of the P-type source diffusion layer 313a, which serves as the first source, and the P-type drain diffusion layer 313b, which serves as the first drain, in a direction parallel with the depth of the first peripheral substrate portion. In this context, the word “shallow” can also be referred to as “shallow injunction depth”. Boundaries of an extension diffusion layer, a source, and a drain are junctions. A junction is a place where the concentration of an N-type impurity and the concentration of a P-type impurity are equal to each other.

The expression “the first extension diffusion layer EX1 includes the first specific layer” is intended to encompass an embodiment in which the first specific layer falls within the first extension diffusion layer EX1” and an embodiment in which the first specific layer protrudes from the first extension diffusion layer EX1. The same applies to similar expressions such as the expression “the first pocket diffusion layer P1 includes the first specific layer”.

In the illustrated example, the first peripheral transistor 27 has the first extension diffusion layer 306a and the first extension diffusion layer 306b. The first extension diffusion layer 306a is adjacent to the P-type source diffusion layer 313a, which serves as the first source. The first extension diffusion layer 306a is shallower than the P-type source diffusion layer 313a, which serves as the first source, and the P-type drain diffusion layer 313b, which serves as the first drain. The first extension diffusion layer 306b is adjacent to the P-type drain diffusion layer 313b, which serves as the first drain. The first extension diffusion layer 306b is shallower than the P-type source diffusion layer 313a, which serves as the first source, and the P-type drain diffusion layer 313b, which serves as the first drain. The first extension diffusion layer 306a and the first extension diffusion layer 306b include the first specific layer.

In one example, the first peripheral transistor 27 has a first pocket diffusion layer P1. The first pocket diffusion layer P1 is adjacent to the P-type source diffusion layer 313a, which serves as the first source, or the P-type drain diffusion layer 313b, which serves as the first drain. The first pocket diffusion layer P1 includes the first specific layer. The first pocket diffusion layer P1 is the first pocket diffusion layer 307a or the first pocket diffusion layer 307b.

In the illustrated example, the first peripheral transistor 27 has the first pocket diffusion layer 307a and the first pocket diffusion layer 307b. The first pocket diffusion layer 307a is adjacent to the P-type source diffusion layer 313a, which serves as the first source. The first pocket diffusion layer 307b is adjacent to the P-type drain diffusion layer 313b, which serves as the first drain. The first pocket diffusion layer 307a and the first pocket diffusion layer 307b include the first specific layer.

Only one selected from among the P-type source diffusion layer 313a, which serves as the first source, the P-type drain diffusion layer 313b, which serves as the first drain, the first extension diffusion layer EX1, and the first pocket diffusion layer P1 may include the first specific layer. Specifically, only one selected from among the P-type source diffusion layer 313a, which serves as the first source, the P-type drain diffusion layer 313b, which serves as the first drain, the first extension diffusion layer 306a, the first extension diffusion layer 306b, the first pocket diffusion layer 307a, and the first pocket diffusion layer 307b may include the first specific layer.

Two or more selected from among the P-type source diffusion layer 313a, which serves as the first source, the P-type drain diffusion layer 313b, which serves as the first drain, the first extension diffusion layer EX1, and the first pocket diffusion layer P1 may include the first specific layer. Specifically, two or more selected from among the P-type source diffusion layer 313a, which serves as the first source, the P-type drain diffusion layer 313b, which serves as the first drain, the first extension diffusion layer 306a, the first extension diffusion layer 306b, the first pocket diffusion layer 307a, and the first pocket diffusion layer 307b may include the first specific layer. In a case where these selected two or more include the first specific layer, these may include the same or different types of specific species. For example, the specific species of the P-type source diffusion layer 313a, which serves as the first source, may be carbon, and the specific species of the first extension diffusion layer EX1 may be nitrogen and fluorine. Further, in this case, these may include the same or different conductivity types of conductive impurity. For example, one of the P-type source diffusion layer 313a, which serves as the first source, and the first pocket diffusion layer P1 may contain boron whose conductivity type is a P type, and the other may contain phosphorus whose conductivity type is an N type.

As can be understood from the foregoing description, the imaging device may have one or more first specific layers.

The following describes an example of a situation in which a technique involving the use of a first specific layer may contribute to such improvement in performance as that noted above.

In the imaging device of the present embodiment, the pixel substrate portion pertaining to the pixel region R1 and the first peripheral substrate portion pertaining to the first peripheral region R2 are stacked on top of each other. In the process of manufacturing an imaging device, the first peripheral region R2 may be heated for the following reasons. First, the first peripheral region R2 may be heated by heat that is supplied in forming the first peripheral region R2. Second, in a case where the first peripheral region R2 and the pixel region R1 are separately formed and then those regions are joined to each other, the first peripheral region R2 may be heated by heating for the joining. Third, in a case where the pixel region R1 is subjected to heat treatment after a stacked structure including the first peripheral region R2 and the pixel region R1 has been formed, the first peripheral region R2 may be heated too by the heat treatment. Heating the first peripheral transistor 27 of the first peripheral region R2 may cause diffusion of a conductive impurity. The diffusion of the conductive impurity may cause deterioration in performance of the first peripheral transistor 27. The deterioration in performance of the first peripheral transistor 27 may cause deterioration in performance of the imaging device as a whole. However, in one example of the present embodiment, the first specific layer contains the conductive impurity and the specific species. The specific species may contribute to the inhibition of the diffusion of the conductive impurity. This diffusion-inhibiting action may reduce the deterioration in performance of the first peripheral transistor 27.

The heat treatment stated as the third reason why the first peripheral region R2 may be heated is further described. The heat treatment may reduce defects in the pixel substrate portion in the pixel region R1. Reducing defects may reduce dark current in the imaging device. Meanwhile, in the first peripheral region R2, the necessity to reduce defects is not necessarily great. On the contrary, in the first peripheral region R2, there is a case where it is necessary to reduce deterioration in performance of the first peripheral transistor 27 attributed to the diffusion of the conductive impurity entailed by the heat treatment. The deterioration in performance is for example an undesirable change in threshold voltage of the first peripheral transistor 27.

In particular, in the present embodiment, the first peripheral transistor 27 includes at least one selected from the group consisting of a first feature and a second feature. The first feature is such a feature that the gate length L₂₇ of the first peripheral transistor 27 is shorter than the gate length L₂₂ of the amplifying transistor 22. The second feature is such a feature that the gate insulator film 301 of the first peripheral transistor 27 is thinner than the gate insulator film 69 of the amplifying transistor 22. In a case where the first peripheral transistor 27 includes at least one selected from the group consisting of the first feature and the second feature, the performance of the first peripheral transistor 27 is susceptible to diffusion redistribution of the conductive impurity due to thermal processing.

In this respect, as mentioned above, in one example of the present embodiment, the first specific layer contains the conductive impurity and the specific species. The specific species may contribute to the inhibition of the diffusion of the conductive impurity. This diffusion-inhibiting action may reduce the deterioration in performance of the first peripheral transistor 27. This makes it possible to, while enjoying the aforementioned advantage called “dark-current reduction”, mitigate the aforementioned disadvantage called “deterioration in performance of the first peripheral transistor 27”.

Let thought be given here to a first example in which the first specific layer is included in the first extension diffusion layer EX1 and the gate length L₂₇ of the first peripheral transistor 27 is shorter than the gate length L₂₂ of the amplifying transistor 22. In the process of manufacturing the imaging device, heat treatment may be executed. The heat treatment may reduce defects in the pixel substrate portion in the pixel region R1. Reducing defects may reduce dark current in the imaging device. Meanwhile, in a case where L₂₇<L₂₂, the heating more easily exert a short channel effect in the first peripheral transistor 27 than in the amplifying transistor 22. The short channel effect may change the threshold voltage of a transistor from a desired value and invite a decrease in performance of the transistor. Thus, the heat treatment may bring about an advantage in that dark current is reduced in the pixel region R1 and, on the other hand, bring about an disadvantage in that the short channel effect becomes obvious in the first peripheral region R2. The term “threshold voltage” here refers to the gate-source voltage of the transistor at which a drain current starts to flow through the transistor.

In this respect, in the first example, the first extension diffusion layer EX1 contains the conductive impurity and the specific species. The specific species may contribute to the inhibition of the diffusion of the conductive impurity. This diffusion-inhibiting action may suppress the short channel effect in the first peripheral transistor 27. This makes it possible to, while enjoying the aforementioned advantage called “dark-current reduction”, mitigate the aforementioned disadvantage called “short channel effect”.

As noted above, in the first specific example, the diffusion-inhibiting action derived from the specific species of the first extension diffusion layer EX1 suppresses the short channel effect of the first peripheral transistor 27 attributed to heat treatment. This means that a margin of a thermal budget of heat treatment becomes wider than in the absence of the diffusion-inhibiting action. Therefore, increasing the duration, temperature, or other conditions of heat treatment makes it possible to reduce dark current in the pixel region R1 without making the short channel effect obvious in the first peripheral transistor 27.

Let thought be given to a second example in which the first specific layer is included in at least one selected from the group consisting of the P-type source diffusion layer 313a, which serves as the first source, and the P-type drain diffusion layer 313b, which serves as the first drain, and the gate length L₂₇ of the first peripheral transistor 27 is shorter than the gate length L₂₂ of the amplifying transistor 22. In the second example too, as in the case of the first example, increasing the duration, temperature, or other conditions of heat treatment makes it possible to reduce dark current in the pixel region R1 without making the short channel effect obvious in the first peripheral transistor 27.

Let thought be given to a third example in which the first specific layer is included in the first pocket diffusion layer P1 and the gate length L₂₇ of the first peripheral transistor 27 is shorter than the gate length L₂₂ of the amplifying transistor 22. In the third example, variations in the threshold voltage of the first peripheral transistor 27 may be reduced by the inhibition of the diffusion of the conductive impurity of the first pocket diffusion layer P1. For this reason, according to the third example, as in the case of the first example, increasing the duration, temperature, or other conditions of heat treatment makes it possible to reduce dark current in the pixel region R1 without making the variations in the threshold voltage of the first peripheral transistor 27 obvious.

As mentioned above, the semiconductor substrate 130A may be a substrate having a semiconductor layer provided on a surface thereof by epitaxial growth. The same applies to the semiconductor substrate 130B, the semiconductor substrate 130C, the pixel substrate portion, the first peripheral substrate portion, and the second peripheral substrate portion. In a semiconductor substrate derived from epitaxial growth, unintended inclusion of carbon is easily reduced. This may contribute to reduction of dark current in the pixel region R1. This also makes it easy to make a difference in concentration of the specific species, such as carbon, between the pixel region R1 and the first peripheral region R2.

As mentioned above, the semiconductor substrate 130A may be a P-type silicon substrate. Note, however, that the semiconductor substrate 130A may be an N-type silicon substrate. The same applies to the semiconductor substrate 130B, the semiconductor substrate 130C, the pixel substrate portion, the first peripheral substrate portion, and the second peripheral substrate portion.

In one example, the pixel region R1 has t the photoelectric conversion layer 12. The photoelectric conversion layer 12, the pixel substrate portion, and the first peripheral substrate portion are stacked on top of each other. In a typical example, in a case where a pixel region R1 having such a configuration is fabricated, such heat treatment as noted above is executed. For this reason, an imaging device including a pixel region R1 having this configuration may enjoy the effect of reducing dark current while reducing the deterioration in performance of the first peripheral transistor 27.

In one example, a method for manufacturing the imaging device includes a first step and a second step in this order. In the first step, a stacked structure including the pixel substrate portion and the first peripheral substrate portion is fabricated. In the second step, the pixel substrate portion in the stacked structure is heated. In such a manufacturing method, heating of the pixel substrate portion may cause the first peripheral substrate portion to be heated too. In this case, the effect of reducing dark current while reducing the deterioration in performance of the first peripheral transistor 27 can be enjoyed. In one specific example, the second step involves thermal processing for recovery of various crystal defects and defect levels in the pixel substrate portion, particularly the vicinity of a charge accumulation portion. Such heating intended for the pixel substrate portion may cause the first peripheral substrate portion to be heated too. The imaging device may also be manufactured by another manufacturing method.

The photoelectric conversion layer 12 may be a panchromatic film. Alternatively, the photoelectric conversion layer 12 may be a film, such as an orthochromatic film, that does not have sensitivity to light in a certain range of wavelengths.

The conductive impurity may be a P-type impurity. Examples of P-type conductive impurities include boron and indium. Alternatively, the conductive impurity may be an N-type impurity. Examples of N-type impurities include phosphorus, arsenic, antimony, and bismuth.

The first source, the first drain, the first extension diffusion layer EX1 may have a conductive impurity of a first conductivity type. The same applies to the first extension diffusion layer 306a and the first extension diffusion layer 306b. On the other hand, the first pocket diffusion layer P1 may have a conductive impurity of a second conductivity type. The same applies to the first pocket diffusion layer 307a and the first pocket diffusion layer 307b. The first conductivity type is an N type or a P type. Further, the second conductivity type is the opposite of the first conductivity type. The second conductivity type is a P type or an N type.

In one specific example, the first peripheral transistor 27 is a logic transistor. The first peripheral transistor 27 can perform a digital operation. In such a first peripheral transistor 27, priority may be placed on speed. In order for a transistor to operate at high speed, it is advantageous for the transistor to be a fine transistor. Further, from the point of view of securing the transistor high driving force too, it is advantageous for the transistor to be a fine transistor. In this respect, in this specific example, the gate length L₂₇ of the first peripheral transistor 27 is shorter than the gate length L₂₂ of the amplifying transistor 22. Further, the gate insulator film 301 of the first peripheral transistor 27 is thinner than the gate insulator film 69 of the amplifying transistor 22. From the point of view of causing the first peripheral transistor 27 to operate at high speed and with high driving force, it may be advantageous for the gate length L₂₇ to be short and for the gate insulator film 301 to be thin. This advantage brought by the gate length L₂₇ being short and the gate insulator film 301 being thin may be exerted, for example, in a case where the first peripheral transistor 27 is a planar transistor. Further, the first peripheral transistor 27 of this specific example is located, for example, between a controller and a pixel driver.

In one example, the first specific layer contains germanium. As can be understood from the foregoing description, in the process of manufacturing the first peripheral transistor 27, germanium may pre-amorphize the inside of the first peripheral substrate portion. In a pre-amorphized region, the diffusion-inhibiting action on the conductive impurity by an impurity exemplified by carbon is easily enhanced. In this example, germanium may be a trace of pre-amorphization that may enhance the diffusion-inhibiting action on the conductive impurity by an impurity exemplified by carbon.

The first specific layer may contain silicon, argon, krypton, or xenon instead of or in addition to germanium. More generally, the first specific layer may contain at least one element selected from the group consisting of germanium, silicon, argon, krypton, and xenon. These elements may be traces of pre-amorphization that may enhance the diffusion-inhibiting action on the conductive impurity by an impurity exemplified by carbon.

In one example, the first peripheral transistor 27 include an end-of-range (EOR) defect. At least part of the first specific layer is located above the EOR defect and overlaps the EOR defect in planar view. In this context, the phrase “above the EOR defect” means a side, as seen from the EOR defect, of a surface of the first peripheral substrate portion over which the gate electrode 302 is provided. As noted above, in a pre-amorphized region in the first peripheral substrate portion, the diffusion-inhibiting action on the conductive impurity by an impurity exemplified by carbon is easily enhanced. As can be understood from the foregoing description, in a case where in the process of manufacturing the first peripheral transistor 27, thermal processing is executed with the first peripheral substrate portion in an amorphized state, an EOR defect may be formed in a region just below the original amorphous/crystal (a/c) interface before the thermal processing. In this example, the EOR defect may be a trace of pre-amorphization that may enhance the diffusion-inhibiting action on the conductive impurity by an impurity exemplified by carbon. The first specific layer in its entirety may be located above the EOR defect and overlaps the EOR defect in planar view.

In one example, the first peripheral transistor 27 includes a segregated portion in which the specific species is segregated in a direction parallel with the depth of the first peripheral substrate portion. At least part of the first specific layer is located above the segregated portion and overlaps the segregated portion in planar view. As noted above, in a pre-amorphized region in the first peripheral substrate portion, the diffusion-inhibiting action on the conductive impurity by an impurity exemplified by carbon is easily enhanced. In a case where in the process of manufacturing the first peripheral transistor 27, thermal processing is executed with the first peripheral substrate portion in an amorphized state, a segregated portion may be formed in a region below the original amorphous/crystal (a/c) interface before the thermal processing. In this example, the segregated portion may be a trace of pre-amorphization that may enhance the diffusion-inhibiting action on the conductive impurity by an impurity exemplified by carbon. The first specific layer in its entirety may be located above the segregated portion and overlaps the segregated portion in planar view. In the expression “segregated portion in which the specific species is segregated”, the word “segregated” means that the specific species unevenly distributed, and is not intended to limit the process of forming the segregated portion.

The segregated portion is described with reference to a concentration profile serving as a relationship of the concentration of the specific species with a depth in the first peripheral substrate portion. In a case where the segregated portion is present, the concentration in the concentration profile takes on a minimal value at a first depth substantially corresponding to the depth of the original amorphous/crystal (a/c) interface before thermal processing. The concentration in the concentration profile takes on a maximal value at a second depth that is deeper than the first depth. The segregated portion refers to a portion of the first peripheral substrate portion that is deeper than the first depth and in which the concentration of the specific species is higher than the minimal value. In the profile of carbon shown in FIG. 12B, the legend “ORIGINAL a/c INTERFACE” substantially corresponds to the first depth, and an upwardly-sticking portion directly below the legend “ORIGINAL a/c INTERFACE” corresponds to the segregated portion.

In the present embodiment, the pixel region R1 includes a charge accumulation region Z. In the charge accumulation region Z, charge generated by photoelectric conversion is accumulated. The charge accumulation region Z is an impurity region. In the example shown in FIG. 3, the charge accumulation region Z corresponds to the impurity region 60n. Specifically, photoelectric conversion is carried out in the photoelectric converter 10, and the charge thus generated is sent to the charge accumulation region Z via a plug cy and a contact plug cx and accumulated in the charge accumulation region Z.

In one example, the segregated portion is shallower than the charge accumulation region Z. The clause “the segregated portion is shallower than the charge accumulation region Z” means that the deepest portion of the segregated portion is at a shallower depth than the deepest portion of the charge accumulation region Z in a direction parallel with the depth of the pixel substrate portion or the first peripheral substrate portion.

In one example, the concentration of carbon in the first specific layer is higher than the concentration of carbon in the charge accumulation region Z. Carbon in the first specific layer may inhibit the diffusion of the conductive impurity. Meanwhile, the presence of carbon in the charge accumulation region Z may cause dark current. Therefore, only a high-performance imaging device can have such a feature that the concentration of carbon in the first specific layer is higher than the concentration of carbon in the charge accumulation region Z. In the expression “the concentration of carbon in the first specific layer is higher than the concentration of carbon in the charge accumulation region Z”, the concentration of carbon in the charge accumulation region Z may be zero, or may be higher than zero.

Note here that a boundary of the charge accumulation region Z is a junction. As mentioned above, a junction is a place where the concentration of an N-type impurity and the concentration of a P-type impurity are equal to each other.

According to a first definition, the phrase “concentration of carbon” in the expression “the concentration of carbon in the first specific layer is higher than the concentration of carbon in the charge accumulation region Z” is a maximum value of concentration. According to a second definition, the phrase “concentration of carbon” in this expression is an average concentration. In the aforementioned example, a case where it can be said on the basis of at least one selected from the group consisting of the first definition and the second definition that “the concentration of carbon in the first specific layer is higher than the concentration of carbon in the charge accumulation region Z” is treated as a case where “the concentration of carbon in the first specific layer is higher than the concentration of carbon in the charge accumulation region Z”.

Let thought be given to a case where the specific species is carbon. The ratio C2/C1 of the concentration C2 of carbon in the first specific layer to the concentration C1 of carbon in the charge accumulation region Z is for example higher than or equal to 1×10⁵. This ratio is for example lower than or equal to 1×10¹¹.

Let thought be given to a case where the specific species is carbon and the first specific layer is included in the first extension diffusion layer EX1. The concentration of the conductive impurity in the first extension diffusion layer EX1 is for example higher than or equal to 1×10¹⁷ atoms/cm³. The concentration of carbon in the first extension diffusion layer EX1 is for example higher than or equal to 1×10¹⁷ atoms/cm³. The concentration of the conductive impurity in the first extension diffusion layer EX1 is for example lower than or equal to 1×10²² atoms/cm³. The concentration of carbon in the first extension diffusion layer EX1 is for example lower than or equal to 1×10²² atoms/cm³. These descriptions may be applied to both the first extension diffusion layers 306a and 306b.

In one example, the concentration of carbon in the charge accumulation region Z is substantially zero. The clause “the concentration of carbon in the charge accumulation region Z is substantially zero” here means, for example, that the concentration of carbon in the charge accumulation region Z is lower than 5×10¹⁶ atoms/cm³. Intentionally-given carbon does not need to be present in the charge accumulation region Z. The concentration of carbon in the charge accumulation region Z may be 0 atoms/cm³.

In one example, the concentration of carbon in the first specific layer is higher than the concentration of carbon under the gate of the amplifying transistor 22. This configuration is advantageous from the point of view of reducing dark current. The phrase “under the gate of the amplifying transistor 22” here refers to that portion of a surface of the pixel substrate portion facing the gate electrode 67c which overlaps the gate electrode 67c of the amplifying transistor 22 in planar view. In the expression “the concentration of carbon in the first specific layer is higher than the concentration of carbon under the gate of the amplifying transistor 22” the concentration of carbon under the gate of the amplifying transistor 22 may be zero, or may be higher than zero.

According to a first definition, the phrase “concentration of carbon” in the expression “the concentration of carbon in the first specific layer is higher than the concentration of carbon under the gate of the amplifying transistor 22” is a maximum value of concentration. According to a second definition, the phrase “concentration of carbon” in this expression is an average concentration. In the aforementioned example, a case where it can be said on the basis of at least one selected from the group consisting of the first definition and the second definition that “the concentration of carbon in the first specific layer is higher than the concentration of carbon under the gate of the amplifying transistor 22” is treated as a case where “the concentration of carbon in the first specific layer is higher than the concentration of carbon under the gate of the amplifying transistor 22”.

In one example, the amplifying transistor 22 does not have an extension diffusion layer.

Incidentally, the gate electrode 302 of the first peripheral transistor 27 may be made, for example, of phosphorus-doped polysilicon. In that case, however, phosphorus may exude to the first peripheral substrate portion when the first peripheral region R2 is heated by heat treatment for heating the pixel region R1. In this respect, an imaging device according to one example has a high-k metal gate constructed in the first peripheral transistor 27. This makes it possible to reduce or avoid the exudation of the impurity from the gate electrode 302 to the first peripheral substrate portion. This may contribute to the suppression of the short channel effect in the first peripheral transistor 27. Specifically, the high-k metal gate can be constructed by the gate electrode 302, which is made of metal, and the gate insulator film 301, which is made of a high-k material. The term “high-k material” refers to a material having a higher dielectric constant than silicon dioxide. Examples of high-k materials include oxides or nitrides of hafnium (Hf), zirconium (Zr), and aluminum (Al). High-k materials are also referred to as “high-dielectric-constant materials”.

The first peripheral region R2 may have one first peripheral transistor 27 or may have a plurality of first peripheral transistors 27.

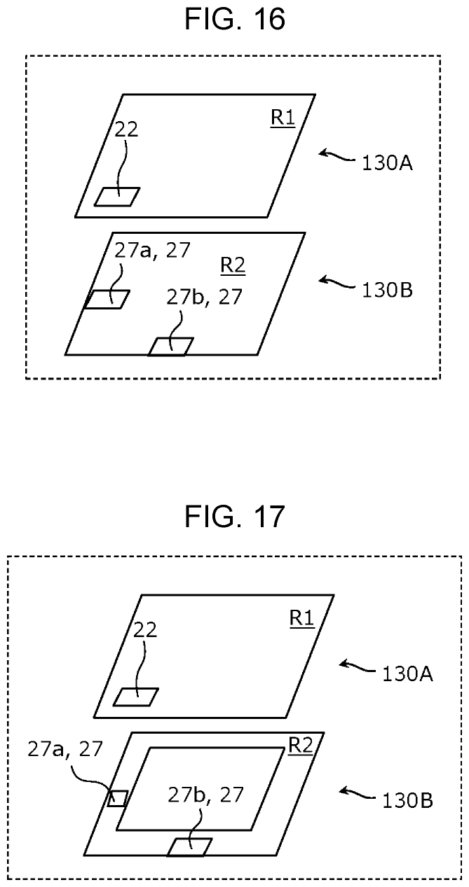

In each of the examples shown in FIGS. 16 and 17, the first peripheral region R2 has a plurality of first peripheral transistors 27. The first peripheral region R2 and the pixel region R1 are stacked on top of each other. The pixel region R1 is constituted using the semiconductor substrate 130A. The first peripheral region R2 is constituted using the semiconductor substrate 130B.

FIG. 16 schematically shows an amplifying transistor 22 in the pixel region R1 and a plurality of first peripheral transistors 27 in the first peripheral region R2 in a case where the first peripheral region R2 is in the shape of a rectangle in planar view. FIG. 17 schematically shows an amplifying transistor 22 in the pixel region R1 and a plurality of first peripheral transistors 27 in the first peripheral region R2 in a case where the first peripheral region R2 is in the shape of a frame in planar view. Specifically, in FIG. 17, the first peripheral region R2 is in the shape of a square in planar view. The first peripheral region R2 may be in the shape of letter L or in the shape of letter U in planar view.

In each of the examples shown in FIGS. 16 and 17, the first peripheral region R2 has a plurality of first peripheral transistors 27. The plurality of first peripheral transistors 27 include transistors 27a and 27b. The expression “a plurality of the first peripheral transistors 27 are present” is not intended to mean that those transistors are completely identical. The same applies to the after-mentioned “two first peripheral transistors”.

As shown in FIGS. 18 and 19, the imaging device may include a second peripheral region R3. The second peripheral region R3 has a second peripheral transistor 427. In one example, the second peripheral transistor 427 is a logic transistor. The second peripheral transistor 427 may be a planar transistor, or may be a three-dimensional structural transistor. A first example of a three-dimensional structural transistor is a FinFET (fin field-effect transistor). A second example of a three-dimensional structural transistor is a GAA (gate all around) such as a nanowire FET. A third example of a three-dimensional structural transistor is a nanosheet FET.

In each of the examples shown in FIGS. 18 and 19, the first peripheral region R2 and the pixel region R1 are stacked on top of each other. The second peripheral region R3 and the pixel region R1 are stacked on top of each other. The pixel region R1 is constituted using the semiconductor substrate 130A. The first peripheral region R2 and the second peripheral region R3 are constituted using the semiconductor substrate 130B. In planar view, the second peripheral region R3 is located outside the first peripheral region R2. In the example shown in FIG. 18, the second peripheral region R3 is in the shape of letter L in planar view. In the example shown in FIG. 19, the second peripheral region R3 is in the shape of a frame in planar view and surrounds the first peripheral region R2. Specifically, in FIG. 19, the second peripheral region R3 is in the shape of a square in planar view. The second peripheral region R3 may be in the shape of letter U in planar view.

As can be understood from the foregoing description, the imaging device according to each of the examples shown in FIGS. 18 and 19 includes a second peripheral region R3. The second peripheral region R3 has a second peripheral substrate portion and a second peripheral transistor 427. The second peripheral transistor 427 is provided in the second peripheral substrate portion. The first peripheral substrate portion and the second peripheral substrate portion are included in the semiconductor substrate 130B. In each of the examples shown in FIGS. 18 and 19, the second peripheral region R3 is located outside the first peripheral region R2.

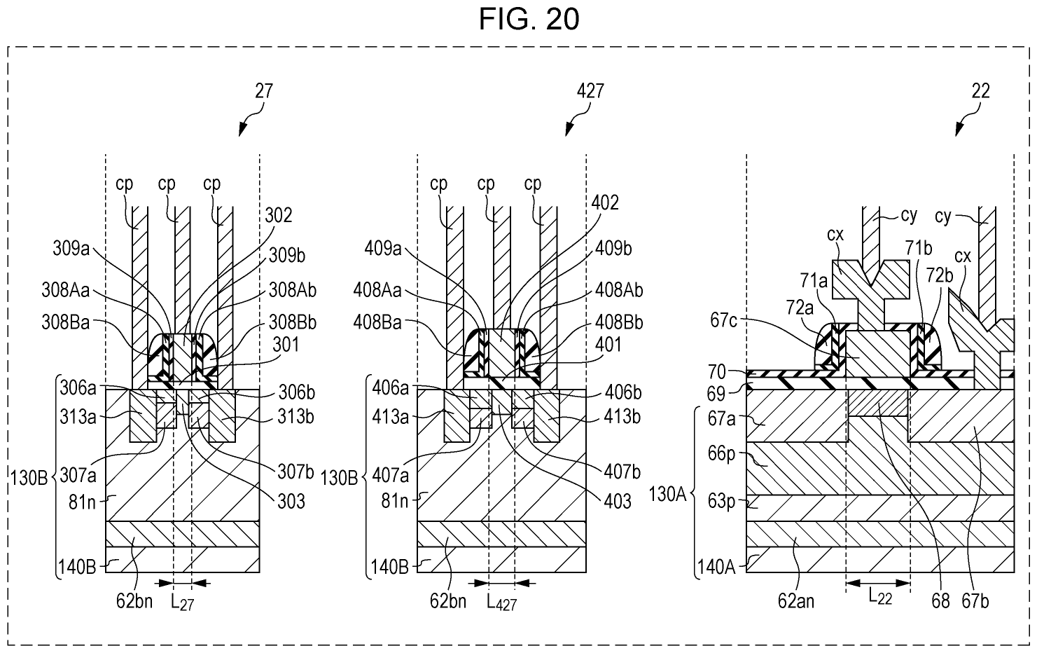

FIG. 20 shows a configuration that the second peripheral transistor 427 in the second peripheral region R3 may have in each of the examples shown in FIGS. 18 and 19. In the example shown in FIG. 20, the second peripheral transistor 427 is a P-channel MOSFET.

In the example shown in FIG. 20, the second peripheral transistor 427 of the second peripheral region R3 have similarities to the first peripheral transistor 27 of the first peripheral region R2. Specifically, as is the case with the first peripheral transistor 27, the second peripheral transistor 427 is a MIS transistor. As is the case with the first peripheral transistor 27, the second peripheral transistor 427 includes a gate electrode 402, a second source 413a, a second drain 413b, second extension diffusion layers 406a and 406b, second pocket diffusion layers 407a and 407b, a channel diffusion layer 403, a gate insulator film 401, offset spacers 409a and 409b, first side walls 408Aa and 408Ab, and second side walls 408Ba and 408Bb. As for these constituent elements, the description of the first peripheral transistor 27 can be invoked in the description of the second peripheral transistor 427, provided no contradiction arises.

In one example, the second peripheral transistor 427 has a second specific layer. The second specific layer is located within the second peripheral substrate portion. The second specific layer contains a conductive impurity.

The conductive impurity of the second specific layer and the conductive impurity of the first specific layer may be identical or different in composition to or from each other.

The second specific layer may contain a specific species. The specific species that the second specific layer has may be the same as or different from the specific species that the first specific layer has. For example, the specific species of the first specific layer may be carbon, and the specific species of the second specific layer may be nitrogen and fluorine. In a case where the second specific layer contains a specific species, the concentration of the specific species in the second specific layer is for example higher than or equal to 5×10¹⁶ atoms/cm³. The concentration of the specific species in the second specific layer may be higher than or equal to 5×10¹⁷ atoms/cm³.

In one example, the second peripheral transistor 427 has the second source 413a and the second drain 413b. At least one selected from the group consisting of the second source 413a and the second drain 413b includes the second specific layer.

In one example, the second peripheral transistor 427 has a second extension diffusion layer. The second extension diffusion layer is adjacent to the second source 413a or the second drain 413b. The second extension diffusion layer is shallower than the second source 413a and the second drain 413b. The second extension diffusion layer includes the second specific layer. The second extension diffusion layer is the second extension diffusion layer 406a or the second extension diffusion layer 406b.

The sentence “the second extension diffusion layer is shallower than the second source 413a and the second drain 413b” means that the deepest portion of the second extension diffusion layer is at a shallower depth than the deepest portions of the second source 413a and the second drain 413b in a direction parallel with the depth of the second peripheral substrate portion. In this context, the word “shallow” can also be referred to as “shallow injunction depth”.

In the illustrated example, the second peripheral transistor 427 has the second extension diffusion layer 406a and the second extension diffusion layer 406b. The second extension diffusion layer 406a is adjacent to the second source 413a. The second extension diffusion layer 406a is shallower than the second source 413a and the second drain 413b. The second extension diffusion layer 406b is adjacent to the second drain 413b. The second extension diffusion layer 406b is shallower than the second source 413a and the second drain 413b. The second extension diffusion layer 406a and the second extension diffusion layer 406b include the second specific layer.

In one example, the second peripheral transistor 427 has a second pocket diffusion layer. The second pocket diffusion layer is adjacent to the second source 413a or the second drain 413b. The second pocket diffusion layer includes the second specific layer. The second pocket diffusion layer is the second pocket diffusion layer 407a or the second pocket diffusion layer 407b.

In the illustrated example, the second peripheral transistor 427 has the second pocket diffusion layer 407a and the second pocket diffusion layer 407b. The second pocket diffusion layer 407a is adjacent to the second source 413a. The second pocket diffusion layer 407b is adjacent to the second drain 413b. The second pocket diffusion layer 407a and the second pocket diffusion layer 407b include the second specific layer.

Only one selected from among the second source 413a, the second drain 413b, the second extension diffusion layer, and the second pocket diffusion layer may include the second specific layer. Specifically, only one selected from among the second source 413a, the second drain 413b, the second extension diffusion layer 406a, the second extension diffusion layer 406b, the second pocket diffusion layer 407a, and the second pocket diffusion layer 407b may include the second specific layer.

Two or more selected from among the second source 413a, the second drain 413b, the second extension diffusion layer, and the second pocket diffusion layer may include the second specific layer. Specifically, two or more selected from among the second source 413a, the second drain 413b, the second extension diffusion layer 406a, the second extension diffusion layer 406b, the second pocket diffusion layer 407a, and the second pocket diffusion layer 407b may include the second specific layer. In a case where these selected two or more include the second specific layer, these may include the same or different types of specific species. For example, the specific species of the second source 413a may be carbon, and the specific species of the second extension diffusion layer may be nitrogen and fluorine. Further, in this case, these may include the same or different conductivity types of conductive impurity. For example, one of the second source 413a and the second pocket diffusion layer may contain boron whose conductivity type is a P type, and the other may contain phosphorus whose conductivity type is an N type.

As can be understood from the foregoing description, the imaging device may have one second specific layer or may have a plurality of second specific layers.

In one example, the concentration of the conductive impurity in the second extension diffusion layer is lower than the concentration of the conductive impurity in the first extension diffusion layer EX1. The second extension diffusion layer is deeper than the first extension diffusion layer EX1. As mentioned above, the first extension diffusion layer EX1 is the first extension diffusion layer 306a or the first extension diffusion layer 306b. Further, the second extension diffusion layer is the second extension diffusion layer 406a or the second extension diffusion layer 406b.

The sentence “the second extension diffusion layer is deeper than the first extension diffusion layer EX1” means that the deepest portion of the second extension diffusion layer is at a greater depth than the deepest portion of the first extension diffusion layer in a direction parallel with the depth of the first peripheral substrate portion or the second peripheral substrate portion. In this context, the word “deep” can also be referred to as “great injunction depth”.

According to a first definition, the phrase “concentration of the conductive impurity” in the expression “the concentration of the conductive impurity in the second extension diffusion layer is lower than the concentration of the conductive impurity in the first extension diffusion layer” is a maximum value of concentration. According to a second definition, the phrase “concentration of the conductive impurity” in this expression is an average concentration. In the aforementioned example, a case where it can be said on the basis of at least one selected from the group consisting of the first definition and the second definition that “the concentration of the conductive impurity in the second extension diffusion layer is lower than the concentration of the conductive impurity in the first extension diffusion layer” is treated as a case where “the concentration of the conductive impurity in the second extension diffusion layer is lower than the concentration of the conductive impurity in the first extension diffusion layer”. Further, in this expression, the type of the conductive impurity in the first extension diffusion layer and the type of the conductive impurity in the second extension diffusion layer may be the same as or different from each other. For example, the conductive impurity in the first extension diffusion layer may be boron, and the conductive impurity in the second extension diffusion layer may be indium.

In the illustrated example, the second peripheral transistor 427 has the second extension diffusion layer 406a and the second extension diffusion layer 406b. The second extension diffusion layer 406a is adjacent to the second source 413a. The second extension diffusion layer 406a is shallower than the second source 413a and the second drain 413b. The second extension diffusion layer 406a has a conductive impurity. The second extension diffusion layer 406b is adjacent to the second drain 413b. The second extension diffusion layer 406b is shallower than the second source 413a and the second drain 413b. The second extension diffusion layer 406b has a conductive impurity. The concentration of the conductive impurity in the second extension diffusion layer 406a is lower than the concentration of the conductive impurity in the first extension diffusion layer 306a. The second extension diffusion layer 406a is deeper than the first extension diffusion layer 306a. The concentration of the conductive impurity in the second extension diffusion layer 406b is lower than the concentration of the conductive impurity in the first extension diffusion layer 306b. The second extension diffusion layer 406b is deeper than the first extension diffusion layer 306b.

In one example, the gate length L₂₇ of the first peripheral transistor 27 is shorter than the gate length L₄₂₇ of the second peripheral transistor 427. In terms of miniaturization of the first peripheral transistor 27 and from the point of view of causing the first peripheral transistor 27 to operate at high speed, it is advantageous for the gate length L₂₇ of the first peripheral transistor 27 to be short. In one specific example, the second peripheral transistor 427 is included in an analog processor, and the first peripheral transistor 27 is included in a digital processor. In this specific example, employing the first peripheral transistor 27 and the second peripheral transistor 427 with different gate lengths allows the digital processor to achieve digital processing making use of the high-speed operation of the first peripheral transistor 27, whose gate length L₂₇ is short. Since the first peripheral transistor 27 is finer, the speeding up of digital processing in the digital processing becomes possible. Meanwhile, since the gate length L₄₂₇ is relatively long, variations in the threshold voltage of the second peripheral transistor 427 may be reduced. This makes it also possible to improve the analog characteristics of the second peripheral transistor 427 in the analog processor.

The ratio L₂₇/L₄₂₇ of the gate length L₂₇ of the first peripheral transistor 27 to the gate length L₄₂₇ of the second peripheral transistor 427 is for example lower than or equal to 0.8, or may be lower than or equal to 0.34. This ratio is for example higher than or equal to 0.01, or may be higher than or equal to 0.05.

In one example, the gate length L₂₂ of the amplifying transistor 22 is longer than the gate length L₄₂₇ of the second peripheral transistor 427. In terms of improvement in characteristic of the amplifying transistor 22, it is advantageous for the gate length L₂₂ of the amplifying transistor 22 to be long. In one specific example, the amplifying transistor 22 is included in the analog processor. In this specific example, the gate length L₂₂ is increased, and variations in the threshold voltage of the amplifying transistor 22 are reduced, so that it is easy to improve a Pelgrom coefficient. This allows the analog processor to achieve analog processing making use of the favorable analog characteristics of the amplifying transistor 22 based on this ease of improvement.

The ratio L₄₂₇/L₂₂ of the gate length L₄₂₇ of the second peripheral transistor 427 to the gate length L₂₂ of the amplifying transistor 22 is for example lower than or equal to 0.95, or may be lower than or equal to 0.9. This ratio is for example higher than or equal to 0.1, or may be higher than or equal to 0.36.

In one example, the gate insulator film 301 of the first peripheral transistor 27 is thinner than the gate insulator film 401 of the second peripheral transistor 427. In terms of miniaturization of the first peripheral transistor 27 and from the point of view of causing the first peripheral transistor 27 to operate at high speed, it is advantageous for the gate insulator film 301 of the first peripheral transistor 27 to be thin. In one specific example, the second peripheral transistor 427 is included in the analog processor, and the first peripheral transistor 27 is included in the digital processor. In this specific example, employing the first peripheral transistor 27 and the second peripheral transistor 427 with different insulator film thicknesses allows the digital processor to achieve digital processing making use of the high-speed operation of the first peripheral transistor 27, whose gate insulator film 301 is thin. Since the first peripheral transistor 27 is finer, the speeding up of digital processing in the digital processing becomes possible. Meanwhile, since the gate insulator film 401 is relatively thick, variations in the threshold voltage of the second peripheral transistor 427 may be reduced. This makes it also possible to improve the analog characteristics of the second peripheral transistor 427 in the analog processor.

The ratio T₃₀₁/T₄₀₁ of the thickness T₃₀₁ of the gate insulator film 301 of the first peripheral transistor 27 to the thickness T₄₀₁ of the gate insulator film 401 of the second peripheral transistor 427 is for example lower than or equal to 0.7, or may be lower than or equal to 0.36. This ratio is for example higher than or equal to 0.1, or may be higher than or equal to 0.22.

In one example, the gate insulator film 69 of the amplifying transistor 22 is thicker than the gate insulator film 401 of the second peripheral transistor 427. In terms of improvement in characteristic of the amplifying transistor 22, it is advantageous for the gate insulator film 69 of the amplifying transistor 22 to be thick. In one specific example, the amplifying transistor 22 is included in the analog processor. In this specific example, the gate insulator film 69 is thickened, and variations in the threshold voltage of the amplifying transistor 22 are reduced, so that it is easy to improve a Pelgrom coefficient. This allows the analog processor to achieve analog processing making use of the favorable analog characteristics of the amplifying transistor 22 based on this ease of improvement.

The ratio T₄₀₁/T₆₉ of the thickness T₄₀₁ of the gate insulator film 401 of the second peripheral transistor 427 to the thickness T₆₉ of the gate insulator film 69 of the amplifying transistor 22 is for example lower than 1. This ratio is for example higher than or equal to 0.68.

In one specific example, the second peripheral transistor 427 is a logic transistor. The second peripheral transistor 427 can perform an analog operation in a state of being incorporated in a pixel driver, a load cell, a column amplifier, a comparator, or other devices. In the analog operation, it may be advantageous for a dynamic range to be wide. In order to secure a wide dynamic range, it is advantageous for a transistor to have a high operating voltage and a wide voltage range. For example, in the case of a pixel voltage of approximately 3 V to 3.5 V, it may be advantageous for the operating voltage to be 3.3 V. In this respect, in this specific example, the gate length L₄₂₇ of the second peripheral transistor 427 is longer than the gate length L₂₇ of the first peripheral transistor 27. The gate insulator film 401 of the second peripheral transistor 427 is thicker than the gate insulator film 301 of the first peripheral transistor 27. From the point of view of raising the operating voltage of the second peripheral transistor 427, it is advantageous from the gate length L₄₇ to be long and for the gate insulator film 401 to be thick. In the aforementioned context, the operating voltage is the drain voltage of a transistor when the transistor is on. The pixel voltage is the voltage of a charge accumulation node in a pixel.

In this specific example, the operating voltage of the second peripheral transistor 427 is higher than the operating voltage of the first peripheral transistor 27. The operating voltage of the second peripheral transistor 427 is for example 3.3 V. The operating voltage of the first peripheral transistor 27 is for example 1.2 V.

In this specific example, variations in the threshold voltage of the second peripheral transistor 427 are small, as the second peripheral transistor 427 is longer in gate length and greater in gate insulator film thickness than the first peripheral transistor 27. Small variations in threshold voltage are a favorable feature. Further, in this specific example, the threshold voltage of the second peripheral transistor 427 is higher than the threshold voltage of the first peripheral transistor 27. The threshold voltage of the second peripheral transistor 427 is for example approximately 0.5 V. The threshold voltage of the first peripheral transistor 27 is for example approximately 0.3 V.

In one example, the concentration of the specific species in the first specific layer is higher than the concentration of the specific species in the second specific layer. In the expression “the concentration of the specific species in the first specific layer is higher than the concentration of the specific species in the second specific layer”, the concentration of the specific species in the second specific layer may be zero, or may be higher than zero.

According to a first definition, the phrase “concentration of the specific layer” in the expression “the concentration of the specific species in the first specific layer is higher than the concentration of the specific species in the second specific layer” is a maximum value of concentration. According to a second definition, the phrase “concentration of the specific species” in this expression is an average concentration. In the aforementioned example, a case where it can be said on the basis of at least one selected from the group consisting of the first definition and the second definition that “the concentration of the specific species in the first specific layer is higher than the concentration of the specific species in the second specific layer” is treated as a case where “the concentration of the specific species in the first specific layer is higher than the concentration of the specific species in the second specific layer”. Further, in this example, the type of the specific species in the first specific layer and the type of the specific species in the second specific layer may be the same as or different from each other. For example, the specific species in the first specific layer may be carbon, and the specific species in the second specific layer may be nitrogen and fluorine.

In a case where the specific species is constituted by plural types of impurity, the concentration of the specific species refers to the total concentration of those plural types of impurity.

The concentration of carbon in the first specific layer may be higher than the concentration of carbon in the second specific layer. The concentration of nitrogen in the first specific layer may be higher than the concentration of nitrogen in the second specific layer. The concentration of fluorine in the first specific layer may be higher than the concentration of fluorine in the second specific layer. The concentration of germanium in the first specific layer may be higher than the concentration of germanium in the second specific layer. The concentration of silicon in the first specific layer may be higher than the concentration of silicon in the second specific layer. The concentration of argon in the first specific layer may be higher than the concentration of argon in the second specific layer.

In one example, the concentration of carbon in the second specific layer is higher than the concentration of carbon under the gate of the amplifying transistor 22. As mentioned above, the phrase “under the gate of the amplifying transistor 22” refers to that portion of the surface of the pixel substrate portion facing the gate electrode 67c which overlaps the gate electrode 67c of the amplifying transistor 22 in planar view. In the expression “the concentration of carbon in the second specific layer is higher than the concentration of carbon under the gate of the amplifying transistor 22”, the concentration of carbon under the gate of the amplifying transistor 22 may be zero, or may be higher than zero.

According to a first definition, the phrase “concentration of carbon” in the expression “the concentration of carbon in the second specific layer is higher than the concentration of carbon under the gate of the amplifying transistor 22” is a maximum value of concentration. According to a second definition, the phrase “concentration of carbon” in this expression is an average concentration. In the aforementioned example, a case where it can be said on the basis of at least one selected from the group consisting of the first definition and the second definition that “the concentration of carbon in the second specific layer is higher than the concentration of carbon under the gate of the amplifying transistor 22” is treated as a case where “the concentration of carbon in the second specific layer is higher than the concentration of carbon under the gate of the amplifying transistor 22”.

In one example, the second extension diffusion layer contains nitrogen.

In the illustrated example, the second extension diffusion layer 406a contains nitrogen. The second extension diffusion layer 406b contains nitrogen.

The nitrogen of the second extension diffusion layer may be derived from ion implantation of nitrogen (N) ions, or may be derived from implantation of nitrogen molecules N₂. In the illustrated example, the nitrogen of the second extension diffusion layer 406a may be derived from ion implantation of nitrogen (N) ions, or may be derived from implantation of nitrogen molecules N₂. The nitrogen of the second extension diffusion layer 406b may be derived from ion implantation of nitrogen (N) ions, or may be derived from implantation of nitrogen molecules N₂. The same applies to the carbon in the first extension diffusion layer EX1 and the first extension diffusion layers 306a and 306b in that the carbon may be derived from ion implantation.

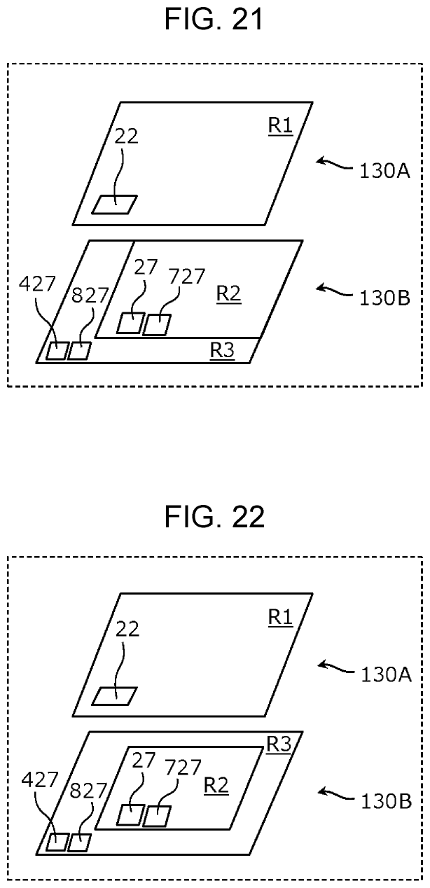

Of course, a transistor other than the transistors shown in FIGS. 18 to 20 may be provided. In each of the examples shown in FIGS. 21 to 24, the first peripheral region R2 has a first peripheral transistor 27 and a first peripheral transistor 727. A device isolation 222 is disposed between the first peripheral transistor 27 and the first peripheral transistor 727. The second peripheral region R3 has a second peripheral transistor 427 and a second peripheral transistor 827.

In planar view, the second peripheral region R3 is located outside the first peripheral region R2. In the example shown in FIG. 21, the second peripheral region R3 is in the shape of letter L in planar view. In the example shown in FIG. 22, the second peripheral region R3 is in the shape of a frame in planar view and surrounds the first peripheral region R2. Specifically, in FIG. 22, the second peripheral region R3 is in the shape of a square in planar view. The second peripheral region R3 may be in the shape of letter U in planar view.

The device isolation 222 is disposed between the second peripheral transistor 427 and the second peripheral transistor 827. It should be noted that FIG. 24 simplistically illustrates the first peripheral transistor 27, the second peripheral transistor 427, and the amplifying transistor 22 and omits to illustrate the device isolation 222.

In each of the examples shown in FIGS. 21 to 24, the first peripheral transistor 727 has similarities to the first peripheral transistor 27. Specifically, as is the case with the first peripheral transistor 27, the first peripheral transistor 727 is a MIS transistor. As is the case with the first peripheral transistor 27, the first peripheral transistor 727 includes a gate electrode 702, a source 713a, a drain 713b, extension diffusion layers 706a and 706b, pocket diffusion layers 707a and 707b, a channel diffusion layer 703, a gate insulator film 701, offset spacers 709a and 709b, first side walls 708Aa and 708Ab, and second side walls 708Ba and 708Bb.

Note, however, that the first peripheral transistor 27 and the first peripheral transistor 727 are opposite in polarity to each other. Specifically, the first peripheral transistor 27 is a P-channel transistor, and the first peripheral transistor 727 is an N-channel transistor. The P-type source diffusion layer 313a, which serves as a source, is of a P type, and the source 713a is of an N type. The P-type drain diffusion layer 313b, which serves as a drain, is of a P type, and the source 713b is of an N type. The first extension diffusion layer 306a is of a P type, and the extension diffusion layer 706a is of an N type. The first extension diffusion layer 306b is of a P type, and the extension diffusion layer 706b is of an N type. The first pocket diffusion layer 307a is of an N type, and the pocket diffusion layer 707a is of a P type. The first pocket diffusion layer 307b is of an N type, and the pocket diffusion layer 707b is of a P type. The channel diffusion layer 303 is of an N type, and the channel diffusion layer 703 is of a P type.

In the following, the ordinal numeral “first” may be added to the constituent elements of the first peripheral transistor 727. For example, the source 713a may be referred to as “first source”. Further, the drain 713b may be referred to as “first drain”.

In the illustrated example, the device isolation 222 is an STI structure. The STI structure has a trench (groove) and a filler filling the trench. The filler is for example an oxide. The depth of the trench is for example approximately 500 nm. The STI structure may be formed in the semiconductor substrate 130B by an STI process.

In the illustrated example, the first peripheral region R2 has two first peripheral transistors 27 and 727 and a device isolation 222 that is an STI structure. The device isolation 222, which is the STI structure, provides device isolation of the two first peripheral transistors 27 and 727 from each other. The device isolation 222, which is the STI structure, has a trench. A range of distribution of the specific species in the first specific layer of at least one of the two first peripheral transistors 27 and 727 is shallower than the bottom of the trench. In this context, the phrase “range of distribution of the specific species” refers to a region in which the concentration of the specific species is higher than or equal to 5×10¹⁶ atoms/cm³. The same applies to a range of distribution of carbon or other substances. The term “bottom of the trench” means the deepest portion of the trench in a direction parallel with the depth of the first peripheral substrate portion. As mentioned above, in a case where the specific species is constituted by plural types of impurity, the concentration of the specific species refers to the total concentration of those plural types of impurity.

A range of distribution of carbon in the first specific layer of at least one of the two first peripheral transistors 27 and 727 may be shallower than the bottom of the trench. A range of distribution of nitrogen in the first specific layer of at least one of the two first peripheral transistors 27 and 727 may be shallower than the bottom of the trench. A range of distribution of fluorine in the first specific layer of at least one of the two first peripheral transistors 27 and 727 may be shallower than the bottom of the trench. A range of distribution of germanium in the first specific layer of at least one of the two first peripheral transistors 27 and 727 may be shallower than the bottom of the trench. A range of distribution of silicon in the first specific layer of at least one of the two first peripheral transistors 27 and 727 may be shallower than the bottom of the trench. A range of distribution of argon in the first specific layer of at least one of the two first peripheral transistors 27 and 727 may be shallower than the bottom of the trench.

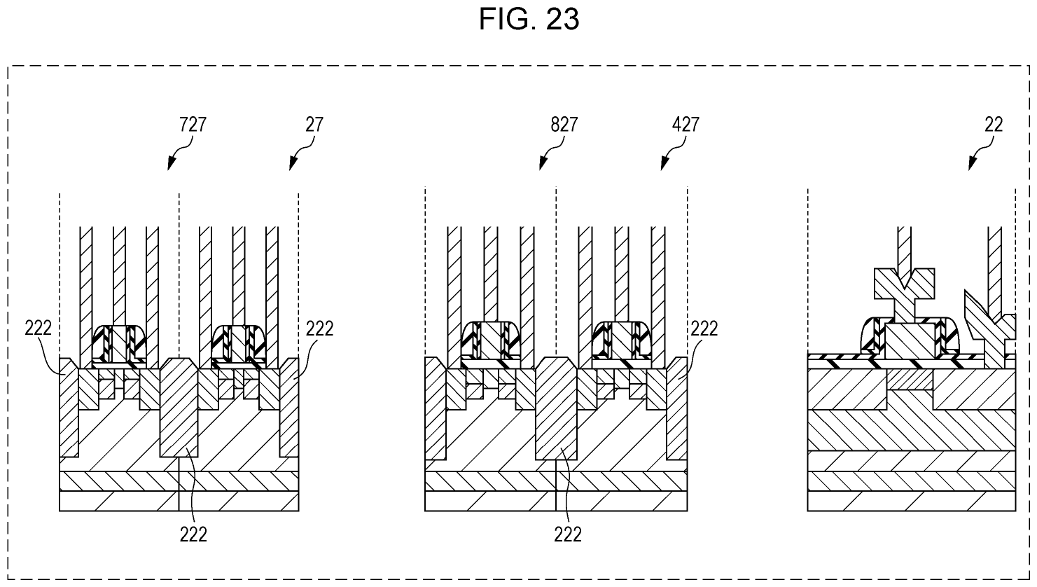

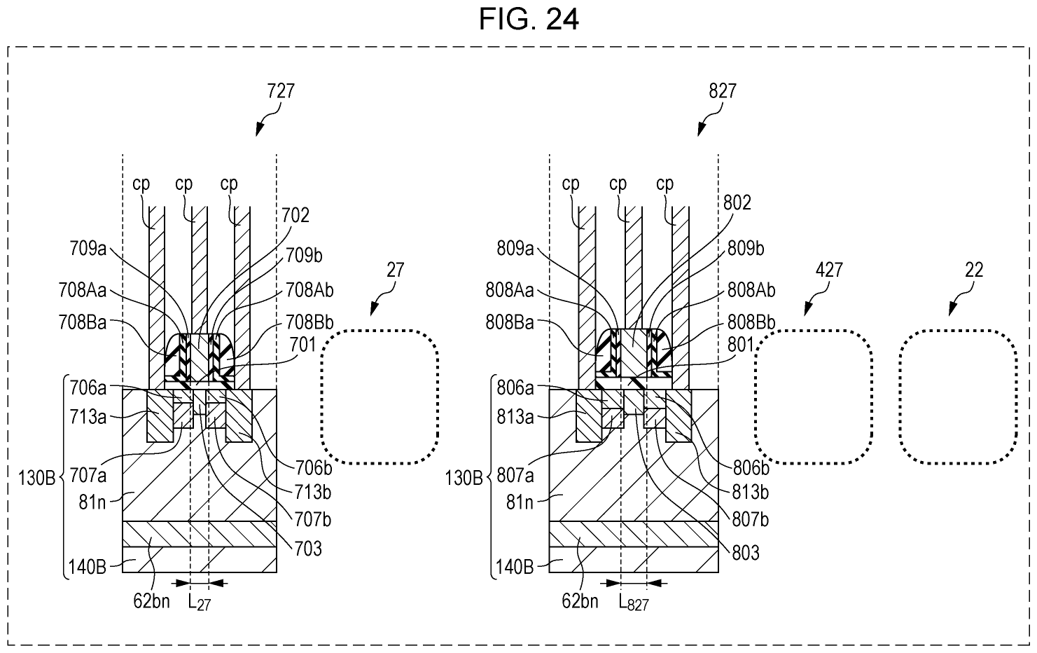

Specifically, the two first peripheral transistors 27 and 727 are opposite in polarity to each other. In planar view, the device isolation 222, which is the STI structure, is disposed between the two first peripheral transistors 27 and 727 and, more specifically, on a segment connecting the two first peripheral transistors 27 and 727 with each other. The specific species contributes to impurity diffusion inhibition. As illustrated in FIG. 23, the STI structure may project upward from a portion of the first peripheral substrate portion that is present around the STI structure.

It should be noted that the device isolation 222 may be an implantation isolation region.

In each of the examples shown in FIGS. 21 to 24, the second peripheral transistor 827 has similarities to the second peripheral transistor 427. Specifically, as is the case with the second peripheral transistor 427, the second peripheral transistor 827 is a MIS transistor. As is the case with the second peripheral transistor 427, the second peripheral transistor 827 includes a gate electrode 802, a source 813a, a drain 813b, extension diffusion layers 806a and 806b, pocket diffusion layers 807a and 807b, a channel diffusion layer 803, a gate insulator film 801, offset spacers 809a and 809b, first side walls 808Aa and 808Ab, and second side walls 808Ba and 808Bb.

Note, however, that the second peripheral transistor 427 and the second peripheral transistor 827 are opposite in polarity to each other. Specifically, the second peripheral transistor 427 is a P-channel transistor, and the second peripheral transistor 827 is an N-channel transistor. The second source 413a is of a P type, and the source 813a is of an N type. The second drain 413b is of a P type, and the source 813b is of an N type. The second extension diffusion layer 406a is of a P type, and the extension diffusion layer 806a is of an N type. The second extension diffusion layer 406b is of a P type, and the extension diffusion layer 806b is of an N type. The second pocket diffusion layer 407a is of an N type, and the pocket diffusion layer 807a is of a P type. The first pocket diffusion layer 407b is of an N type, and the pocket diffusion layer 807b is of a P type. The channel diffusion layer 403 is of an N type, and the channel diffusion layer 803 is of a P type.

The ordinal numeral “second” may be added to the constituent elements of the second peripheral transistor 827. For example, the source 813a may be referred to as “second source”. Further, the drain 813b may be referred to as “second drain”.

Let it be emphatically said that the second peripheral region R3 is not essential. Of course, the second peripheral transistors 427 and 827 are not essential. Further, in the first peripheral region R2, at least one of the first peripheral transistors 27 and 727 may be used in analog processing. In one specific example, in the first peripheral region R2, one first peripheral transistor is used in digital processing, and another first peripheral transistor is used in analog processing.

The description of the first peripheral transistor 27 and elements thereof can be invoked in the description of the first peripheral transistor 727 and elements thereof, provided no contradiction arises. The description of the second peripheral transistor 427 and elements thereof can be invoked in the description of the second peripheral transistor 827 and elements thereof, provided no contradiction arises. The description of a relationship among the first peripheral transistor 27, the second peripheral transistor 427, and the amplifying transistor 22 can be invoked in the description of a relationship among the first peripheral transistor 727, the second peripheral transistor 827, and the amplifying transistor 22, provided no contradiction arises.

For example, the gate length L₇₂₇ of the first peripheral transistor 727 may be shorter than the gate length L₂₂ of the amplifying transistor 22. The gate length L₇₂₇ of the first peripheral transistor 727 may be shorter than the gate length L₈₂₇ of the second peripheral transistor 827. The gate length L₈₂₇ of the second peripheral transistor 827 may be shorter than the gate length L₂₂ of the amplifying transistor 22. The extension diffusion layer 706a may be shallower than the source 713a and the drain 713b. The extension diffusion layer 706b may be shallower than the source 713a and the drain 713b. The extension diffusion layer 806a may be shallower than the source 813a and the drain 813b. The extension diffusion layer 806b may be shallower than the source 813a and the drain 813b. The extension diffusion layer 706a may contain a conductive impurity and a specific species. The extension diffusion layer 706b may contain a conductive impurity and a specific species. The extension diffusion layer 806a may contain nitrogen. The nitrogen of the extension diffusion layer 806a may be derived from ion implantation of nitrogen (N) ions, or may be derived from implantation of nitrogen molecules N₂. The extension diffusion layer 806b may contain nitrogen. The nitrogen of the extension diffusion layer 806b may be derived from ion implantation of nitrogen (N) ions, or may be derived from implantation of nitrogen molecules N₂.

As can be understood from the foregoing description, in the imaging device, at least one selected from the group consisting of the extension diffusion layer 806a and the extension diffusion layer 806b of the second peripheral transistor 827, which is an N-channel transistor, may contain nitrogen. This nitrogen affects not only the distribution of impurities in the second peripheral substrate portion but also the interface characteristics of the gate insulator film of the second peripheral transistor 827, thereby bringing about improvement in reliability of the imaging device. At least one selected from the group consisting of the extension diffusion layer 806a and the extension diffusion layer 806b that contains the aforementioned nitrogen may be a so-called LDD diffusion layer.

In an example in which at least one selected from the group consisting of the extension diffusion layer 806a and the extension diffusion layer 806b of the second peripheral transistor 827, which is an N-channel transistor, contains nitrogen, the second extension diffusion layer 406a of the second peripheral transistor 427, which is a P-channel transistor, may or may not contain nitrogen. In this example, the second extension diffusion layer 406b of the second peripheral transistor 427, which is a P-channel transistor, may or may not contain nitrogen.

In planar view, the amplifying transistor 22, the second peripheral transistor 427, the second peripheral transistor 827, the first peripheral transistor 27, and the first peripheral transistor 727 are arranged in this order.

The matters described with reference to FIGS. 21 to 24 can be applied to the examples shown in FIGS. 13 to 17, provided no contradiction arises.

The foregoing description has taken a front-side illumination (FSI) imaging device as an example. Note, however, that the foregoing description is also applicable to a back-side illumination (BSI) imaging device.

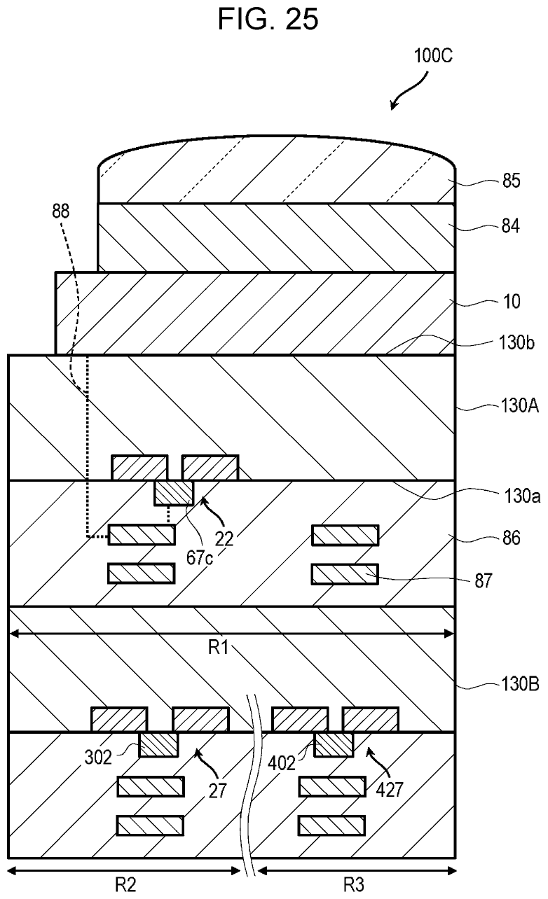

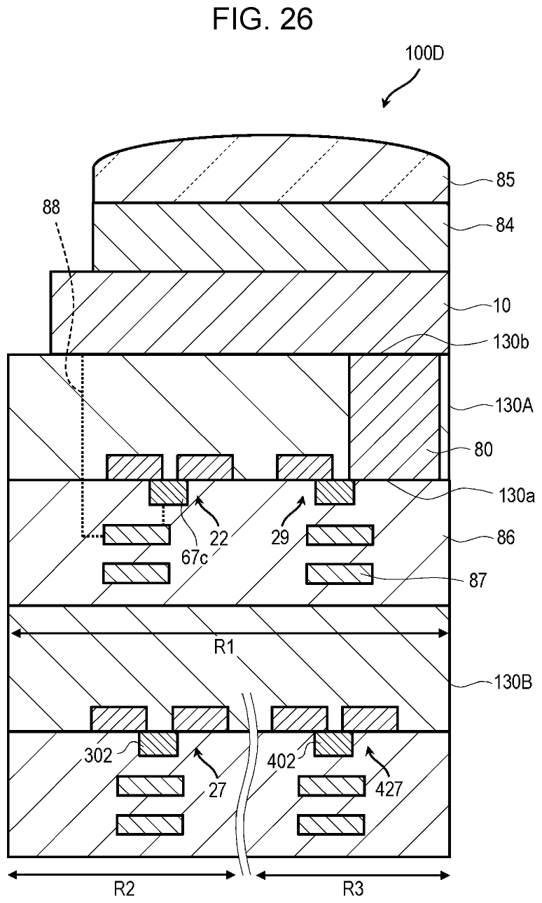

FIG. 25 is a schematic view of a back-side illumination imaging device 100C according to one example.

In the imaging device 100C shown in FIG. 25, the semiconductor substrate 130A has a front surface 130a and a back surface 130b. The back surface 130b is a surface on which light falls. The front surface 130a is a surface opposite to the surface on which light falls.

On the back surface 130b, a photoelectric converter 10 is stacked. On the photoelectric converter 10, a color filter 84 is stacked. On the color filter 84, an on-chip lens 85 is stacked. In a typical example, the semiconductor substrate 130A and the photoelectric converter 10 are joined to each other by joining the photoelectric converter 10 to the back surface 130b with the back surface 130b polished. The color filter 84 and the on-chip lens 85 may be omitted. In at least one selected from the group consisting of the space between the photoelectric converter 10 and the color filter 84 and the space between the color filter 84 and the on-chip lens 85, an interlayer insulator film intended for planarization, protection, or other purposes may be provided.

On the front surface 130a, a wiring layer 86 is stacked. The wiring layer 86 has a plurality of wires 87 provided inside an insulator. The plurality of wires 87 are used for electrical connections to the amplifying transistor 22, the first peripheral transistor 27, and the second peripheral transistor 427. For example, a wire 87 constitutes part of an electrical pathway 88 electrically connecting the pixel electrode 11 of the photoelectric converter 10 to the gate electrode 67c of the amplifying transistor 22. Specifically, in this example, the electrical pathway 88 includes a through-silicon via (TSV) provided in the semiconductor substrate 130A. FIG. 25 omits to illustrate the through-silicon via. In FIG. 25, the dotted line representing the electrical pathway 88 is schematic, and is not intended to limit the position or other features of the electrical pathway 88. Instead of the TSV connection, a Cu—Cu connection may be employed.

Although not illustrated in detail in FIG. 25, the amplifying transistor 22, the first peripheral transistor 27, and the second peripheral transistor 427 may have the features described with reference to FIGS. 1 to 24. The same applies to other elements such as the photoelectric converter 10. Specifically, in this example, the first peripheral transistor 27 and the second peripheral transistor 427 include sources, drains, extension diffusion layers, pocket diffusion layers, or other elements. The semiconductor substrate 130A includes a supporting substrate 140A. The semiconductor substrate 130B includes a supporting substrate 140B.

FIG. 26 is a schematic view of a back-side illumination imaging device 100D according to another example. In the example shown in FIG. 26, the pixel substrate portion pertaining to the pixel region R1 includes a photodiode 80.

The imaging device 100D shown in FIG. 26 includes the elements of the imaging device 100C shown in FIG. 25. The imaging device 100D further includes a photodiode 80 and a transfer transistor 29. The photodiode 80 and the transfer transistor 29 are provided in the semiconductor substrate 130A.

As is the case with the photoelectric converter 10, the photodiode 80 falls under the category of photoelectric converters. The photodiode 80 generates signal charge through photoelectric conversion. The transfer transistor 29 transfers this signal charge to a charge accumulation region (not illustrated).

According to the back-side illumination configuration shown in FIG. 26, the irradiation of the photodiode 80 with light from the on-chip lens 85 and the color filter 84 is not prevented by a wire 87 of the wiring layer 86. This enables the photodiode 80 to carry out efficient photoelectric conversion.

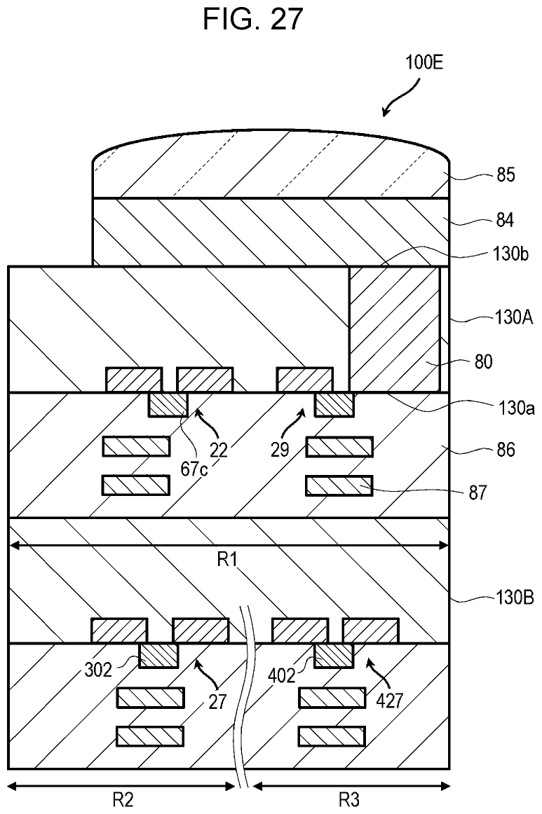

FIG. 27 is a schematic view of a back-side illumination imaging device 100E according to another example.

The imaging device 100E shown in FIG. 27 includes some of the elements of the imaging device 100D shown in FIG. 26. Note, however, that the imaging device 100E shown in FIG. 27 does not have a photoelectric converter 10.

FIGS. 28 to 31 are schematic views showing shapes that the pixel region R1, first peripheral region R2, and second peripheral region R3 of the imaging device 100E shown in FIG. 27 may take.

In the example shown in FIG. 28, the second peripheral region R3 surrounds the first peripheral region R2 in planar view. Specifically, the second peripheral region R3 exhibits a square shape outside the first peripheral region R2 in planar view.

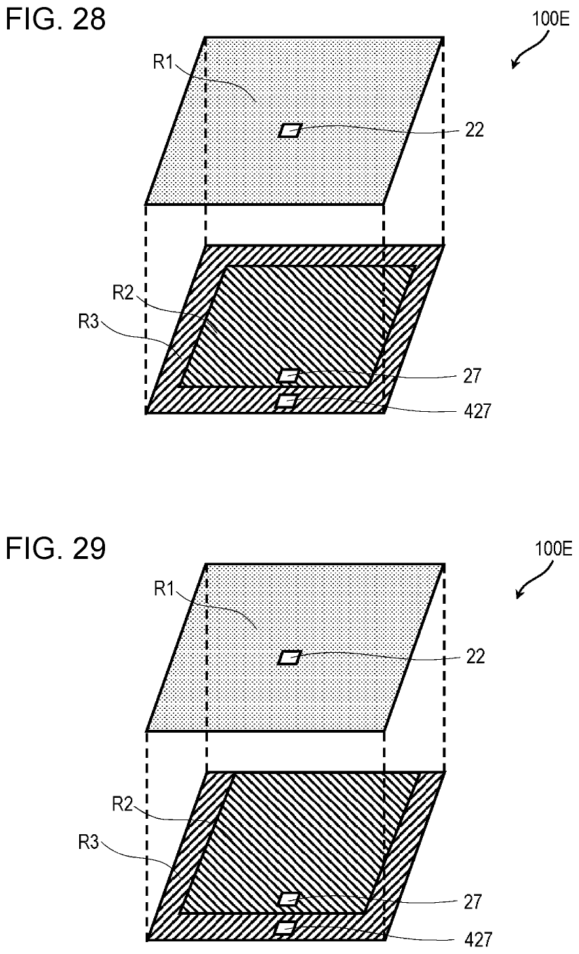

In the example shown in FIG. 29, the second peripheral region R3 exhibits a U-shape outside the first peripheral region R2 in planar view.

In the example shown in FIG. 30, the second peripheral region R3 exhibits an L-shape outside the first peripheral region R2 in planar view.

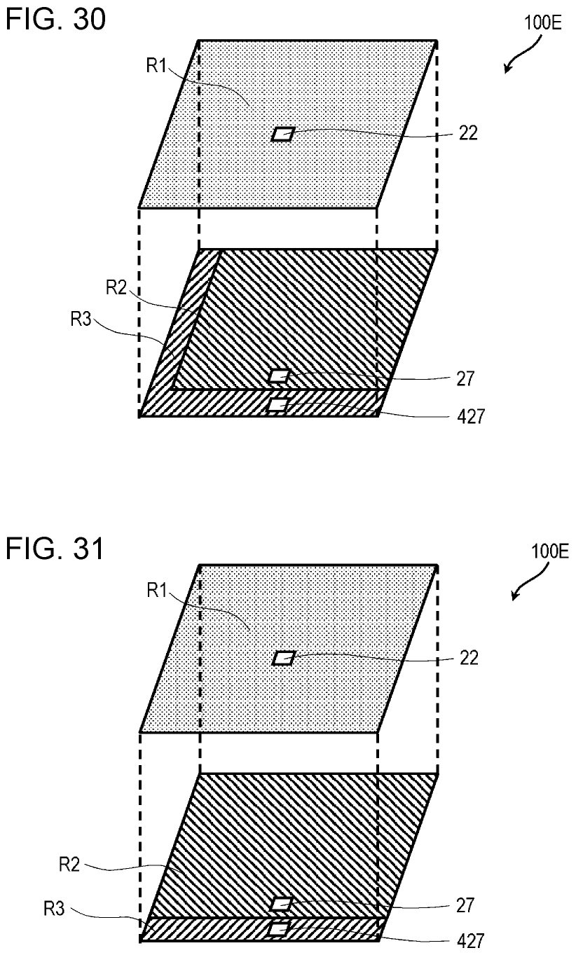

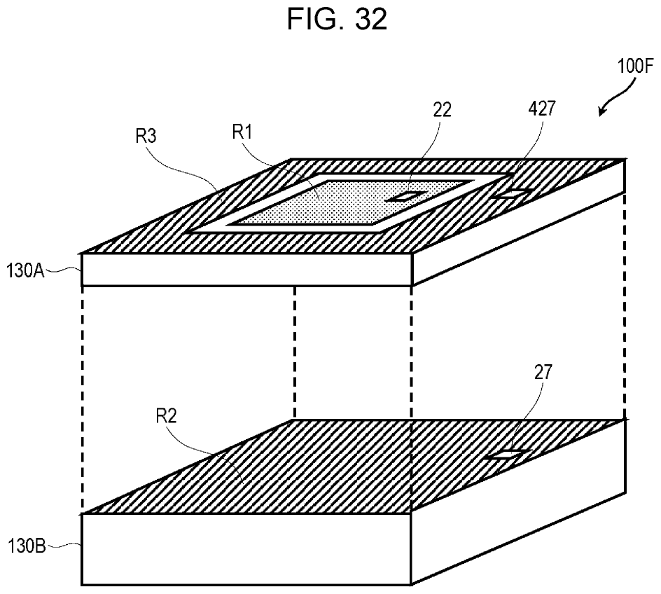

In the example shown in FIG. 31, the second peripheral region R3 extends straight outside the first peripheral region R2 in planar view.

The shapes of the pixel region R1, the first peripheral region R2, and the second peripheral region R3 shown in FIGS. 28 to 31 are also applicable to the imaging devices 100C and 100D shown in FIGS. 25 and 26. Further, these shapes are also applicable to the imaging devices 100A and 100B shown in FIGS. 1 to 24.

As shown in FIG. 3 or other drawings, the imaging device may be a front-side illumination imaging device. In one example of the front-side illumination imaging device, the pixel substrate portion pertaining to the pixel region R1 is disposed above the first peripheral substrate portion pertaining to the first peripheral region R2. The first gate electrode 302 of the first peripheral transistor 27 is disposed above the first peripheral substrate portion. An imaging device having such a configuration may be manufactured by a manufacturing method including fabricating a stacked structure including the pixel substrate portion and the first peripheral substrate portion and then heating the pixel substrate portion in the stacked structure. In this case, it is easy in the first peripheral region R2 to enjoy such a benefit that the redistribution of the conductive impurity is inhibited by a diffusion-inhibiting effect based on a specific species such as carbon.

As shown in FIGS. 25 to 31 or other drawings, the imaging device may be a back-side illumination imaging device. In one example of the back-side illumination imaging device, the pixel substrate portion pertaining to the pixel region R1 is disposed above the first peripheral substrate portion pertaining to the first peripheral region R2. The first gate electrode 302 of the first peripheral transistor 27 is disposed below the first peripheral substrate portion. An imaging device having such a configuration may be manufactured by a manufacturing method including fabricating a stacked structure including the pixel substrate portion and the first peripheral substrate portion and then heating the pixel substrate portion in the stacked structure. In this case, it is easy in the first peripheral region R2 to enjoy such a benefit that the redistribution of the conductive impurity is inhibited by a diffusion-inhibiting effect based on a specific species such as carbon.

In one configuration example, the pixel region R1 has a contact plug cx. The contact plug cx is connected to the charge accumulation region Z. The contact plug cx and the charge accumulation region Z include a predetermined impurity as the conductive impurity. The predetermined impurity is for example phosphorus. Such a configuration may be obtained by a method in which the predetermined impurity doped into the contact plug cx is diffused into the charge accumulation region Z by heating the pixel substrate portion pertaining to the pixel region R1. This heating may cause the first peripheral substrate pertaining to the first peripheral region R2 to be heated too. However, in the first peripheral substrate, the specific species may contribute to the inhibition of the diffusion of the conductive impurity. For this reason, this configuration makes it easy to enjoy such a benefit that the redistribution of the conductive impurity is inhibited by a diffusion-inhibiting effect based on a specific species such as carbon. This configuration may be adopted in both the front-side illumination imaging device and the back-side illumination imaging device.

The front-side illumination imaging device may have the following configuration. That is, in one example of the front-side illumination imaging device, the pixel substrate portion pertaining to the pixel region R1 is disposed below the first peripheral substrate portion pertaining to the first peripheral region R2. The first gate electrode 302 of the first peripheral transistor 27 is disposed above the first peripheral substrate portion. In this configuration, for example, a transistor that can be manufactured by the after-mentioned low-temperature process can be employed as the first peripheral transistor 27.

The back-side illumination imaging device may have the following configuration. That is, in one example of the back-side illumination imaging device, the pixel substrate portion pertaining to the pixel region R1 is disposed below the first peripheral substrate portion pertaining to the first peripheral region R2. The first gate electrode 302 of the first peripheral transistor 27 is disposed below the first peripheral substrate portion. In this configuration, for example, a transistor that can be manufactured by the after-mentioned low-temperature process can be employed as the first peripheral transistor 27.

The configuration of FIG. 32 can also be adopted. In the imaging device 100F shown in FIG. 32, the semiconductor substrate 130A and the semiconductor substrate 130B are stacked on top of each other. The pixel region R1 and the second peripheral region R3 are provided using the semiconductor substrate 130A. The first peripheral region R2 is provided using the semiconductor substrate 130B.

Although not illustrated, at least one selected from the group consisting of a TSV connection and a Cu—Cu connection may be utilized as an electrical connection between a device provided in the semiconductor substrate 130A and a device provided in the semiconductor substrate 130B.

The pixel region R1 has an amplifying transistor 22. The first peripheral region R2 has a first peripheral transistor 27. The second peripheral region R3 has a second peripheral transistor 427.

The pixel substrate portion pertaining to the pixel region R1 and the second peripheral substrate portion pertaining to the second peripheral region R3 are included in the semiconductor substrate 130A. In the example shown in FIG. 32, the second peripheral region R3 is located outside the pixel region R1 in planar view.

In one example, in the imaging device 100F, the second peripheral transistor 427 is a load transistor. The amplifying transistor 22 is connected to the load transistor via the vertical signal line 35.

In one specific example, the aforementioned load transistor functions as a constant current source. A constant current determined by the load transistor flows through the amplifying transistor 22, the vertical signal line 35, and the load transistor in this order. The amplifying transistor 22 and the load transistor form a source follower. For this reason, a voltage corresponding to the gate voltage of the amplifying transistor 22, i.e. the voltage of a charge accumulation region Z, appears in the vertical signal line 35. This state continues as long as the address transistor 24 is on. The load transistor may be included in the load circuit 45 shown in FIG. 2.

In the imaging device 100F, the first peripheral transistor 27 may be included in at least one selected from the group consisting of a comparator and a driver.

In each of the examples shown in FIGS. 25 to 32 too, the contribution of the specific species of the first specific layer to diffusion inhibition makes it possible to reduce dark current in the pixel region R1 while reducing deterioration in performance of the first peripheral transistor 27 attributed to thermal processing.

In each of the examples shown in FIGS. 25 to 32, the pixel region R1, the first peripheral region R2, and the second peripheral region R3 may have the features described with reference to FIGS. 1 to 24. For example, the pixel region R1 may include an address transistor 24, a reset transistor 26, or other devices in addition to the amplifying transistor 22. The first peripheral region R2 may include a first peripheral transistor 727 in addition to the first peripheral transistor 27. The second peripheral region R3 may include a second peripheral transistor 827 in addition to the second peripheral transistor 427.

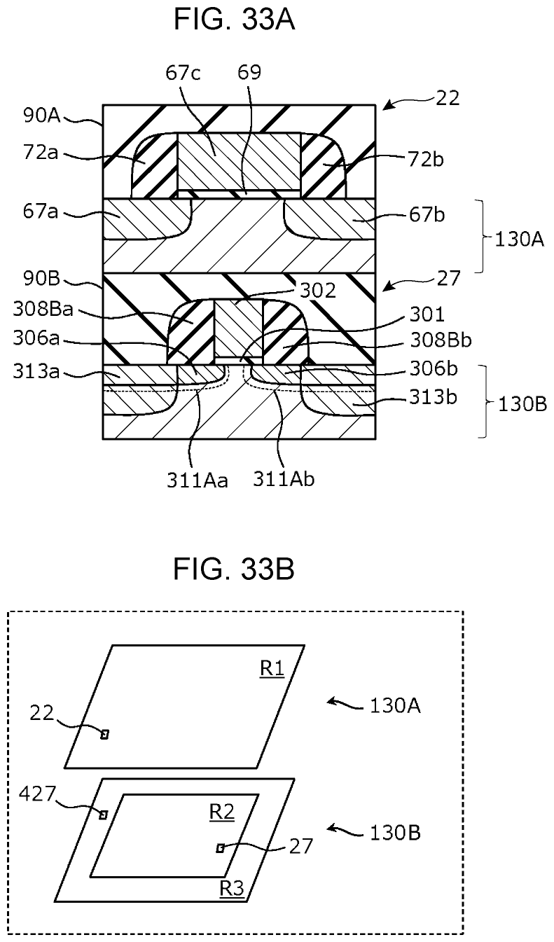

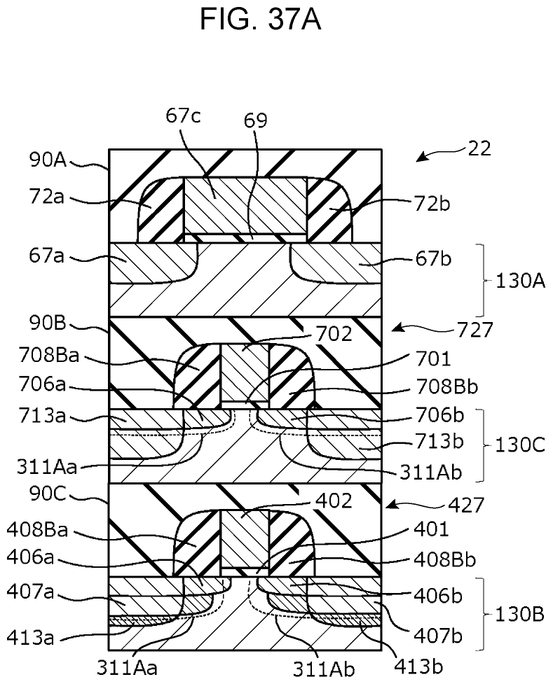

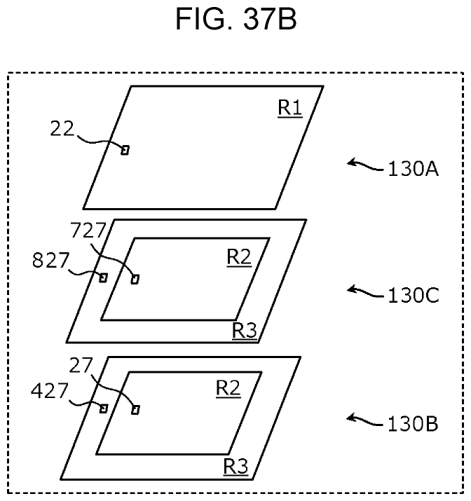

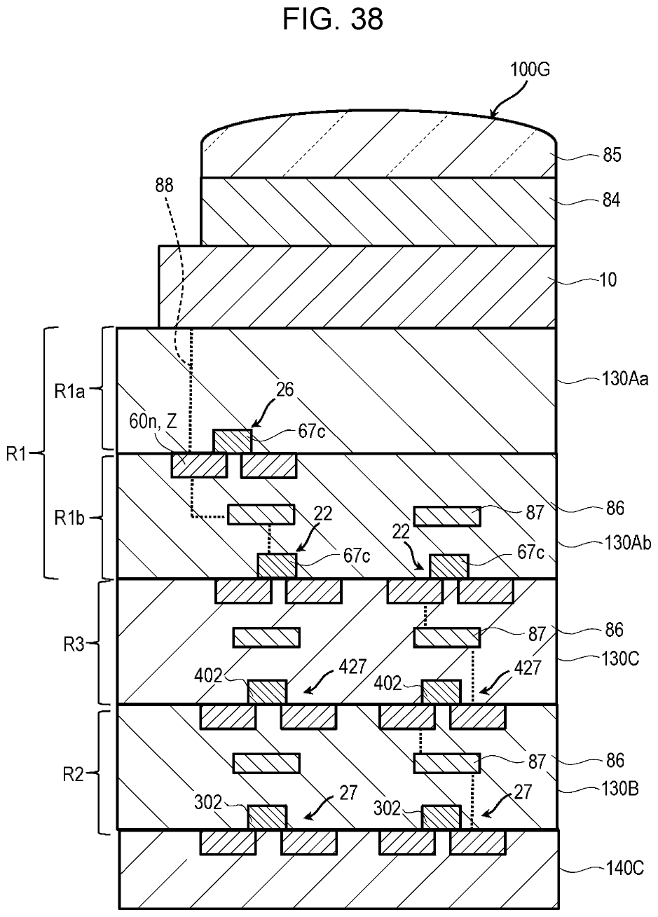

In the following, imaging devices according specific examples of the present disclosure are described with reference to FIGS. 33A to 37B. FIGS. 37A to 37B omit to illustrate the photoelectric conversion layer 12 or other components. In each of FIGS. 33A, 34A, 35A, 36A, and 37A, the solid or dotted lines in the semiconductor substrates 130A, 130B, or 130C schematically represent the boundaries of a region in which an impurity spreads. The dotted lines schematically represent the boundaries of a region in which a specific species spreads. In each of FIGS. 33A, 34A, 35A, 36A, and 37A, the dotted lines are given reference sign 311Aa or 311Ab representing a carbon-implanted layer for illustrative purposes. The insulating part may correspond to the interlayer insulating layers 90A and 90B described earlier.

FIG. 33A is a schematic cross-sectional view of an imaging device according to a first specific example. FIG. 33B is a schematic perspective view of the imaging device according to the first specific example. FIG. 33A omits to illustrate the second peripheral transistor 427. In the imaging device according to the first specific example, the pixel region R1 is constituted using a first semiconductor substrate 130A. The first peripheral region R2 and the second peripheral region R3 are constituted using a second semiconductor substrate 130B. The first peripheral region R2 is surrounded by the second peripheral region R3. In the first specific example, the second semiconductor substrate 130B, the interlayer insulating layer 90B, which is an insulating part, the first semiconductor substrate 130A, the interlayer insulating layer 90A, which is an insulating part, and the photoelectric conversion layer 12 are stacked in this order. An output section that outputs a pixel signal is provided near a peripheral edge of the pixel region R1. This makes it possible to shorten the length of a wire that leads a pixel signal from the pixel region R1 to the second peripheral region R3. This is advantageous from the point of view of securing transfer speed.

In a modification (not illustrated) of the first specific example, the first semiconductor substrate 130A, the interlayer insulating layer 90A, which is an insulating part, the second semiconductor substrate 130B, the interlayer insulating layer 90B, which is an insulating part, and the photoelectric conversion layer 12 are stacked in this order. In this modification, a transistor that can be manufactured by a low-temperature process may be utilized as at least one selected from the group consisting of the peripheral transistors 27 and 427. The low-temperature process may contribute to the securement of the performance of a peripheral transistor, as the low-temperature can better inhibit the diffusion of a conductive impurity than a high-temperature process. Examples of transistors that can be manufactured by the low-temperature process include silicon transistors, germanium transistors, carbon nanotube transistors, TMD (transition metal dichalcogenide) transistors, and oxide semiconductor transistors. Examples of oxide semiconductors of oxide semiconductor transistors include IGZO constituted by In—Ga—Zn—O, IAZO constituted by In—Al—Zn—O, and ITZO constituted by In—Sn—Zn—O. Examples of TMD transistors include molybdenum sulfide (MoS₂) transistors and tungsten sulfide (WS₂) transistors. In a case where a silicon transistor is utilized, it is also possible to use a low-temperature diffusion process, such as solid-phase epitaxial regrowth (SPER), by which an amorphized diffusion layer regrows in a solid phase in a range of approximately 400° C. to 650° C.

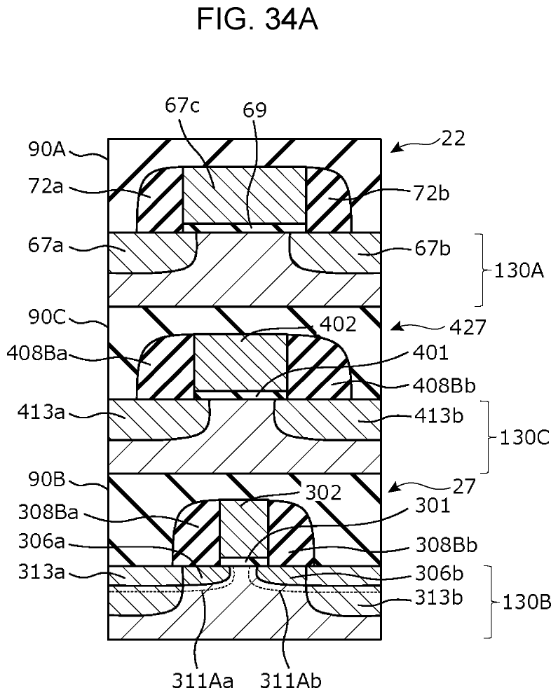

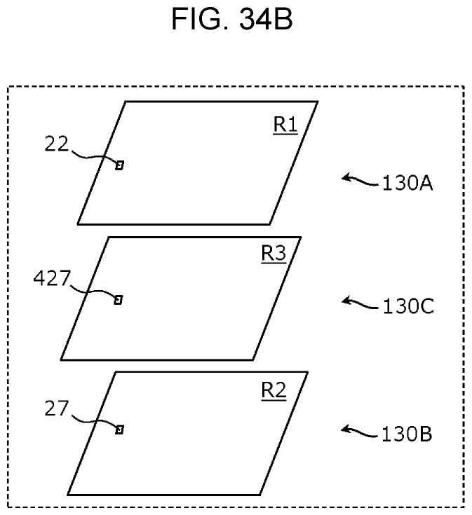

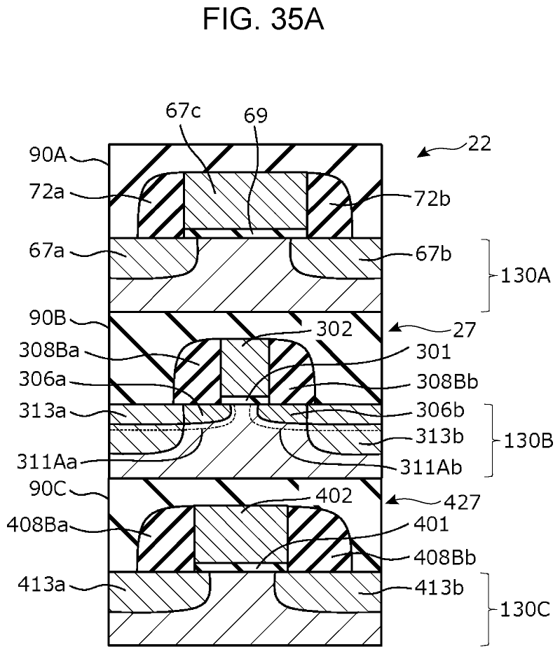

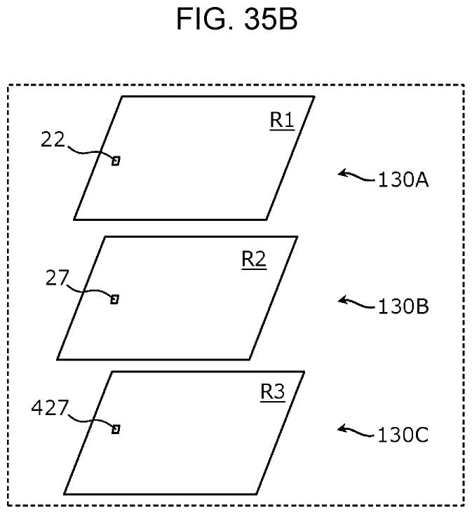

FIG. 34A is a schematic cross-sectional view of an imaging device according to a second specific example. FIG. 34B is a schematic perspective view of the imaging device according to the second specific example. FIG. 35A is a schematic cross-sectional view of an imaging device according to a third specific example. FIG. 35B is a schematic perspective view of an imaging device according to the third specific example. In each of the imaging devices according to the second and third specific examples, the pixel substrate portion pertaining to the pixel region R1, the first peripheral substrate portion pertaining to the first peripheral region R2, and the second peripheral substrate portion pertaining to the second peripheral region R3 are stacked on top of each other. In each of the second and third specific examples, the pixel region R1 is constituted using a first semiconductor substrate 130A. The first peripheral region R2 is constituted using a second semiconductor substrate 130B. The second peripheral region R3 is constituted using a third semiconductor substrate 130C. The pixel substrate portion, the first peripheral substrate portion, and the second peripheral substrate portion are isolated by insulator films or other films, are electrically joined, for example, via plugs, and can exchange signals.

In the second specific example shown in FIGS. 34A and 34B, the first peripheral substrate portion pertaining to the first peripheral region R2, the second peripheral substrate portion pertaining to the second peripheral region R3, and the pixel substrate portion pertaining to the pixel region R1 are stacked in this order. The second semiconductor substrate 130B, the third semiconductor substrate 130C, and the first semiconductor substrate 130A are stacked in this order. The gate length of the second peripheral transistor 427 of the second peripheral region R3 is longer than the gate length of the first peripheral transistor 27 of the first peripheral region R2. This makes it easy to keep the first peripheral transistor 27, which is relatively short in gate length and susceptible to noise, distant from the pixel region R1. This makes it hard for pixel characteristics to be affected by noise from the first peripheral transistor 27. Further, the second peripheral transistor 427, which is relatively long in gate length, can be easily held close to the pixel region R1. This makes it easy to secure the transfer speed of signal charge from the pixel region R1 to the second peripheral transistor 427.

Specifically, in the second specific example, the second semiconductor substrate 130B, the interlayer insulating layer 90B, which is an insulating part, the third semiconductor substrate 130C, an interlayer insulating layer 90C serving as an insulating part, the first semiconductor substrate 130A, the interlayer insulating layer 90A, which is an insulating part, and the photoelectric conversion layer 12 are stacked in this order.

In the third specific example shown in FIGS. 35A and 35B, the second peripheral substrate portion pertaining to the second peripheral region R3, the first peripheral substrate portion pertaining to the first peripheral region R2, and the pixel substrate portion pertaining to the pixel region R1 are stacked in this order. The third semiconductor substrate 130C, the second semiconductor substrate 130B, and the first semiconductor substrate 130A are stacked in this order. The first peripheral transistor 27 of the first peripheral region R2 has a first extension diffusion layer that is shallow in junction depth. In the first extension diffusion layer, which is shallow injunction depth, diffusion of a conductive impurity of the first extension diffusion layer by heat easily causes variations in characteristic of the first peripheral transistor 27. However, in the third specific example, in which the second peripheral region R3, the first peripheral region R2, and the pixel region R1 are stacked in this order, the second peripheral region R3, the first peripheral region R2, and the pixel region R1 can be formed in this order in the process of manufacturing the imaging device. This makes it hard for the first peripheral region R2 to be affected by heat in the formation of the second peripheral region R3. This makes it possible to inhibit the diffusion layer redistribution of the conductive impurity of the first extension diffusion layer and reduce variations in characteristic of the first peripheral transistor 27.

Specifically, in the third specific example, the third semiconductor substrate 130C, an interlayer insulating layer 90C serving as an insulating part, the second semiconductor substrate 130B, the interlayer insulating layer 90B, which is an insulating part, the first semiconductor substrate 130A, the interlayer insulating layer 90A, which is an insulating part, and the photoelectric conversion layer 12 are stacked in this order.

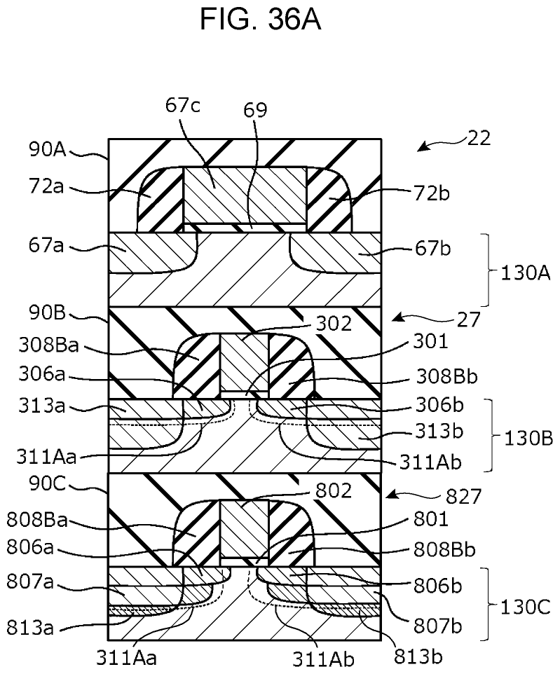

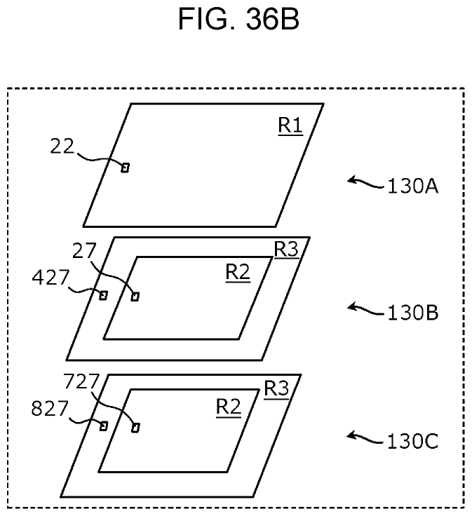

FIG. 36A is a schematic cross-sectional view of an imaging device according to a fourth specific example. FIG. 36B is a schematic perspective view of an imaging device according to the fourth specific example. FIG. 37A is a schematic cross-sectional view of an imaging device according to a fifth specific example. FIG. 37B is a schematic perspective view of an imaging device according to the fifth specific example. In each of the imaging devices according to the fourth and fifth specific examples, the pixel substrate portion pertaining to the pixel region R1 is included in a first semiconductor substrate 130A. The first peripheral substrate portion pertaining to the first peripheral region R2 and the second peripheral substrate portion pertaining to the second peripheral region R3 each have a portion included in a second semiconductor substrate 130B. The first peripheral transistor 27 and the second peripheral transistor 427, which are P-channel transistors, are provided in the second semiconductor substrate 130B. The first peripheral substrate portion pertaining to the first peripheral region R2 and the second peripheral substrate portion pertaining to the second peripheral region R3 each have a portion included in a third semiconductor substrate 130C. The first peripheral transistor 727 and the second peripheral transistor 827, which are N-channel transistors, are provided in the third semiconductor substrate 130C. The first semiconductor substrate 130A, the second semiconductor substrate 130B, and the third semiconductor substrate 130C are stacked on top of each other. Specifically, regarding both the second semiconductor substrate 130B and the third semiconductor substrate 130C, the second peripheral region R3 is located outside the first peripheral region R2 in planar view. More specifically, regarding both the second semiconductor substrate 130B and the third semiconductor substrate 130C, the second peripheral region R3 is in the shape of a frame surrounding the first peripheral region R2 in planar view.

In each of the fourth and fifth specific examples, the P-channel transistors and the N-channel transistors are provided in semiconductor substrates differing from each other. This configuration makes it easy to optimize a process step such as a stacking order of semiconductor substrates in consideration of a change in thermal stability due to diffusion of a P-type impurity and a change in thermal stability due to diffusion of an N-type impurity. Further, in each of the fourth and fifth specific examples, the P-channel transistors and the N-channel transistors are provided not in one semiconductor substrate spreading in the same plane but in stacked semiconductor substrates differing from each other. This configuration makes it easy to reduce the area of a CMOS circuit. For example, this configuration makes it possible to, as in the case of a CFET (complementary FET), form a CMOS by vertically stacking an NFET and a PFET that constitute the CMOS. This makes it easy to reduce the area of a CMOS circuit. The term “vertically stacking” here means staking along a direction parallel with the thickness of a semiconductor substrate. Furthermore, it is also possible to provide the first peripheral transistors and the second peripheral transistors in semiconductor substrates differing from each other. This makes it easier to reduce the area.

Specifically, in each of the fourth and fifth specific examples, the first peripheral transistor 27 is provided in the first peripheral region R2 in the second semiconductor substrate 130B. The second peripheral transistor 427 is provided in the second peripheral region R3 in the second semiconductor substrate 130B. The first peripheral transistor 427 is provided in the first peripheral region R2 in the third semiconductor substrate 130C. The second peripheral transistor 827 is provided in the second peripheral region R3 in the third semiconductor substrate 130C. The first peripheral transistor 27 is a P-type transistor, and an operating voltage of the first peripheral transistor 27 is a first voltage. The second peripheral transistor 427 is a P-type transistor, and an operating voltage of the second peripheral transistor 427 is a second voltage. The first peripheral transistor 727 is an N-type transistor, and an operating voltage of the first peripheral transistor 727 is the first voltage. The second peripheral transistor 827 is an N-type transistor, and an operating voltage of the second peripheral transistor 827 is the second voltage. The first voltage is lower than the second voltage. The first voltage is for example 1.2 V. The second voltage is for example 3.3 V.

Boron (B), which is a representative P-type impurity, is more prone to transient enhanced diffusion than arsenic (As), which is a representative N-type impurity. In the fourth specific example shown in FIGS. 36A and 36B, the third semiconductor substrate 130C, the second semiconductor substrate 130B, and the first semiconductor substrate 130A are stacked in this order. For this reason, in the fourth specific example, the second semiconductor substrate 130B, which has a P-type impurity, can be formed after the third semiconductor substrate 130C, which has an N-type impurity, has been formed. This makes it hard for the first peripheral transistor 27 and the second peripheral transistor 427, which are P-channel transistors, to be affected by heat in the formation of the third semiconductor substrate 130C. This configuration is advantageous from the point of view of inhibiting the transient enhanced diffusion of the conductive impurity.

Meanwhile, in the fifth specific example shown in FIGS. 37A and 37B, the second semiconductor substrate 130B, the third semiconductor substrate 130C, and the first semiconductor substrate 130A are stacked in this order. In a case where this configuration is adopted, the action of the inhibition of transient enhanced diffusion by the specific species of the first specific layer is easily made use of.

FIG. 38 is a schematic cross-sectional view of an imaging device according to a sixth specific example. In the sixth specific example shown in FIG. 38, an imaging device 100G is configured such that a first peripheral region R2, a second peripheral region R3, a pixel transistor section Rib provided in a semiconductor substrate 130Ab, an FD section Ria provided in a semiconductor substrate 130Aa, a photoelectric converter 10, a color filter 84, an on-chip lens 85 are stacked in this order over a supporting substrate 140C. In this specific example, the pixel transistor section Rib and the FD section Ria constitute a pixel region R1. In one example, this stacked structure is manufactured by a three-dimensional stacking technology 3DSI (3D Sequential Integration).

The FD section R1a is provided with a charge accumulation node FD and a reset transistor 26. The charge accumulation node FD has a function of temporarily retaining charge generated by the photoelectric converter 10. The charge accumulation node FD includes as part thereof an impurity region formed in the semiconductor substrate 130Ab. Either a drain or a source of the reset transistor 26 corresponds to an impurity region 60n. The pixel transistor section Rib is provided with a pixel transistor. For example, the amplifying transistor 22 and the address transistor 24 may fall in the category of pixel transistors.

The first peripheral transistors 27 and 727 are provided in the first peripheral region R2. The second peripheral transistors 427 and 827 are provided in the second peripheral region R3. The first peripheral transistor 27 is a P-type transistor, and an operating voltage of the first peripheral transistor 27 is a first voltage. The second peripheral transistor 427 is a P-type transistor, and an operating voltage of the second peripheral transistor 427 is a second voltage. The first peripheral transistor 727 is an N-type transistor, and an operating voltage of the first peripheral transistor 727 is the first voltage. The second peripheral transistor 827 is an N-type transistor, and an operating voltage of the second peripheral transistor 827 is the second voltage. The first voltage is lower than the second voltage. The first voltage is for example 1.2 V. The second voltage is for example 3.3 V.

By thus dividing the pixel region in a longitudinal direction, the area of the amplifying transistor can be increased within a cell pitch, so that noise from the amplifying transistor can be reduced. Further, by disposing the first peripheral transistor of the smallest gate length at the lowermost layer, the distance from the charge accumulation node FD in a longitudinal direction increases, so that the effect of the first peripheral transistor on the charge accumulation node FD can be reduced.

In vertically stacking a plurality of layers in sequence in a 3DSI process, a lower layer is affected by thermal processing of an upper layer. Accordingly, such a transistor structure is preferable that a lower layer is affected less by thermal heating. For example, in a region in a lower layer in which a shallow junction of an extension diffusion layer needs to be retained, thermal tolerance may be increased by inhibiting the diffusion of an impurity by implanting a specific species such as carbon into the extension diffusion layer, or the anneal temperature of a process step of a device in an upper layer may be lowered. In a case where the pixel region is divided in a longitudinal direction, the redistribution of an LDD diffusion layer may be inhibited by implanting carbon into a diffusion layer of a pixel transistor provided at a lower layer. Further, the anneal temperature of the FD section R1a may be lowered. The gate lengths L₂₇ and L₇₂₇ of the first peripheral transistors 27 and 727 may be shorter than the gate length L₂₂ of the amplifying transistor 22. The gate lengths L₂₇ and L₇₂₇ of the first peripheral transistors 27 and 727 may be shorter than the gate lengths L₄₂₇ and L₈₂₇ of the second peripheral transistors 427 and 827.

In terms of miniaturization of the first peripheral transistors 27 and 727 and from the point of view of causing the first peripheral transistors 27 and 727 to operate at high speed, it is advantageous for the gate lengths L₂₇ and L₇₂₇ of the first peripheral transistors 27 and 727 to be short. In one specific example, the second peripheral transistors 427 and 827 are included in the analog processor, and the first peripheral transistors 27 and 727 are included in the digital processor. In this specific example, employing the first peripheral transistors 27 and 727 and the second peripheral transistors 427 and 827 with different gate lengths allows the digital processor to achieve digital processing making use of the high-speed operation of the first peripheral transistors 27 and 727, whose gate lengths L₂₇ and L₇₂₇ are short. Since the first peripheral transistors 27 and 727 are finer, the speeding up of digital processing in the digital processing becomes possible. Meanwhile, since the gate lengths L₄₂₇ and L₈₂₇ are relatively long, variations in the threshold voltage of the second peripheral transistors 427 and 827 may be reduced. This makes it also possible to improve the analog characteristics of the second peripheral transistors 427 and 827 in the analog processor.

The gate lengths L₄₂₇ and L₈₂₇ of the second peripheral transistors 427 and 827 may be shorter than the gate length L₂₂ of the amplifying transistor 22. In one specific example, the amplifying transistor 22 is included in the analog processor. In this specific example, the gate length L₂₂ is increased, and variations in the threshold voltage of the amplifying transistor 22 are reduced, so that it is easy to improve a Pelgrom coefficient. This allows the analog processor to achieve analog processing making use of the favorable analog characteristics of the amplifying transistor 22 based on this ease of improvement.

The extension diffusion layers of the first peripheral transistors 27 and 727 may be shallower than the sources and the drains. The extension diffusion layers of the second peripheral transistors 427 and 827 may be shallower than the sources and the drains. The extension diffusion layers of the first peripheral transistors 27 and 727 may include a conductive impurity and a specific species. The extension diffusion layers of the second peripheral transistors 427 and 827 may include a conductive impurity and a specific species. The extension diffusion layers of the first peripheral transistors 27 and 727 may include nitrogen. The extension diffusion layers of the second peripheral transistors 427 and 827 may include nitrogen.

In each of the first to sixth specific examples, the first specific layer may be provided in both the first peripheral transistor 27 and the second peripheral transistor 427 or only either the first peripheral transistor 27 or the second peripheral transistor 427. The second specific layer may be provided in both the first peripheral transistor 727 and the second peripheral transistor 827 or only either the first peripheral transistor 727 or the second peripheral transistor 827. The second specific layer may be provided in neither the first peripheral transistor 727 nor the second peripheral transistor 827.

Various changes are applicable to the techniques disclosed here. For example, the pocket diffusion layer 707a and pocket diffusion layer 707b of the first peripheral transistor 727 and the pocket diffusion layer 807a and pocket diffusion layer 807b of the second peripheral transistor 827 may be omitted. Further, the blocking regions 200A and 200B may be omitted. Further, a silicide layer may be formed over the drain, source, and gate electrode of the first peripheral transistor 27.

In a first peripheral transistor, a specific species may be contained only in a pocket diffusion layer. In a case where an N-channel MIS transistor is fabricated as such a first peripheral transistor, a specific species is implanted only into a P-type pocket diffusion layer of the transistor. In that case, the concentration of the specific species that is implanted into the P-type pocket diffusion layer may be lower than the concentration of a specific species that is implanted into an extension diffusion layer in a case where the first peripheral transistor of FIG. 5 is fabricated.

In each of the examples shown in FIGS. 18, 19, 21, 22, 28 to 31, 33A, 33B, 36A to 37B or other drawings, the second peripheral region R3 is located outside the first peripheral region R2 in planar view. Note, however, that the second peripheral region R3 may be located inside the first peripheral region R2 in planar view.

Features connected with the second peripheral region R3 may be applied to the first peripheral region R2. For example, the features of the second peripheral transistors 427 and 827 may be applied to the first peripheral transistors 27 and 727.

Features connected with the first peripheral region R2 may be applied to the second peripheral region R3. For example, the features of the first peripheral transistors 27 and 727 may be applied to the second peripheral transistors 427 and 827.

In each of the examples shown in FIGS. 3, 25, 33A, and 33B or other drawings, the first peripheral substrate portion pertaining to the first peripheral region R2, the pixel substrate portion pertaining to the pixel region R1, and the photoelectric converter 10 are stacked in this order. Further, the first peripheral substrate portion, the pixel substrate portion, and the photoelectric conversion layer 12 are stacked in this order. Note, however, that as in the case of the modification of the first specific example shown in FIGS. 33A and 33B, the pixel substrate portion pertaining to the pixel region R1, the first peripheral substrate portion pertaining to the first peripheral region R2, and the photoelectric converter 10 may be stacked in this order. Further, the pixel substrate portion, the first peripheral substrate portion, and the photoelectric converter 10 may be stacked in this order. No matter which stacking order is adopted, the first peripheral transistor may have a specific species. No matter which stacking order is adopted, the first peripheral transistor may have a conductive impurity. No matter which stacking order is adopted, the first peripheral transistor may have a first specific layer.

The first peripheral transistor may be manufactured by the low-temperature process or may be manufactured by a process other than the low-temperature process. No matter what manufacturing method the first peripheral transistor is manufactured by, the first peripheral transistor may have a specific species. No matter what manufacturing method the first peripheral transistor is manufactured by, the first peripheral transistor may have a conductive impurity. No matter what manufacturing method the first peripheral transistor is manufactured by, the first peripheral transistor may have a first specific layer.

An imaging device disclosed here is useful, for example, in an image sensor, a digital camera, or other devices. The imaging device disclosed here can be used, for example, in a camera for medical use, a camera for use in a robot, a security camera, a car-mounted camera, or other cameras.

What is claimed is:

1. An imaging device comprising:
a pixel region including a pixel substrate portion and an amplifying transistor that is located in the pixel substrate portion and that outputs a signal voltage corresponding to an amount of signal charge; and
a first peripheral region including a first peripheral substrate portion and a first peripheral transistor located in the first peripheral substrate portion, wherein
the pixel substrate portion and the first peripheral substrate portion are stacked on each other, and
when at least one type of impurity that contributes to inhibition of transient enhanced diffusion of a conductive impurity is defined as a specific species, the first peripheral transistor includes a first specific layer that is located in the first peripheral substrate portion and that contains the conductive impurity and the specific species.

2. The imaging device according to claim 1, wherein the specific species contains at least one selected from the group consisting of carbon, nitrogen, and fluorine.

3. The imaging device according to claim 1, wherein the specific species contains at least one selected from the group consisting of germanium, silicon, and argon.

4. The imaging device according to claim 1, wherein a gate length of the first peripheral transistor is shorter than a gate length of the amplifying transistor.

5. The imaging device according to claim 1, wherein
the amplifying transistor includes an amplifying gate insulator film,
the first peripheral transistor includes a first peripheral gate insulator film, and
the first peripheral gate insulator film is thinner than the amplifying gate insulator film.

6. The imaging device according to claim 1, wherein
the first peripheral transistor includes a first source, a first drain, and a first extension diffusion layer,
the first extension diffusion layer is adjacent to the first source or the first drain and shallower than the first source and the first drain, and
the first extension diffusion layer includes the first specific layer.

7. The imaging device according to claim 1, wherein
the first peripheral transistor includes a first source, a first drain, and a first pocket diffusion layer,
the first pocket diffusion layer is adjacent to the first source or the first drain, and the first pocket diffusion layer includes the first specific layer.

8. The imaging device according to claim 1, wherein
the pixel substrate portion includes a charge accumulation region serving as an impurity region in which charge generated by photoelectric conversion is accumulated, and
a concentration of carbon in the first specific layer is higher than a concentration of carbon in the charge accumulation region.

9. The imaging device according to claim 1, wherein
the amplifying transistor includes a gate, and
a concentration of carbon in the first specific layer is higher than a concentration of carbon in a portion of a surface of the pixel substrate portion, the portion of the surface overlapping the gate in a plan view.

10. The imaging device according to claim 1, wherein
the pixel region further includes a photoelectric conversion layer, and
the photoelectric conversion layer, the pixel substrate portion, and the first peripheral substrate portion are stacked on each other.

11. The imaging device according to claim 1, wherein
the first peripheral transistor includes an end-of-range defect,
at least part of the first specific layer is located above the end-of-range defect and overlaps the end-of-range defect in a plan view.

12. The imaging device according to claim 1, wherein
the first peripheral transistor includes a segregated portion in which the specific species is segregated in a direction parallel with a depth of the first peripheral substrate portion, and
at least part of the first specific layer is located above the segregated portion and overlaps the segregated portion in a plan view.

13. The imaging device according to claim 1, further comprising an insulating part,
wherein the pixel substrate portion and the first peripheral substrate portion are stacked with the insulating part disposed between the pixel substrate portion and the first peripheral substrate portion.

14. The imaging device according to claim 1, further comprising a second peripheral region including a second peripheral substrate portion and a second peripheral transistor located in the second peripheral substrate portion,
wherein the first peripheral substrate portion and the second peripheral substrate portion are included in one semiconductor substrate.

15. The imaging device according to claim 1, further comprising a second peripheral region including a second peripheral substrate portion and a second peripheral transistor located in the second peripheral substrate portion,
wherein the pixel substrate portion, the first peripheral substrate portion, and the second peripheral substrate portion are stacked on each other.

16. The imaging device according to claim 14, wherein a gate length of the second peripheral transistor is longer than a gate length of the first peripheral transistor and shorter than a gate length of the amplifying transistor.

17. The imaging device according to claim 16, wherein
the second peripheral transistor includes a second specific layer that is located in the second peripheral substrate portion and that contains a conductive impurity, and
a concentration of the specific species in the first specific layer is higher than a concentration of the specific species in the second specific layer.

18. The imaging device according to claim 16, wherein
the amplifying transistor includes an amplifying gate insulator film,
the first peripheral transistor includes a first peripheral gate insulator film,
the second peripheral transistor includes a second peripheral gate insulator film, and
the second peripheral gate insulator film is thicker than the first peripheral gate insulator film and thinner than the amplifying gate insulator film.

19. The imaging device according to claim 14, wherein an operating voltage of the first peripheral transistor is lower than an operating voltage of the second peripheral transistor.

20. The imaging device according to claim 14, wherein a threshold voltage of the first peripheral transistor is lower than a threshold voltage of the second peripheral transistor.

21. The imaging device according to claim 1, wherein
the amplifying transistor includes a gate, a source, and a drain,
the first peripheral transistor includes a gate, a source, and a drain,
the imaging device is configured such that the gate of the amplifying transistor is located closer to a position of incidence of incident light on the imaging device than the source of the amplifying transistor and the drain of the amplifying transistor in a direction parallel with a thickness of the imaging device, and
the imaging device is configured such that the gate of the first peripheral transistor is located closer to the position of incidence of the incident light on the imaging device than the source of the first peripheral transistor and the drain of the first peripheral transistor in the direction parallel with the thickness of the imaging device.

22. The imaging device according to claim 1, wherein
the amplifying transistor includes a gate, a source, and a drain,
the first peripheral transistor includes a gate, a source, and a drain,
the imaging device is configured such that the source of the amplifying transistor and the drain of the amplifying transistor are located closer to a position of incidence of incident light on the imaging device than the gate of the amplifying transistor in a direction parallel with a thickness of the imaging device, and
the imaging device is configured such that the source of the first peripheral transistor and the drain of the first peripheral transistor are located closer to the position of incidence of the incident light on the imaging device than the gate of the first peripheral transistor in the direction parallel with the thickness of the imaging device.

23. The imaging device according to claim 1, wherein the imaging device is configured such that the pixel substrate portion is located closer to a position of incidence of incident light on the imaging device than the first peripheral substrate portion in a direction parallel with a thickness of the imaging device.

24. An imaging device comprising:
a pixel region including a first pixel substrate, an impurity region that is located in the first pixel substrate and that accumulates signal charge, a second pixel substrate, and an amplifying transistor that is located in the second pixel substrate and that outputs a signal voltage corresponding to an amount of the signal charge; and
a peripheral region including a first peripheral substrate and a first peripheral transistor located in the first peripheral substrate, wherein
the first pixel substrate, the second pixel substrate, and the first peripheral substrate are stacked in this order from a position of incidence of incident light on the imaging device, and
when at least one type of impurity that contributes to inhibition of transient enhanced diffusion of a conductive impurity is defined as a specific species, the first peripheral transistor includes a first specific layer that is located in the first peripheral substrate and that contains the conductive impurity and the specific species.

25. The imaging device according to claim 24, wherein a gate length of the first peripheral transistor is shorter than a gate length of the amplifying transistor.

26. A method for manufacturing the imaging device according to claim 1, the method comprising:
fabricating a stacked structure including the pixel substrate portion and the first peripheral substrate portion; and
heating the stacked structure.
